(19) United States
(12) Patent Application Publication
(10) Pub. No.: US 2024/0395974 A1
(43) Pub. Date: Nov. 28, 2024

(54) Display Apparatus, Display Module, And Electronic Device

(71) Applicant: Semiconductor Energy Laboratory Co., Ltd., Kanagawa-ken (JP)

(72) Inventors: Shunpei YAMAZAKI, Setagaya, Tokyo (JP); Koji KUSUNOKI, Isehara, Kanagawa (JP); Yoshiaki OIKAWA, Atsugi, Kanagawa (JP)

(73) Assignee: Semiconductor Energy Laboratory Co., Ltd., Kanagawa-ken (JP)

(21) Appl. No.: 18/695,601

(22) PCT Filed: Sep. 16, 2022
(86) PCT No.: PCT/IB2022/058743

§ 371 Date: Mar. 26, 2024

(30) Foreign Application Priority Data
Sep. 29, 2021 (JP) 2021-159438

(51) Int. Cl. H01L 33/38; H01L 25/075; H01L 25/16; H01L 33/10; H01L 33/50; H01L 33/62

(52) U.S. Cl. CPC H01L 33/382; H01L 25/0753; H01L 25/167; H01L 33/10; H01L 33/504; H01L 33/62

(57) ABSTRACT

A display apparatus with high display quality is provided. The display apparatus includes a first light-emitting device, a second light-emitting device, a first insulating layer, and a filling layer. The first light-emitting device includes a first electrode, a first semiconductor layer over the first electrode, and a common electrode over the first semiconductor layer. The second light-emitting device includes a second electrode, a second semiconductor layer over the second electrode, and the common electrode over the second semiconductor layer. The first insulating layer includes a region in contact with the side surface of the first semiconductor layer and a region in contact with the side surface of the second semiconductor layer. The filling layer includes a region overlapping with the side surface of the first semiconductor layer with the first insulating layer therebetween and a region overlapping with the side surface of the second semiconductor layer with the first insulating layer therebetween. The common electrode includes a region in contact with the top surface of the filling layer.

### TECHNICAL FIELD

One embodiment of the present invention relates to a display apparatus, a display module, and an electronic device. One embodiment of the present invention relates to a method for manufacturing a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for fabricating any of them.

### BACKGROUND ART

In recent years, display apparatuses applicable to virtual reality (VR), augmented reality (AR), substitutional reality (SR), or mixed reality (MR) have been desired.

VR, AR, SR, and MR are collectively referred to as xR (Extended Reality). Display apparatuses for xR have been expected to have higher resolution and higher color reproducibility so that realistic feeling and the sense of immersion can be enhanced. Examples of display elements (also referred to as display devices) applicable to such display apparatuses include a light-emitting device such as a liquid crystal display, an organic EL (Electro Luminescence) device, or a light-emitting diode (LED) device.

Patent Document 1 discloses a display apparatus using a micro LED.

### Reference

### Patent Document

[Patent Document 1] PCT International Publication No. 2019/220267

### SUMMARY OF THE INVENTION

### Problems to be Solved by the Invention

An object of one embodiment of the present invention is to provide a display apparatus with high display quality. An object of one embodiment of the present invention is to provide a display apparatus with high resolution. An object of one embodiment of the present invention is to provide a display apparatus with high definition. An object of one embodiment of the present invention is to provide a display apparatus with high luminance. An object of one embodiment of the present invention is to provide a display apparatus with high contrast. An object of one embodiment of the present invention is to provide a highly reliable display apparatus. An object of one embodiment of the present invention is to provide a novel display apparatus.

An object of one embodiment of the present invention is to provide a method for manufacturing a display apparatus with high display quality. An object of one embodiment of the present invention is to provide a method for manufacturing a display apparatus with high resolution. An object of one embodiment of the present invention is to provide a method for manufacturing a display apparatus with high definition. An object of one embodiment of the present invention is to provide a method for manufacturing a display apparatus with high luminance. An object of one embodiment of the present invention is to provide a method for manufacturing a display apparatus with high contrast. An object of one embodiment of the present invention is to provide a method for manufacturing a highly reliable display apparatus. An object of one embodiment of the present invention is to provide a method for manufacturing a novel display apparatus.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display apparatus including a first light-emitting device, a second light-emitting device, a first insulating layer, and a filling layer. The first light-emitting device includes a first electrode, a first semiconductor layer over the first electrode, and a common electrode over the first semiconductor layer. The second light-emitting device includes a second electrode, a second semiconductor layer over the second electrode, and the common electrode over the second semiconductor layer. The first insulating layer includes a region in contact with a side surface of the first semiconductor layer and a region in contact with a side surface of the second semiconductor layer. The filling layer includes a region overlapping with the side surface of the first semiconductor layer with the first insulating layer therebetween and a region overlapping with the side surface of the second semiconductor layer with the first insulating layer therebetween. The common electrode includes a region in contact with a top surface of the filling layer.

The above-described display apparatus includes a coloring layer and a color conversion layer. The coloring layer includes a region overlapping with the first light-emitting device with the color conversion layer therebetween. The color conversion layer contains a fluorescent substance or a quantum dot.

In the above-described display apparatus, end portions of the filling layer are positioned over the first semiconductor layer and the second semiconductor layer. The end portions of the filling layer each have a tapered shape in a cross-sectional view.

In the above-described display apparatus, end portions of the first insulating layer are positioned over the first semiconductor layer and the second semiconductor layer. The end portions of the first insulating layer each have a tapered shape in a cross-sectional view.

In the above-described display apparatus, the end portion of the filling layer is positioned outside the end portion of the first insulating layer.

In the above-described display apparatus, the filling layer has a top surface in a convex shape in a cross-sectional view.

The above-described display apparatus includes a reflective layer. The reflective layer is positioned between the first insulating layer and the filling layer. The reflective layer includes a region overlapping with the side surface of the first semiconductor layer with the first insulating layer therebetween and a region overlapping with the side surface of the second semiconductor layer with the first insulating layer therebetween.

The above-described display apparatus includes a second insulating layer. The second insulating layer includes a region in contact with a top surface of the first semiconductor layer. The filling layer includes a region overlapping with the top surface of the first semiconductor layer with the second insulating layer therebetween.

In the above-described display apparatus, an end portion of the second insulating layer has a tapered shape in a cross-sectional view.

In the above-described display apparatus, the first insulating layer contains an inorganic material, and the filling layer contains an organic material.

In the above-described display apparatus, the filling layer has an insulating property.

In the above-described display apparatus, the filling layer has a conductive property.

In the above-described display apparatus, each of the first semiconductor layer and the second semiconductor layer is a compound containing a Group 13 element and a Group 15 element.

The above-described display apparatus device includes a layer. The layer includes a first transistor and a second transistor. The first light-emitting device and the second light-emitting device are preferably provided over the layer. The first light-emitting device is electrically connected to the first transistor. The second light-emitting device is electrically connected to the second transistor.

One embodiment of the present invention is a display module including the above-described display apparatus and at least one of a connector and an integrated circuit.

One embodiment of the present invention is an electronic device including the above-described display module and at least one of a housing, a battery, a camera, a speaker, and a microphone.

### Effect of the Invention

One embodiment of the present invention can provide a display apparatus with high display quality. One embodiment of the present invention can provide a display apparatus with high resolution. One embodiment of the present invention can provide a display apparatus with high definition. One embodiment of the present invention can provide a display apparatus with high luminance. One embodiment of the present invention can provide a display apparatus with high contrast. One embodiment of the present invention can provide a highly reliable display apparatus. One embodiment of the present invention can provide a novel display apparatus.

One embodiment of the present invention can provide a method for manufacturing a display apparatus with high display quality. One embodiment of the present invention can provide a method for manufacturing a display apparatus with high resolution. One embodiment of the present invention can provide a method for manufacturing a display apparatus with high definition. One embodiment of the present invention can provide a method for manufacturing a display apparatus with high luminance. One embodiment of the present invention can provide a method for manufacturing a display apparatus with high contrast. One embodiment of the present invention can provide a method for manufacturing a highly reliable display apparatus. One embodiment of the present invention can provide a method for manufacturing a novel display apparatus.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a display apparatus. FIG. 1B is a cross-sectional view illustrating an example of the display apparatus.

FIG. 2A and FIG. 2B are cross-sectional views illustrating an example of a display apparatus.

FIG. 3A and FIG. 3B are cross-sectional views illustrating an example of a display apparatus.

FIG. 4A and FIG. 4B are cross-sectional views illustrating an example of a display apparatus.

FIG. 5A and FIG. 5B are cross-sectional views each illustrating an example of a display apparatus.

FIG. 6A and FIG. 6B are cross-sectional views each illustrating an example of a display apparatus.

FIG. 7A and FIG. 7B are cross-sectional views each illustrating an example of a display apparatus.

FIG. 8 is a cross-sectional view illustrating an example of a display apparatus.

FIG. 9A and FIG. 9B are cross-sectional views illustrating an example of a display apparatus.

FIG. 10 is a cross-sectional view illustrating an example of a display apparatus.

FIG. 11A and FIG. 11B are cross-sectional views illustrating an example of a display apparatus.

FIG. 12A and FIG. 12B are perspective views each illustrating an example of a method for manufacturing a display apparatus.

FIG. 13A and FIG. 13B are cross-sectional views each illustrating an example of a display apparatus.

FIG. 14A and FIG. 14B are cross-sectional views each illustrating an example of a display apparatus.

FIG. 15A and FIG. 15B are cross-sectional views each illustrating an example of a display apparatus.

FIG. 16A is a top view illustrating an example of a display apparatus. FIG. 16B is a cross-sectional view illustrating an example of the display apparatus.

FIG. 17A to FIG. 17D are cross-sectional views illustrating an example of a method for manufacturing a display apparatus.

FIG. 18A to FIG. 18C are perspective views illustrating an example of a method for manufacturing a display apparatus.

FIG. 19A and FIG. 19B are perspective views illustrating an example of a method for manufacturing a display apparatus.

FIG. 20A to FIG. 20D are cross-sectional views illustrating an example of a method for manufacturing a display apparatus.

FIG. 21A to FIG. 21D are cross-sectional views illustrating an example of a method for manufacturing a display apparatus.

FIG. 22A to FIG. 22D are cross-sectional views illustrating an example of a method for manufacturing a display apparatus.

FIG. 23A to FIG. 23C are cross-sectional views illustrating an example of a method for manufacturing a display apparatus.

FIG. 24A and FIG. 24B are cross-sectional views illustrating an example of a display apparatus.

FIG. 25A and FIG. 25B are cross-sectional views illustrating an example of a display apparatus.

FIG. 26A to FIG. 26D are cross-sectional views illustrating an example of a method for manufacturing a display apparatus.

FIG. 27A to FIG. 27C are cross-sectional views illustrating an example of a method for manufacturing a display apparatus.

FIG. 28A to FIG. 28D are cross-sectional views illustrating an example of a method for manufacturing a display apparatus.

FIG. 29A to FIG. 29C are cross-sectional views illustrating an example of a method for manufacturing a display apparatus.

FIG. 30A and FIG. 30B are cross-sectional views illustrating an example of a method for manufacturing a display apparatus.

FIG. 31A to FIG. 31G are diagrams each illustrating an example of a pixel.

FIG. 32A to FIG. 32K are top views each illustrating an example of a pixel.

FIG. 33A and FIG. 33B are perspective views illustrating an example of a display apparatus.

FIG. 34 is a cross-sectional view illustrating an example of a display apparatus.

FIG. 35 is a cross-sectional view illustrating an example of a display apparatus.

FIG. 36 is a cross-sectional view illustrating an example of a display apparatus.

FIG. 37 is a cross-sectional view illustrating an example of a display apparatus.

FIG. 38 is a cross-sectional view illustrating an example of a display apparatus.

FIG. 39 is a cross-sectional view illustrating an example of a display apparatus.

FIG. 40 is a perspective view illustrating an example of a display apparatus.

FIG. 41A is a cross-sectional view illustrating an example of a display apparatus. FIG. 41B and FIG. 41C are cross-sectional views illustrating examples of transistors.

FIG. 42 is a cross-sectional view illustrating an example of a display apparatus.

FIG. 43 is a cross-sectional view illustrating an example of a display apparatus.

FIG. 44A to FIG. 44D are diagrams illustrating examples of electronic devices.

FIG. 45A to FIG. 45F are diagrams illustrating examples of electronic devices.

FIG. 46A to FIG. 46G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be interchanged with each other depending on the case or the circumstances. For example, the term “conductive layer” can be replaced with the term “conductive film”. As another example, the term “insulating film” can be replaced with the term “insulating layer”.

### Embodiment 1

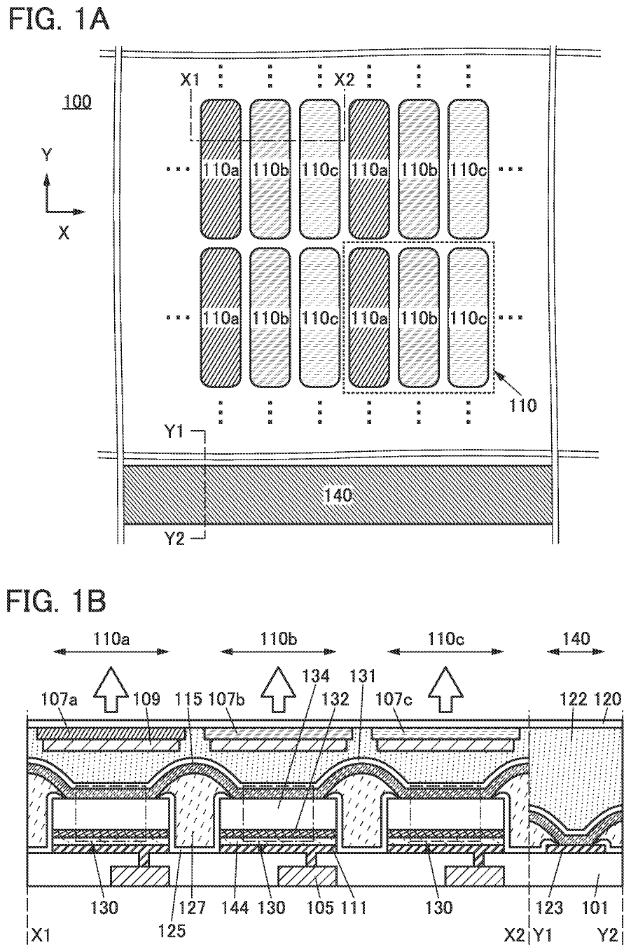

In this embodiment, a display apparatus of one embodiment of the present invention will be described with reference to FIG. 1 to FIG. 23.

One embodiment of the present invention is a display apparatus including a first light-emitting device, a second light-emitting device, a first insulating layer, and a filling layer. As each of the first light-emitting device and the second light-emitting device, a light-emitting diode (LED) can be used. An inorganic material is preferably used as the light-emitting material included in the light-emitting diode. The first light-emitting device includes a first electrode, a common electrode, and an island-shaped first semiconductor layer sandwiched between the first electrode and the common electrode. The second light-emitting device includes a second electrode, the common electrode, and an island-shaped second semiconductor layer sandwiched between the second electrode and the common electrode.

Note that in this specification and the like, the term “island shape” refers to a state where two or more layers formed using the same material in the same step are physically separated from each other. For example, “island-shaped semiconductor layer” means a state where the semiconductor layer and its adjacent semiconductor layer are physically separated from each other.

The first insulating layer includes a region in contact with the side surface of the first semiconductor layer and a region in contact with the side surface of the second semiconductor layer. Providing the first insulating layer can inhibit diffusion of impurities into the first semiconductor layer and the second semiconductor layer, so that a highly reliable display apparatus can be provided.

The filling layer is provided over the first insulating layer. The common electrode is provided over the filling layer. Providing the filling layer can reduce a level difference generated between the first light-emitting device and the second light-emitting device and increase the coverage with the common electrode. The filling layer has a function of filling a space between the first light-emitting device and the second light-emitting device to make flatness (also referred to as LFP (Local Filling Planarization)).

In the display apparatus of one embodiment of the present invention, a semiconductor layer and an electrode included in the light-emitting device can be formed by a photolithography method. When the display apparatus is formed over a glass substrate, the distance between light-emitting devices adjacent to each other can be decreased to less than 10 μm, less than or equal to 5 μm, less than or equal to 3 μm, less than or equal to 2 μm, less than or equal to 1.5 μm, less than or equal to 1 μm, or less than or equal to 0.5 μm. When the display apparatus is formed over a single crystal substrate, using a light exposure apparatus for LSI can further shorten the distance between adjacent light-emitting devices to less than or equal to 500 nm, less than or equal to 200 nm, less than or equal to 100 nm, or even less than or equal to 50 nm, for example. Accordingly, the area of a non-light-emitting region that could exist between two light-emitting devices can be significantly reduced, and the aperture ratio can be close to 100%. For example, the display apparatus of one embodiment of the present invention can achieve an aperture ratio higher than or equal to 40%, higher than or equal to 50%, higher than or equal to 60%, higher than or equal to 70%, higher than or equal to 80%, or higher than or equal to 90%, but the aperture ratio is lower than 100%. Since the sizes of the semiconductor layer and the electrode included in the light-emitting device can be extremely small, a display apparatus having both high resolution and high aperture ratio can be manufactured. Furthermore, a small and lightweight display apparatus can be achieved.

Specifically, for example, the display apparatus of one embodiment of the present invention can have a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

In this embodiment, a structure example of a display apparatus of one embodiment of the present invention and an example of a method for manufacturing the display apparatus will be described.

### Structure Example 1-1

FIG. 1A is a top view illustrating a display apparatus 100 that is one embodiment of the present invention. The display apparatus 100 includes a display portion in which a plurality of pixels 110 are arranged in a matrix and a connection portion 140 outside the display portion. Each of the pixels 110 includes a plurality of subpixels. The pixels 110 illustrated in FIG. 1A are in two rows and two columns. Each of the pixels 110 includes three subpixels (a subpixel 110a, a subpixel 110b, and a subpixel 110c), and the subpixels in two rows and six columns are illustrated. The connection portion 140 can also be referred to as a cathode contact portion.

Each of the subpixels includes a light-emitting device. Note that a light-emitting diode (LED) can be used as the light-emitting device. An inorganic material is preferably used as a light-emitting material included in the light-emitting diode. With use of an inorganic material as a light-emitting material, the lifetime of the display apparatus can be extended and the reliability thereof can be increased. In the case where a light-emitting diode, which is a self-luminous device, is used as a display device, a backlight is unnecessary and a polarizing plate does not have to be provided in a display apparatus. Accordingly, power consumption of the display apparatus can be reduced, and a thin and lightweight display apparatus can be achieved. Furthermore, a display apparatus using a light-emitting diode can have high luminance (e.g., higher than or equal to 5000 cd/m², preferably higher than or equal to 10000 cd/m²), a high contrast, and a wide viewing angle, which enables high display quality to be achieved.

The top surface shapes of the subpixels illustrated in FIG. 1A correspond to those of the light-emitting regions of the light-emitting devices. Examples of the top surface shape of the subpixel include polygons such as a triangle, a tetragon (including a rectangle and a square), and a pentagon; polygons with rounded corners; an ellipse; and a circle.

The subpixels each include a pixel circuit having a function of controlling the light-emitting device. The range of the circuit layout is not limited to the range of the subpixel illustrated in FIG. 1A and may be placed outside the subpixel. For example, transistors included in a pixel circuit of the subpixel 110a may be positioned within the range of the subpixel 110b illustrated in FIG. 1A, or some or all of the transistors may be positioned outside the range of the subpixel 110a.

Although the subpixel 110a, the subpixel 110b, and the subpixel 110c have the same or substantially the same aperture ratio (also referred to as size or size of a light-emitting region) in FIG. 1A, one embodiment of the present invention is not limited thereto. The aperture ratio of each of the subpixel 110a, the subpixel 110b, and the subpixel 110c can be determined as appropriate. The subpixel 110a, the subpixel 110b, and the subpixel 110c may have different aperture ratios, or two or more of the subpixel 110a, the subpixel 110b, and the subpixel 110c may have the same or substantially the same aperture ratio.

The pixel 110 illustrated in FIG. 1A employs stripe arrangement. The pixel 110 illustrated in FIG. 1A consists of three subpixels: the subpixel 110a, the subpixel 110b, and the subpixel 110c. The subpixel 110a, the subpixel 110b, and the subpixel 110c include light-emitting devices emitting light of different colors. The subpixel 110a, the subpixel 110b, and the subpixel 110c can be subpixels of three colors of red (R), green (G), and blue (B) or subpixels of three colors of yellow (Y), cyan (C), and magenta (M), for example. The number of types of subpixels is not limited to three, and may be four or more. As the subpixels of four colors, subpixels of four colors of R, G, B, and white (W), subpixels of four colors of R, G, B, and Y, or four subpixels of R, G, B, and infrared light (IR) can be given, for example.

In this specification and the like, the row direction and the column direction are sometimes referred to as the X direction and the Y direction, respectively. The X direction and the Y direction intersect with each other and are, for example, orthogonal to each other (see FIG. 1A). FIG. 1A illustrates an example in which subpixels of different colors are arranged in the X direction and subpixels of the same color are arranged in the Y direction.

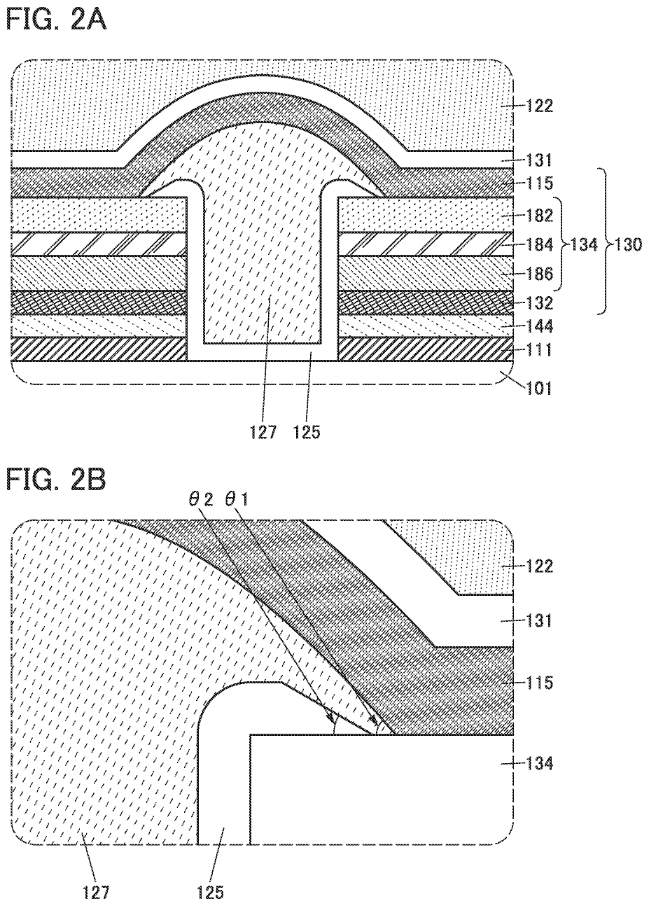

FIG. 1B is a cross-sectional view taken along dashed-dotted line X1-X2 and dashed-dotted line Y1-Y2 in FIG. 1A. FIG. 2A and FIG. 2B are enlarged views of part of the cross-sectional view illustrated in FIG. 1B.

As illustrated in FIG. 1B, in the display apparatus 100, light-emitting devices 130 are provided over a layer 101 and a protective layer 131 is provided to cover the light-emitting devices 130. A substrate 120 is bonded onto the protective layer 131 with a resin layer 122.

The light-emitting device 130 includes a conductive layer 132, an LED layer 134 over the conductive layer 132, and a conductive layer 115 over the LED layer 134. The conductive layer 132 and the conductive layer 115 each function as an electrode of the light-emitting device 130. The LED layer 134 sandwiched between a pair of electrodes (the conductive layer 132 and the conductive layer 115) includes at least a light-emitting layer. The light-emitting device 130 illustrated in FIG. 1B can be referred to as a light-emitting diode having what is called a vertical structure, in which the conductive layer 132 and the conductive layer 115 are provided on one surface of the LED layer 134 and the surface opposite thereto, respectively.

Next, structures of the light-emitting devices 130 are described with reference to FIG. 2A. FIG. 2A is an enlarged cross-sectional view of a region including two adjacent light-emitting devices 130 and its periphery.

The light-emitting device 130 includes the conductive layer 132, the conductive layer 115, and the LED layer 134 sandwiched between the conductive layer 132 and the conductive layer 115. The LED layer 134 has a stacked-layer structure in which a semiconductor layer 186, a light-emitting layer 184, and a semiconductor layer 182 are stacked in this order. Note that the LED layer 134 may include a layer besides the semiconductor layer 186, the light-emitting layer 184, and the semiconductor layer 182.

The light-emitting layer 184 is sandwiched between the semiconductor layer 186 and the semiconductor layer 182. In the light-emitting layer 184, electrons and holes are combined to emit light. An n-type semiconductor layer can be used as one of the semiconductor layer 186 and the semiconductor layer 182, and a p-type semiconductor layer can be used as the other. An n-type semiconductor layer, an i-type semiconductor layer, or a p-type semiconductor layer can be used as the light-emitting layer 184. That is, a semiconductor layer can be used as each of the semiconductor layer 186, the light-emitting layer 184, and the semiconductor layer 182. Thus, the LED layer can be referred to as a semiconductor layer.

The LED layer 134 is formed to emit light such as red light, yellow light, green light, blue light, or ultraviolet light. There is no particular limitation on the structure of the LED layer 134; a homostructure, a heterostructure, a double-heterostructure, or the like having a pn junction or a pin junction may be used or a MIS (metal-insulator-semiconductor) junction may be used. The LED layer 134 may have a superlattice structure, a single quantum well structure or a multi quantum well (MQW) structure. The LED layer 134 may be formed using nanocolumns.

A compound containing a Group 13 element and a Group 15 element can be used for the LED layer 134, for example. Examples of the Group 13 element include aluminum, gallium, and indium. Examples of the Group 15 element include nitrogen, phosphorus, arsenic, and antimony. For the LED layer 134, a compound of gallium and phosphorus, a compound of gallium and arsenic, a compound of gallium, aluminum, and arsenic, a compound of aluminum, gallium, indium, and phosphorus, gallium nitride (GaN), a compound of indium and gallium nitride, a compound of selenium and zinc, or the like can be used, for example.

For example, gallium nitride can be used for the LED layer 134 emitting light in the ultraviolet wavelength range to the blue wavelength range. A compound of indium and gallium nitride can be used for the LED layer 134 emitting light in the ultraviolet wavelength range to the green wavelength range. A material such as a compound of aluminum, gallium, indium, and phosphorus or a compound of gallium and arsenic can be used for the LED layer 134 emitting light in the green wavelength range to the red wavelength range. A compound of gallium and arsenic can be used for the LED layer 134 emitting light in the infrared wavelength range.

The layer 101 preferably includes a pixel circuit having a function of controlling the light-emitting device 130. The pixel circuit can include a transistor, a capacitor, and a wiring, for example. FIG. 1B illustrates a transistor 105 as a transistor included in the pixel circuit.

The layer 101 can have a structure in which a pixel circuit is provided over a semiconductor substrate or an insulating substrate. As a semiconductor substrate, a single crystal semiconductor substrate or a polycrystalline semiconductor substrate using silicon or silicon carbide as a material, a compound semiconductor substrate of silicon germanium or the like, an SOI substrate, or the like can be used. As an insulating substrate, a glass substrate, a quartz substrate, a sapphire substrate, a ceramic substrate, an organic resin substrate, or the like can be used. Note that the shapes of the semiconductor substrate and an insulating substrate may be circular or square. As the semiconductor substrate and the insulating substrate, a substrate having at least heat resistance high enough to withstand heat treatment performed later can be used.

The layer 101 can have a stacked-layer structure of a substrate provided with a plurality of transistors and an insulating layer covering these transistors, for example. The insulating layer over the transistors may have a single-layer structure or a stacked-layer structure. Note that the layer 101 may include one or both of a gate line driver circuit (a gate driver) and a source line driver circuit (a source driver) in addition to the pixel circuit. Furthermore, one or both of an arithmetic circuit and a memory circuit may be included.

A conductive layer 111 is provided over the layer 101. The conductive layer 111 is electrically connected to the transistor 105 and serves as a pixel electrode. A connection layer 144 is provided over the conductive layer 111, and the light-emitting device 130 is provided over the connection layer 144. A conductive material can be used for the connection layer 144. For the conductive material, for example, a metal such as gold, silver, or tin, an alloy containing any of these metals, a conductive film, or a conductive paste can be used. For example, gold can be suitably used for the connection layer 144. The connection layer 144 can be formed by a printing method, a transfer method, or a discharge method. The conductive layer 132 included in the light-emitting device 130 is electrically connected to the conductive layer 111 through a connection layer 144. It can be said that the conductive layer 132, the connection layer 144, and the conductive layer 111 collective functions as a pixel electrode. Note that electrical connection between the conductive layer 111 and the conductive layer 132 may be formed by making the conductive layer 111 and the conductive layer 132 in direct contact with each other without providing the connection layer 144.

FIG. 1B illustrates an example in which end portions of the LED layer 134, the conductive layer 132, the connection layer 144, and the conductive layer 111 are aligned or substantially aligned with each other, that is, the top surface shapes of the LED layer 134, the conductive layer 132, the connection layer 144, and the conductive layer 111 are aligned or substantially aligned with each other. For example, the LED layer 134, the conductive layer 132, the connection layer 144, and the conductive layer 111 can be formed using the same mask. At least preferably, the end portions of the LED layer 134 and the conductive layer 132 are aligned or substantially aligned with each other. With such a structure, a region provided with the conductive layer 132 can be entirely used as a light-emitting region of the light-emitting device 130, increasing the aperture ratio of the pixels. Note that the end portions of the LED layer 134, the conductive layer 132, the connection layer 144, and the conductive layer 111 are not necessarily completely aligned with each other; parts thereof are not needed to be aligned with each other.

In the case where end portions are aligned or substantially aligned with each other and in the case where top surface shapes are the same or substantially the same, it can be said that outlines of stacked layers at least partly overlap with each other in a top view. For example, the case of processing an upper layer and a lower layer with use of the same mask pattern or mask patterns that are partly the same is included. However, in some cases, the outlines do not completely overlap with each other and the upper layer is located inward from the lower layer or the upper layer is located outside the lower layer; such a case is also represented by the expression “end portions are substantially aligned with each other” or “top surface shapes are substantially the same”.

The conductive layer 115 provided over the LED layer 134 is shared by the plurality of light-emitting devices 130 and functions as a common electrode.

The conductive layer 115 is electrically connected to a conductive layer 123 provided in the connection portion 140. For the conductive layer 123, the same material as the conductive layer 111 can be used. In other words, the conductive layer 123 can be formed through the same steps as the conductive layer 111.

Although the top view in FIG. 1A illustrates an example in which the connection portion 140 is positioned in the lower side of the display portion, the position of the connection portion is not particularly limited. The connection portion 140 may be provided in at least one of the upper side, the right side, the left side, and the lower side of the display portion in the top view, and may be provided so as to surround the four sides of the display portion. The top surface shape of the connection portion 140 is not particularly limited and can be a belt-like shape, an L shape, a U shape, a frame-like shape, or the like. The number of the connection portions 140 can be one or more.

As illustrated in FIG. 1B and FIG. 2A, an insulating layer 125 and a filling layer 127 over the insulating layer 125 are provided between the adjacent light-emitting devices 130. The insulating layer 125 is provided in contact with the side surfaces of the LED layer 134, the conductive layer 132, the connection layer 144, and the conductive layer 111 and the top surface of the layer 101. Furthermore, the insulating layer 125 preferably includes a region in contact with part of the top surface of the LED layer 134. The filling layer 127 is provided over the insulating layer 125 to fill a depressed portion formed by the insulating layer 125. The filling layer 127 preferably covers at least part of the side surface of the insulating layer 125. The filling layer 127 can include a region overlapping with the side surface of the LED layer 134 with the insulating layer 125 therebetween. The conductive layer 115 is provided over the filling layer 127.

Providing the insulating layer 125 and the filling layer 127 can reduce a level difference generated between a region where the light-emitting device 130 is provided and a region where the light-emitting device 130 is not provided. Thus, unevenness of the formation surface of the conductive layer 115 functioning as the common electrode can be reduced, so that coverage with the conductive layer 115 can be improved. Consequently, a connection defect due to disconnection of the conductive layer 115 can be inhibited. Alternatively, an increase in electrical resistance due to local thinning of the conductive layer 115 caused by the level difference can be inhibited.

Note that in this specification and the like, step disconnection refers to a phenomenon in which a layer, a film, or an electrode is disconnected because of the shape of the formation surface (e.g., a level difference).

The filling layer 127 preferably includes a region where the level of the top surface is higher than the level of the top surface of the LED layer 134. The top surface of the filling layer 127 preferably has a shape with higher planarity and may have a convex portion, a convex surface, a concave surface, or a concave portion. For example, the top surface of the filling layer 127 preferably has a smooth convex shape with high flatness.

The side surface and part of the top surface of the LED layer 134 is covered with the insulating layer 125. The filling layer 127 includes a region overlapping with the side surface and part of the top surface of the LED layer 134 with the insulating layer 125 therebetween. When the side surface and part of the top surface of the LED layer 134 are covered with at least one of the insulating layer 125 and the filling layer 127, entry of impurities can be inhibited. Thus, deterioration of the light-emitting device 130 can be inhibited, and the reliability of the light-emitting device 130 can be increased.

The side surfaces of the conductive layer 132, the connection layer 144, and the conductive layer 111 are covered with the insulating layer 125. The filling layer 127 includes a region overlapping with the side surfaces of the conductive layer 132, the connection layer 144, and the conductive layer 111 with the insulating layer 125 therebetween. When the side surfaces of the conductive layer 132, the connection layer 144, and the conductive layer 111 are covered with at least one of the insulating layer 125 and the filling layer 127, the conductive layer 115 can be inhibited from being in contact with one or more of the conductive layer 132, the connection layer 144, and the conductive layer 111. Hence, a short circuit of the light-emitting device 130 can be inhibited, and the reliability of the light-emitting device 130 can be increased.

The insulating layer 125 is preferably in contact with the side surface of the LED layer 134. The insulating layer 125 in contact with the LED layers 134 can prevent peeling of the LED layers 134. When the insulating layer 125 is in close contact with the LED layer 134, adjacent LED layers 134 can be fixed or bonded to each other by the insulating layer 125. Thus, the reliability of the light-emitting device 130 can be increased. Furthermore, the manufacturing yield of the light-emitting device 130 can be increased.

For example, even in the case where a material with low adhesion or mechanical strength is used for the connection layer 144, a structure in which the insulating layer 125 is in contact with the side surface of the LED layer 134, the side surface of the conductive layer 132, the side surface of the conductive layer 111, and part of the top surface of the layer 101 enables the connection layer 144 to be fixed, so that peeling of the connection layer 144 can be inhibited and the mechanical strength can be increased.

When the insulating layer 125 and the filling layer 127 cover both the side surface and part of the top surface of the LED layer 134, peeling of the LED layer 134 can be further inhibited, leading to an increase in the reliability of the light-emitting device 130. The manufacturing yield of the light-emitting device 130 can also be improved.

Although FIG. 1B illustrates a plurality of cross sections of the insulating layer 125 and the filling layers 127, the insulating layer 125 and the filling layer 127 are each a continuous layer in the top view of the display apparatus 100. In other words, the display apparatus 100 can have a structure in which one insulating layer 125 and one filling layer 127 are included, for example. Note that the display apparatus 100 may include a plurality of insulating layers 125 which are separated from each other and a plurality of filling layers 127 which are separated from each other.

Next, materials that can be used in the insulating layer 125 and the filling layer 127 are described.

The insulating layer 125 can be formed using an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferable because it has high selectivity with respect to the LED layer 134 in etching and has a function of protecting the LED layer 134 in formation of the filling layer 127.

In particular, when an inorganic insulating film such as an aluminum oxide film, a hafnium oxide film, or a silicon oxide film that is formed by an atomic layer deposition (ALD) method is employed for the insulating layer 125, it is possible to form the insulating layer 125 that has few pinholes and an excellent function of protecting the LED layer 134. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition; in the case where silicon nitride oxide is described, it refers to a material that contains more nitrogen than oxygen in its composition.

The insulating layer 125 preferably has a function of a barrier insulating layer against at least one of water and oxygen. The insulating layer 125 preferably has a function of inhibiting the diffusion of at least one of water and oxygen. The insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as having low permeability). Alternatively, a barrier property refers to a function of capturing or fixing (also referred to as gettering) a particular substance.

When the insulating layer 125 has a function of the barrier insulating layer or a gettering function, entry of impurities (typically, at least one of water and oxygen) that would diffuse into the light-emitting devices from the outside can be inhibited. With this structure, a highly reliable light-emitting device and a highly reliable display apparatus can be provided.

The insulating layer 125 preferably has a low impurity concentration. Accordingly, deterioration of the LED layer 134, which is caused by entry of impurities into the LED layer 134 from the insulating layer 125, can be inhibited. In addition, when the impurity concentration is reduced in the insulating layer 125, a barrier property against at least one of water and oxygen can be increased. For example, it is preferable that one of a hydrogen concentration and carbon concentration or desirably both of them be sufficiently low in the insulating layer 125.

The filling layer 127 provided over the insulating layer 125 has a function of reducing unevenness of the insulating layer 125 formed between the adjacent light-emitting devices 130. In other words, the filling layer 127 has an effect of improving the planarity of the formation surface of the conductive layer 115.

An insulating layer containing an organic material can be suitably used as the filling layer 127. As the organic material, a photosensitive resin is preferably used, and for example, a photosensitive acrylic resin is preferably used. Note that in this specification and the like, an acrylic resin refers to not only a polymethacrylic acid ester or a methacrylic resin, but also all the acrylic polymer in a broad sense in some cases.

Alternatively, for the filling layer 127, it is possible to use an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, for the filling layer 127, it is possible to use an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive organic resin, either a positive material or a negative material may be used.

A material with a low light transmittance is preferably used for the filling layer 127, so that the filling layer 127 has a light-blocking property. The filling layer 127 may be formed using a material absorbing visible light. When the filling layer 127 blocks light emitted from the light-emitting device 130, light leaking from the light-emitting device 130 to another subpixel through the filling layer 127 (stray light) can be inhibited. Thus, the display quality of the display apparatus can be improved. Furthermore, since the display quality can be increased even when a polarizing plate is not used in the display apparatus, a lightweight and thin display apparatus can be achieved.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferable to enhance the effect of blocking visible light. In particular, mixing color filter materials of three or more colors makes it possible to form a black or nearly black resin layer.

A material used for the filling layer 127 preferably has the low volume shrinkage rate. This facilitates formation of the filling layer 127 into a desired shape. In addition, the volume shrinkage rate of the filling layer 127 after curing is preferably low. Accordingly, the shape of the filling layer 127 is easily maintained in various steps after the formation of the filling layer 127. Specifically, the rate of volume shrinkage of the filling layer 127 by thermal curing, by light curing, or by light curing and thermal curing is preferably lower than or equal to 10%, further preferably lower than or equal to 5%, still further preferably lower than or equal to 1%. Here, as the volume shrinkage rate, one of the rate of volume shrinkage by light irradiation and the rate of volume shrinkage by heating, or the sum of these rates can be used.

Although the insulating material is described as an example of the material that can be used for the filling layer 127, the conductivity of the filling layer 127 is not particularly limited. For the filling layer 127, a material of a semiconductor may be used or a conductive material may be used. For example, when a conductive material is used for the filling layer 127, the tolerance to overcurrent generated by electrostatic discharge (ESD) can be enhanced in the display apparatus. For the filling layer 127, for example, an organic resin in which metal particles are dispersed can be used.

In the case where a conductive material is used for the filling layer 127, the insulating layer 125 is preferably provided between the filling layer 127 and the conductive layer 132, the connection layer 144, and the conductive layer 111. When the side surfaces of the conductive layer 132, the connection layer 144, and the conductive layer 111 are covered with the insulating layer 125, the conductive layer 115 can be inhibited from being in contact with one or more of the conductive layer 132, the connection layer 144, and the conductive layer 111 through the filling layer 127. Hence, a short circuit of the light-emitting device 130 can be inhibited, and the reliability of the light-emitting device 130 can be increased.

Next, a structure of the filling layer 127 and the vicinity thereof will be described with reference to FIG. 2A and FIG. 2B. FIG. 2B is an enlarged cross-sectional view of an end portion of the filling layer 127 over the LED layer 134 illustrated in FIG. 2A and its vicinity.

As illustrated in FIG. 2A and FIG. 2B, the end portion of the filling layer 127 is preferably positioned outside the end portion of the insulating layer 125. With this structure, unevenness of the formation surface (here, the filling layer 127 and the LED layer 134) of the conductive layer 115 can be reduced, so that coverage with the conductive layer 115 can be improved. Furthermore, as illustrated in FIG. 2B, the end portion of the filling layer 127 is preferably tapered in the cross-sectional view.

Note that in this specification and the like, a tapered shape refers to such a shape that at least part of a side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

The angle θ1 formed by the side surface of the filling layer 127 and the formation surface (here, the LED layer 134) is preferably less than 90°, further preferably less than or equal to 60°, still further preferably less than or equal to 45°, yet still further preferably less than or equal to 20°. When the end portion of the filling layer 127 has a tapered shape, the conductive layer 115 can be deposited with good coverage over the filling layer 127, so that step disconnection or local thinning of the thickness can be inhibited. Accordingly, the thickness of the conductive layer 115 and the in-plane uniformity of the resistance can be increased, so that the display quality of the display apparatus can be improved.

As illustrated in FIG. 2A, the top surface of the filling layer 127 preferably has a convex shape in the cross-sectional view. The convex shape of the top surface of the filling layer 127 is preferably a shape that expands gradually toward the center. It is also preferable that the convex portion in the center portion of the top surface of the filling layer 127 have a shape gently connected to a tapered portion in the end portion. When the filling layer 127 has such a shape, the conductive layer 115 can be deposited entirely over the filling layer 127 with good coverage.

As illustrated in FIG. 2B, the end portion of the insulating layer 125 preferably has a tapered shape in the cross-sectional view. The angle θ2 formed by the side surface of the insulating layer 125 and the formation surface (here, the LED layer 134) is preferably less than 90°, further preferably less than or equal to 60°, still further preferably less than or equal to 45°, yet still further preferably less than or equal to 20°. When the end portion of the insulating layer 125 has a tapered shape, the filling layer 127 can be deposited with good coverage over the insulating layer 125. Deposition of the filling layer 127 with good coverage enables the conductive layer 115 to be deposited with good coverage over the filling layer 127.

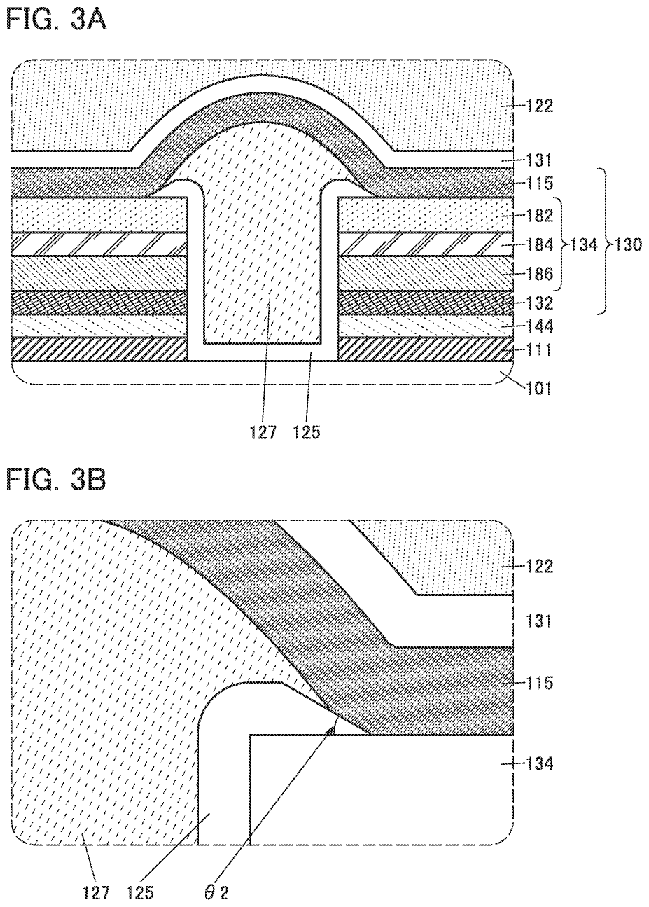

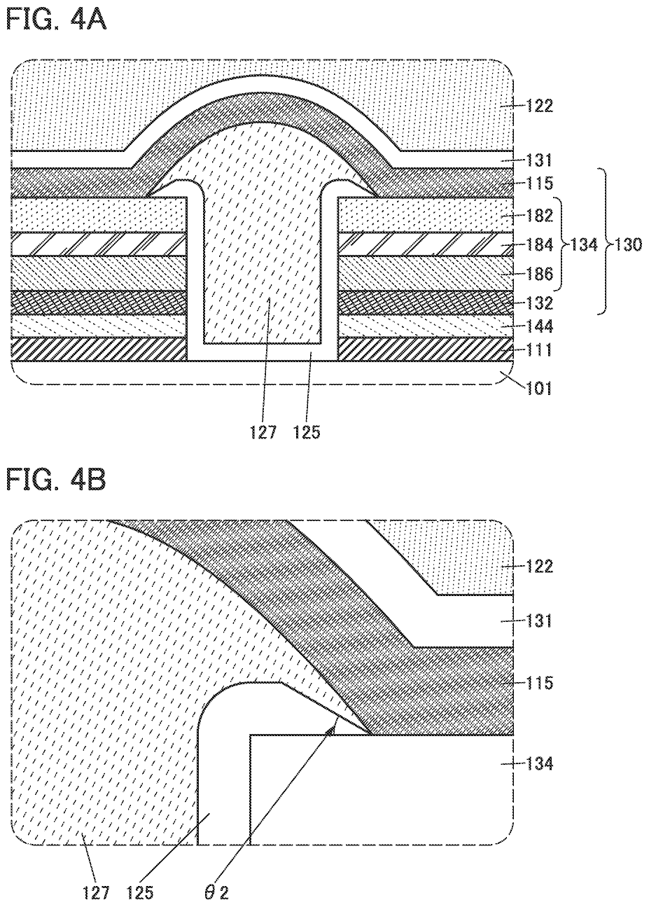

As illustrated in FIG. 3A and FIG. 3B, the end portion of the filling layer 127 may be located inward from the end portion of the insulating layer 125. As illustrated in FIG. 4A and FIG. 4B, the end portion of the filling layer 127 may be aligned or substantially aligned with the end portion of the insulating layer 125.

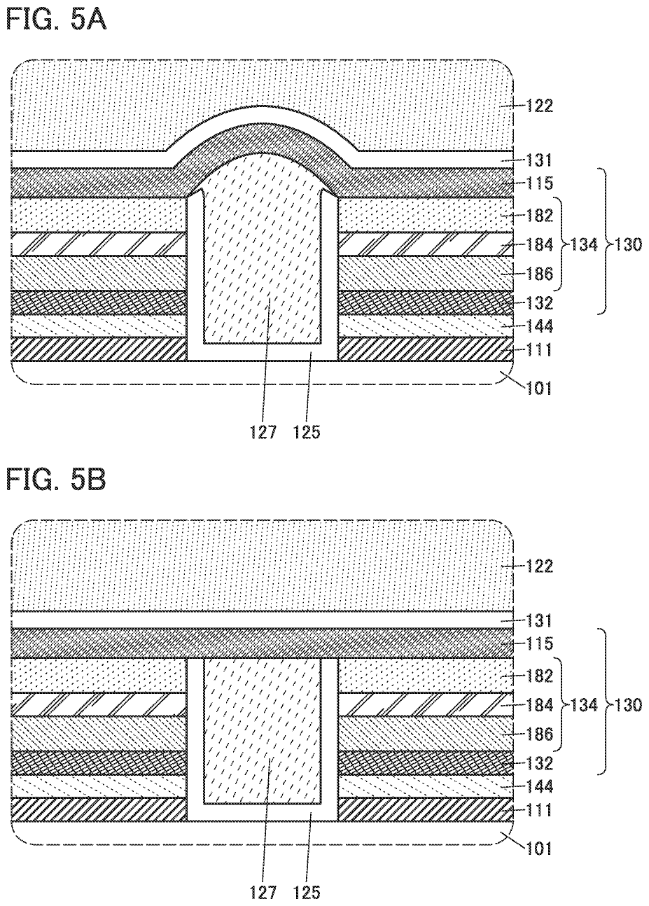

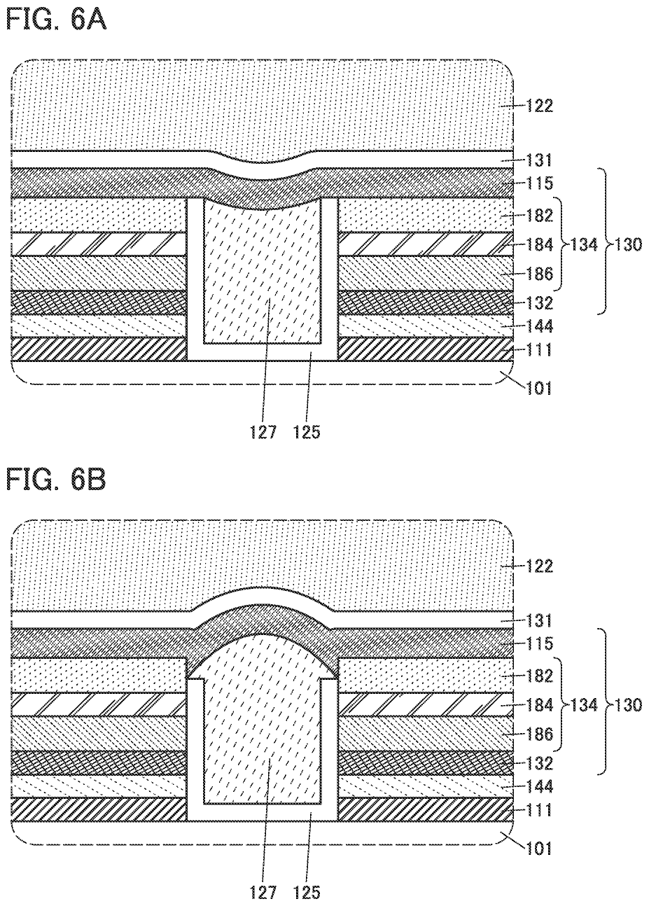

As illustrated in FIG. 5A, each of the insulating layer 125 and the filling layer 127 does not necessarily include a region in contact with the top surface of the LED layer 134. As illustrated in FIG. 5B, the top surfaces of the insulating layer 125, the filling layer 127, and the LED layer 134 may be level or substantially level with each other. Alternatively, as illustrated in FIG. 6A, the filling layer 127 may include a region where the level of the top surface is lower than the level of the top surface of the LED layer 134. FIG. 6A illustrates an example in which the filling layer 127 includes a depressed portion on the top surface.

As illustrated in FIG. 6B, the entire side surface of the LED layer 134 is not necessarily covered with the insulating layer 125 or the filling layer 127. Note that it is preferable that the insulating layer 125 cover at least the entire side surface of the light-emitting layer 184.

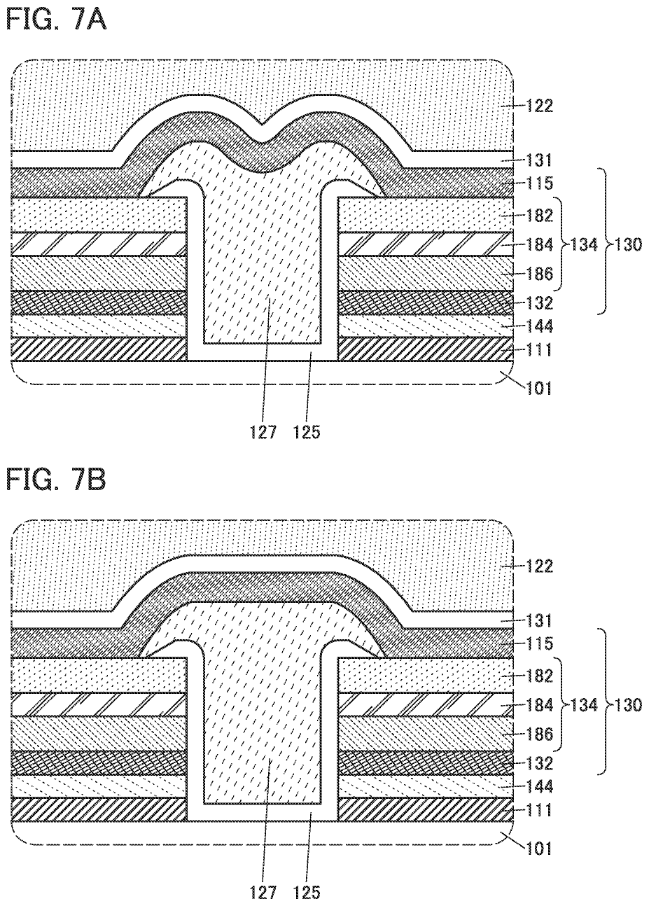

The top surface of the insulating layer 127 preferably has a smooth shape. For example, as illustrated in FIG. 7A, the top surface of the filling layer 127 may have a concave shape in a cross-sectional view. FIG. 7A illustrates an example in which the top surface of the filling layer 127 has a shape that is gently bulged toward the center, i.e., includes a convex surface, and has a shape that is recessed in the center and its vicinity, i.e., includes a concave surface. The convex portion of the top surface of the filling layer 127 has a shape gently connected to the tapered portion in the end portion. Even when the insulating layer 127 has such a shape, the conductive layer 115 can be deposited with good coverage entirely over the filling layer 127. Note that the top surface of the filling layer 127 is not limited to the above; for example, the top surface of the filling layer 127 may include a region that is flat or substantially flat as illustrated in FIG. 7B. When the filling layer 127 has a top surface including a flat or substantially flat region, for example, the bonding strength on the surface to which another substrate is bonded can be increased. Furthermore, the bonding defect caused by unevenness is inhibited, and the productivity can be increased.

The display apparatus 100 of one embodiment of the present invention can have any of the following structures: a top-emission structure in which light is emitted in a direction opposite to the formation surface (here, the layer 101) of the light-emitting device 130, a bottom-emission structure where light is emitted toward the formation surface of the light-emitting device 130, and a dual-emission structure where light is emitted toward both surfaces. As an example of a top emission structure in FIG. 1B and the like, light emitted from the substrate 120 side is schematically illustrated with white blank arrows. In the case where a top emission structure is employed, a material having a high visible-light-transmitting property is preferably used for the substrate 120. One or both of the conductive layer 132 and the conductive layer 111 are preferably formed using a material that reflects light, and the conductive layer 115 is preferably formed using a material that transmits light.

A coloring layer 107a, a coloring layer 107b, and a coloring layer 107c are provided between a surface from which light is emitted (here, the substrate 120) and the light-emitting device 130. The coloring layer 107a, the coloring layer 107b, and the coloring layer 107c each function as a color filter that transmit red light, green light, or blue light, for example. For each of the coloring layer 107a, the coloring layer 107b, and the coloring layer 107c, a metal material, a resin material, or a resin material containing a pigment or dye can be used. Note that the coloring layer 107a, the coloring layer 107b, and the coloring layer 107c may be collectively referred to as a coloring layer 107.

A color conversion layer 109 is provided between the light-emitting device 130 and each of the coloring layer 107a, the coloring layer 107b, and the coloring layer 107c. As the color conversion layer 109, a resin layer in which a color conversion material is mixed can be used, for example. For the color conversion layer, a fluorescent substance or a quantum dot (QD) can be used, for example. In particular, a quantum dot (QD) has an emission spectrum with a narrow peak width, so that emission with high color purity can be obtained. Thus, the display quality of the display apparatus can be improved. Note that both of a fluorescent substance and a quantum dot (QD) may be used as the color conversion material.

There is no particular limitation on a material of a quantum dot (QD), and examples include a Group 14 element, a Group 15 element, a Group 16 element, a compound of a plurality of Group 14 elements, a compound of an element belonging to any of Group 4 to Group 14 and a Group 16 element, a compound of a Group 2 element and a Group 16 element, a compound of a Group 13 element and a Group 15 element, a compound of a Group 13 element and a Group 17 element, a compound of a Group 14 element and a Group 15 element, a compound of a Group 11 element and a Group 17 element, iron oxides, titanium oxides, spinel chalcogenides, and a variety of semiconductor clusters.

Specific examples of materials included in a quantum dot (QD) include cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and a combinations thereof. What is called an alloyed quantum dot, whose composition is represented by a given ratio, may be used.

Examples of the quantum dot (QD) include core-type quantum dots, core-shell quantum dots, and core-multishell quantum dots. Quantum dots (QD) have a high proportion of surface atoms and thus have high reactivity and easily aggregate together. To prevent aggregation of quantum dots (QD) and increase dispersiveness to a dispersion medium, it is preferable that a protective agent be attached to, or a protective group be provided at the surfaces of quantum dots. This can also reduce reactivity and improve electrical stability.

Since band gaps of quantum dots (QD) are increased as their size is decreased, the size is adjusted as appropriate so that light with a desired wavelength can be obtained. Light emission from the quantum dots (QD) is shifted to a short wavelength side, i.e., a high energy side, as the crystal size is decreased; thus, emission wavelengths of the quantum dots can be adjusted over a wavelength range of an ultraviolet region, a visible light region, and an infrared region by changing the size of quantum dots. The size (diameter) of quantum dots is, for example, greater than or equal to 0.5 nm and less than or equal to 20 nm, preferably greater than or equal to 1 nm and less than or equal to 10 nm. The emission spectra are narrowed as the size distribution of quantum dots gets smaller, and thus light emission with high color purity can be obtained. The shape of quantum dots (QD) is not particularly limited and may be a spherical shape, a rod shape, a circular shape, or the like. A quantum rod, which is a rod-shaped quantum dot, has a function of emitting directional light.

As a color conversion material contained in the color conversion layer 109, a material that emits light when being excited by light emitted from the light-emitting device 130 can be used. For example, when a color of light emitted from the color conversion material is a complementary color of light emitted from the light-emitting device 130, white light can be emitted from the color conversion layer 109.

For example, when the color conversion layer 109 contains a color conversion material that emits yellow light and the light-emitting device 130 emits blue light, light passing through the color conversion layer 109 is white light. In the subpixel 110a provided with the coloring layer 107a transmitting red light, light emitted from the light-emitting device 130 passes through the color conversion layer 109 and the coloring layer 107a, whereby red light is emitted. Similarly, in the subpixel 110b provided with the coloring layer 107b transmitting green light, light emitted from the light-emitting device 130 passes through the color conversion layer 109 and the coloring layer 107b, whereby green light is emitted. In the subpixel 110c provided with the coloring layer 107c transmitting blue light, light emitted from the light-emitting device 130 passes through the color conversion layer 109 and the coloring layer 107c, whereby blue light is emitted. The display apparatus of one embodiment of the present invention can perform color display using one type of light-emitting device 130. A manufacturing process of the display apparatus using one type of light-emitting device 130 can be simplified. Thus, according to one embodiment of the present invention, a display apparatus with a high luminance, a high contrast, a high response speed, and low power consumption can be obtained at a low manufacturing cost

Note that there is no particular limitation on the combination of the color of light emitted from the color conversion material contained in the color conversion layer 109 and the color of light emitted from the light-emitting device 130. For example, white light may be emitted from the color conversion layer 109 with a structure where the color conversion layer 109 contains a color conversion material that emits red light and the light-emitting device 130 emits blue green light. Furthermore, white light may be emitted from the color conversion layer 109 with a structure where the color conversion layer 109 contains a color conversion material that emits red light, a color conversion material that emits green light, and a color conversion material that emits blue light and the light-emitting device 130 emits near-ultraviolet light or ultraviolet light.

The protective layer 131 is preferably provided over the light-emitting device 130. Providing the protective layer 131 can improve the reliability of the light-emitting device 130. The protective layer 131 may have a single-layer structure or a stacked-layer structure of two or more layers.

There is no limitation on the conductivity of the protective layer 131. For the protective layer 131, at least one of an insulating film, a semiconductor film, and a conductive film can be used.

The protective layer 131 includes an inorganic film, which can inhibit oxidation of the conductive layer 115 and entry of impurities (e.g., moisture and oxygen) into the light-emitting device 130. Accordingly, deterioration of the light-emitting device 130 can be inhibited, and the reliability of the display apparatus can be increased.

As the protective layer 131, an inorganic insulating film such as an oxide insulating film, a nitride insulating film, an oxynitride insulating film, or a nitride oxide insulating film can be used, for example. Specific examples of these inorganic insulating films are as listed in the description of the insulating layer 125. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the conductive layer 115. The inorganic film may further contain nitrogen.

When light emitted from the light-emitting device 130 is extracted through the protective layer 131, the protective layer 131 preferably has a high visible-light-transmitting property. For example, ITO, IGZO, and aluminum oxide are preferable because they are each an inorganic material having a high property of transmitting visible light.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit diffusion of impurities (e.g., water and oxygen) to the LED layer 134 side.

Furthermore, the protective layer 131 may include an organic film. For example, the protective layer 131 may include both an organic film and an inorganic film. Examples of an organic material that can be used for the protective layer 131 include organic insulating materials that can be used for the filling layer 127.

The protective layer 131 may have a stacked-layer structure of two layers which are formed by different deposition methods. Specifically, the first layer of the protective layer 131 may be formed by an ALD method, and the second layer of the protective layer 131 may be formed by a sputtering method.

A light-blocking layer may be provided on the surface of the substrate 120 on the resin layer 122 side. A variety of optical members can be arranged on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be placed as a surface protective layer on the outer surface of the substrate 120. For example, a glass layer or a silica layer (a SiOₓ layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. Note that for the surface protective layer, a material having high visible light transmittance is preferably used. The surface protective layer is preferably formed using a material with high hardness.

For the substrate 120, glass, quartz, ceramic, sapphire, a resin, a metal, an alloy, a semiconductor, or the like can be used. The substrate on the side from which light from the light-emitting device 130 is extracted is formed using a material that transmits the light. When a flexible material is used for the substrate 120, the flexibility of the display apparatus can be increased and a flexible display can be provided. Furthermore, a polarizing plate may be used as the substrate 120.

For the substrate 120, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate 120 and the film absorbs water, the shape of the display apparatus might be changed, e.g., creases are generated. Thus, for the substrate 120, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferable. A two-liquid-mixture-type resin may be used. An adhesive sheet or the like may be used.

A structure example is partly different from that of <Structure example 1-1> shown above will be described below. Note that description of the same portions as those in <Structure example 1-1> is omitted in some cases. Furthermore, in drawings that are referred to later, the same hatching pattern is applied to portions having functions similar to those in <Structure example 1-1>, and the portions are not denoted by reference numerals in some cases.

### Structure Example 1-2

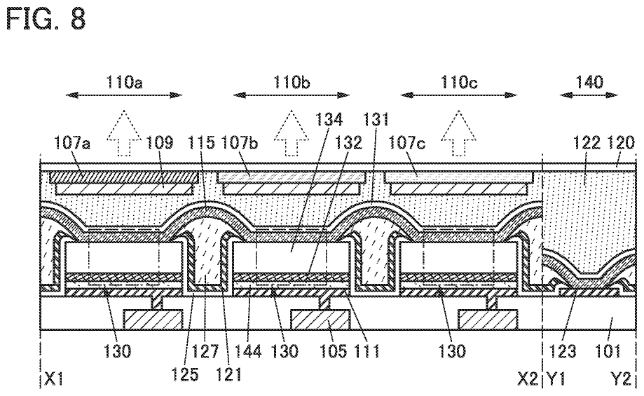

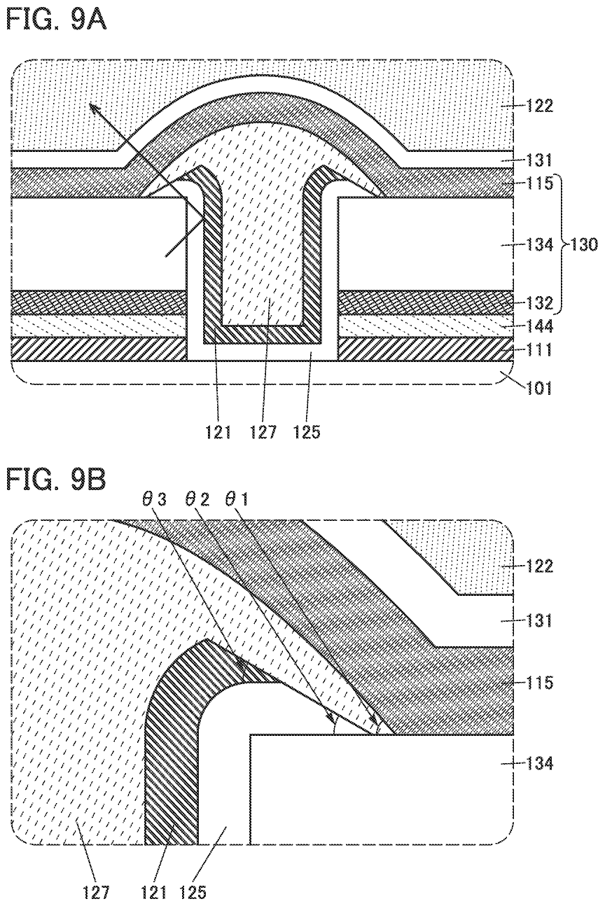

FIG. 8 is a schematic cross-sectional view of a display apparatus of one embodiment of the present invention. FIG. 1A can be referred to for a top view. FIG. 9A and FIG. 9B are enlarged views of part of the cross-sectional view illustrated in FIG. 8.

The display apparatus illustrated in FIG. 8 is different from the display apparatus described in <Structure example 1-1> mainly in that a reflective layer 121 is provided between the insulating layer 125 and the filling layer 127. The reflective layer 121 preferably includes a region overlapping with the side surface of the LED layer 134. The reflective layer 121 has a function of reflecting light emitted from the LED layer 134. Providing the reflective layer 121 enables light emitted from the side surface of the LED layer 134 to be reflected toward the conductive layer 115 side or the conductive layer 132 side. This can increase the luminance of the display apparatus 100. Providing the reflective layer 121 can inhibit light leaking to the adjacent subpixels through the insulating layer 125 and the filling layer 127 (such light is also referred to as stray light). Thus, the display quality of the display apparatus 100 can be improved. In FIG. 9A, an arrow schematically indicates light emitted from the LED layer 134 to the adjacent subpixel side. As illustrated in FIG. 9A, light emitted from the LED layer 134 to the adjacent subpixel side is reflected by the reflective layer 121, whereby light leaking to the adjacent subpixel (also referred to as stray light) can be inhibited.

The reflective layer 121 is preferably formed using a material having high reflectance of light emitted from the light-emitting device 130. Examples of a material for the reflective layer 121 include metal such as aluminum, titanium, chromium, nickel, copper, yttrium, zirconium, tin, zinc, silver, platinum, gold, molybdenum, tantalum, and tungsten, and an alloy containing the metal as its main component (e.g., an alloy of silver, palladium, and copper (APC: Ag—Pd—Cu)). The reflective layer 121 may be a stack of two or more of the above materials.

In the case where the reflective layer 121 is provided, the insulating layer 125 is preferably provided between the reflective layer 121 and the conductive layer 132, the connection layer 144, and the conductive layer 111. When the side surfaces of the conductive layer 132, the connection layer 144, and the conductive layer 111 are covered with the insulating layer 125, the conductive layer 115 can be inhibited from being in contact with one or more of the conductive layer 132, the connection layer 144, and the conductive layer 111 through the reflective layer 121. Hence, a short circuit of the light-emitting device 130 can be inhibited, and the reliability of the light-emitting device 130 can be increased.

In the case where the reflective layer 121 is provided, a material having a high light transmittance may be used for the filling layer 127 so that the filling layer 127 does not have a light-blocking property. Providing the reflective layer 121 can inhibit light (stray light) leaking to the adjacent subpixel. Note that in addition to the reflective layer 121, the filling layer 127 with a light-blocking property may be provided.

As illustrated in FIG. 9B, the end portion of the reflective layer 121 preferably has a tapered shape in a cross-sectional view. The angle θ3 formed by the side surface of the reflective layer 121 and the formation surface (here, the insulating layer 125) is preferably less than 90°, further preferably less than or equal to 60°, still further preferably less than or equal to 45°, yet still further preferably less than or equal to 20°. When a mask layer 118 has a tapered shape, the filling layer 127 can be formed with good coverage over the reflective layer 121. When the filling layer 127 is deposited with good coverage, the conductive layer 115 provided over the filling layer 127 can be further deposited with good coverage.

### Structure Example 1-3

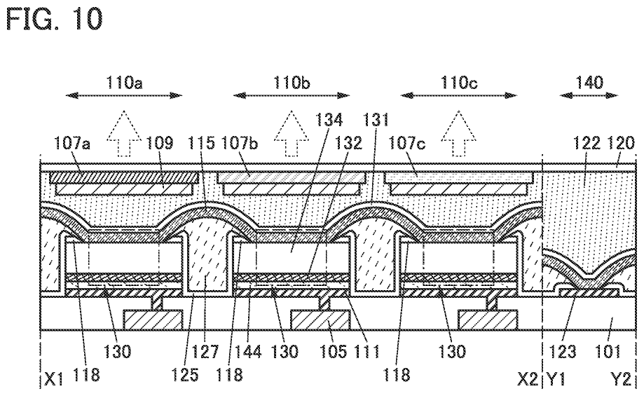

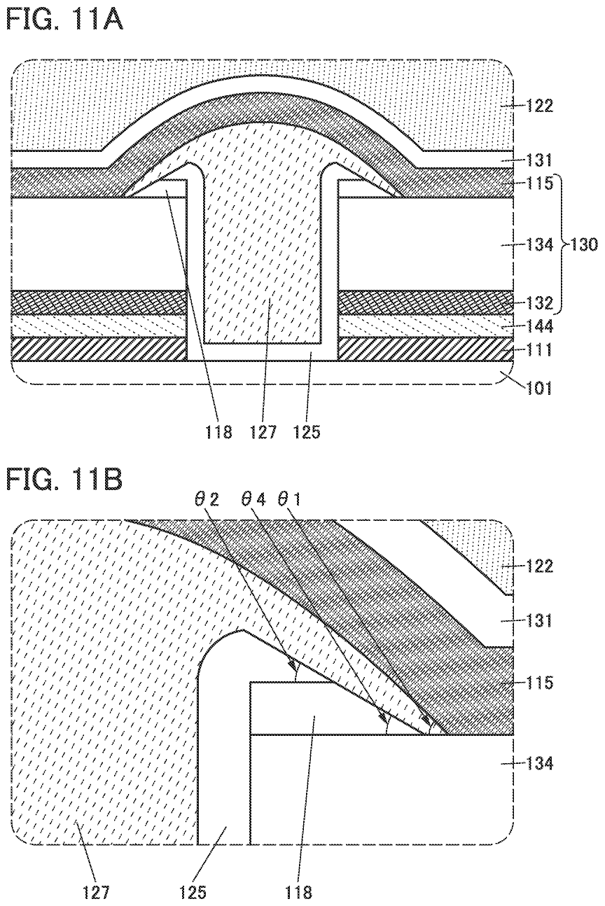

FIG. 10 is a cross-sectional view of a display apparatus of one embodiment of the present invention. FIG. 1A can be referred to for a top view. FIG. 11A and FIG. 11B are enlarged views of part of the cross-sectional view illustrated in FIG. 10.

The display apparatus illustrated in FIG. 10 is different from the display apparatus described in <Structure example 1-1> mainly in that a mask layer 118 is provided between the insulating layer 125 and the LED layer 134. The mask layer 118 is provided over the LED layer 134. The mask layer 118 is a remaining part of a mask layer provided in contact with the top surface of the LED layer 134 at the time of processing the LED layer 134. Thus, the mask layer used to protect the LED layer 134 in manufacture of the display apparatus may partly remain in the display apparatus of one embodiment of the present invention. Note that FIG. 10 illustrates an example in which the mask layer 118 is not provided over the conductive layer 123 in the connection portion 140.

In this specification and the like, a mask film and a mask layer are positioned at least above the LED layer and have a function of protecting the LED layer in the manufacturing process. Provision of a mask layer over a LED layer can reduce damage to the LED layer during a manufacturing process of the display apparatus and increase the reliability of the light-emitting device.

One end portion of the mask layer 118 is aligned or substantially aligned with the end portion of the LED layer 134, and the other end portion of the mask layer 118 is positioned above the LED layer 134. The mask layer 118 is positioned between the top surface of the island-shaped LED layer 134 and the insulating layer 125, for example.

Part of the top surface of the LED layer 134 is covered with the mask layer 118. The insulating layer 125 and the filling layer 127 each include a region overlapping with part of the top surface of the LED layer 134 with the mask layer 118 therebetween.

Note that the insulating layer 125 and the mask layer 118 can be formed using the same material. In this case, the boundary between the insulating layer 125 and the mask layer 118 is unclear and thus the layers cannot be distinguished from each other in some cases. Thus, the insulating layer 125 and the mask layer 118 are observed as one layer in some cases. That is, in observation, it sometimes seems that one layer is provided in contact with the side surface and part of the top surface of the LED layer 134, and the filling layer 127 covers at least part of the side surface of the one layer.

As illustrated in FIG. 11A, the mask layer 118 is provided in contact with part of the top surface of the LED layer 134. The insulating layer 125 is provided in contact with the top surface and the side surface of the mask layer 118, the side surface of the LED layer 134, the side surface of the conductive layer 132, the side surface of the connection layer 144, the side surface of the conductive layer 111, and the top surface of the layer 101. The filling layer 127 is provided in contact with the top surface of the insulating layer 125. The filling layer 127 may include a region in contact with the mask layer 118. The filling layer 127 may include a region in contact with the LED layer 134. The conductive layer 115 is provided to cover the LED layer 134, the mask layer 118, the insulating layer 125, and the filling layer 127.

As illustrated in FIG. 11B, the end portion of the mask layer 118 preferably has a tapered shape in a cross-sectional view. The angle θ4 formed by the side surface of the mask layer 118 and the formation surface (here, the LED layer 134) is preferably less than 90°, further preferably less than or equal to 60°, still further preferably less than or equal to 45°, yet still further preferably less than or equal to 20°. When the mask layer 118 has a tapered shape, the filling layer 127 can be formed with good coverage over the mask layer 118. When the filling layer 127 is deposited with good coverage, the conductive layer 115 can be further deposited with good coverage over the filling layer 127.

The end portion of the mask layer 118 is preferably positioned outside the end portion of the insulating layer 125. Accordingly, unevenness of the formation surface of the conductive layer 115 can be reduced, so that coverage with the conductive layer 115 can be improved.

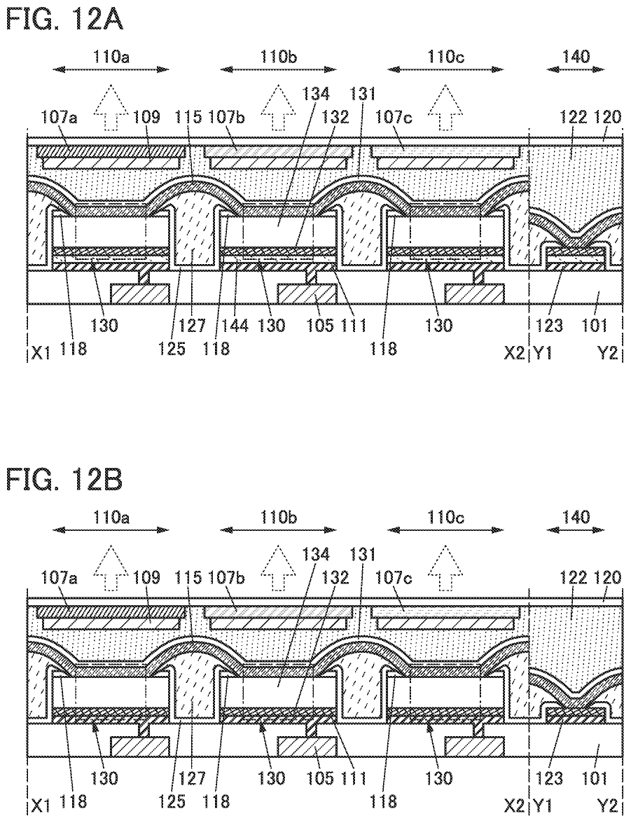

As illustrated in FIG. 12A, the connection portion 140 may include the conductive layer 123 and the connection layer 144 over the conductive layer 123. The conductive layer 123 is electrically connected to the conductive layer 115 through the conductive layer 123 and the connection layer 144. The connection layer 144 is not necessarily provided as illustrated in FIG. 12B. The conductive layer 132 included in the light-emitting device 130 can be directly in contact with the conductive layer 111, thereby being electrically connected thereto.

### Structure Example 1-4

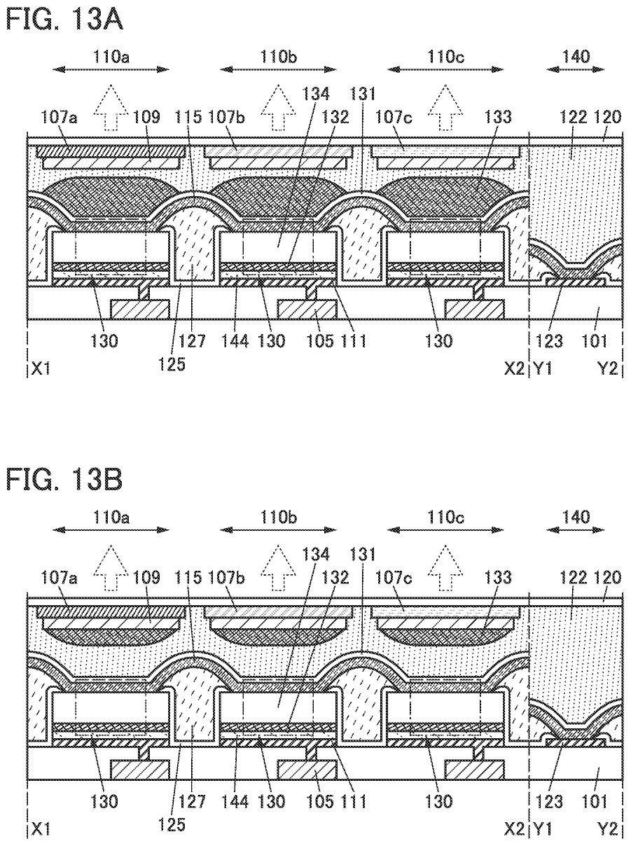

FIG. 13A and FIG. 13B are cross-sectional views of a display apparatus of one embodiment of the present invention. FIG. 1A can be referred to for a top view.

As illustrated in FIG. 13A, a lens 133 may be provided over the light-emitting device 130. FIG. 13A illustrates an example in which the lens 133 is provided over the light-emitting device 130 with the protective layer 131 therebetween. When the lens 133 is directly formed over the substrate provided with the light-emitting device 130, the accuracy of positional alignment of the light-emitting device 130 and the lens 133 can be enhanced.

As illustrated in FIG. 13B, the lens 133 may be provided over the light-emitting device 130 with the protective layer 131 and the resin layer 122 therebetween. The substrate 120 provided with the lens 133 can be bonded onto the protective layer 131 with the resin layer 122. By providing the lens 133 for the substrate 120, the heat treatment temperature in the formation step of them can be increased.

The lens 133 may have a convex surface facing the substrate 120 side or a convex surface facing the light-emitting device 130 side.

The lens 133 can be formed using at least one of an inorganic material and an organic material. For example, a material containing a resin can be used for the lens. Moreover, a material containing at least one of an oxide and a sulfide can be used for the lens. As the lens 133, a microlens array can be used, for example. The lens 133 may be directly formed over the substrate or the light-emitting device; alternatively, a lens array separately formed may be bonded thereto.

### Structure Example 1-5

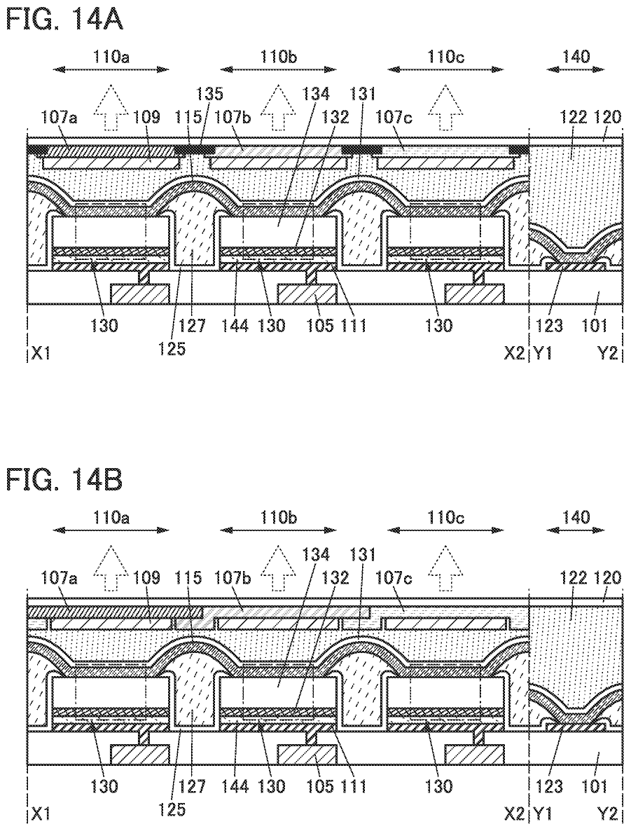

FIG. 14A is cross-sectional view of a display apparatus of one embodiment of the present invention. FIG. 1A can be referred to for a top view.

As illustrated in FIG. 14A, a light-blocking layer 135 may be provided. The light-blocking layer 135 is provided between adjacent coloring layers 107. The light-blocking layer 135 has an opening in a region overlapping with the light-emitting device 130. Providing the light-blocking layer 135 can block light emitted from the adjacent light-emitting device 130 and inhibit color mixture. Here, the coloring layer 107 is provided such that its end portion overlaps with the light-blocking layer 135, whereby light leakage can be suppressed. For the light-blocking layer 135, a material with a low transmittance can be used; for example, a metal material or a resin material containing pigment or dye can be used.

As illustrated in FIG. 14B, adjacent coloring layers 107 may partly overlap with each other. A region where the coloring layers 107 overlap with each other functions as a light-blocking layer. Although FIG. 14B illustrates an example in which the coloring layer 107a, the coloring layer 107b, and the coloring layer 107c are formed in this order on the substrate 120, the formation order of the coloring layers 107 is not particularly limited.

### Structure Example 1-6

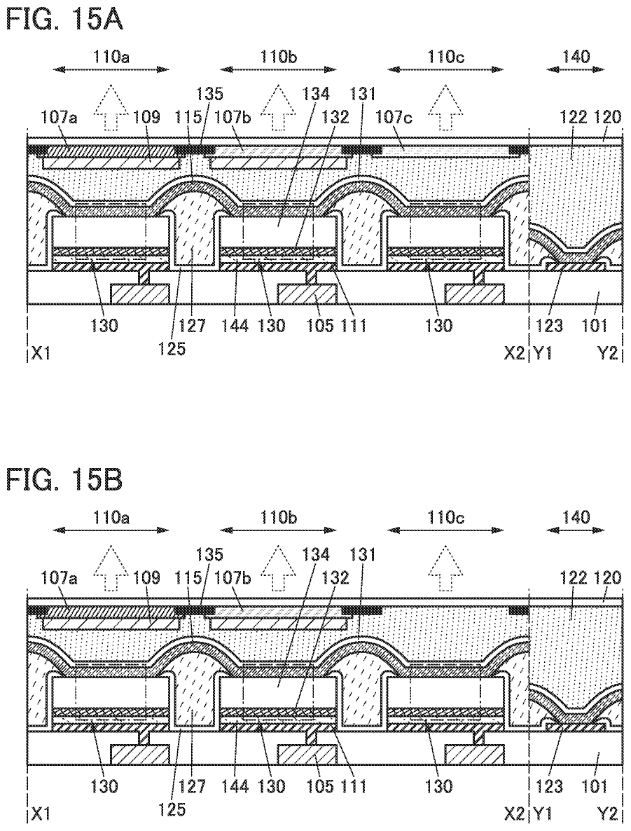

FIG. 15A is a cross-sectional view of a display apparatus of one embodiment of the present invention. FIG. 1A can be referred to for a top view.

As illustrated in FIG. 15A, a subpixel not provided with the color conversion layer 109 may be provided. A subpixel that emits light of a color in the shortest wavelength range can have a structure without the color conversion layer 109. The subpixel 110c illustrated in FIG. 15A does not include the color conversion layer 109, and light emitted from the light-emitting device 130 passes through the coloring layer 107c and is emitted to the outside of the display apparatus.

For example, in the case where red light is emitted from the subpixel 110a, green light is emitted from the subpixel 110b, and blue light is emitted from the subpixel 110c, the color conversion layer 109 is not necessarily provided in the subpixel 110c. The color conversion layers 109 provided in the subpixel 110a and the subpixel 110b may contain a color conversion material that emits yellow light. In the subpixel 110a provided with the coloring layer 107a transmitting red light, light emitted from the light-emitting device 130 passes through the color conversion layer 109 and the coloring layer 107a, whereby red light is emitted. Similarly, in the subpixel 110b provided with the coloring layer 107b transmitting green light, light emitted from the light-emitting device 130 passes through the color conversion layer 109 and the coloring layer 107b, whereby green light is emitted. In the subpixel 110c provided with the coloring layer 107c transmitting blue light, light emitted from the light-emitting device 130 passes through the coloring layer 107c, whereby blue light is emitted.

The light-blocking layer 135 is preferably provided between adjacent coloring layers 107. Providing the light-blocking layer 135 can block light emitted from the adjacent light-emitting device 130 and inhibit color mixture.

Note that as illustrated in FIG. 15B, the subpixel 110c may have a structure with no color conversion layer and no coloring layer.

### Structure Example 1-7

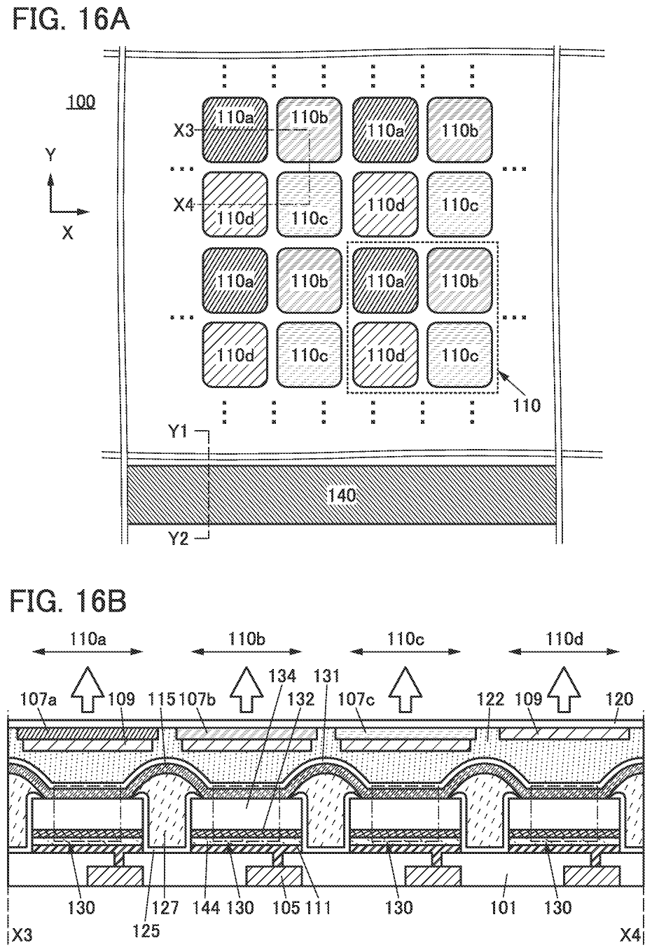

FIG. 16A illustrates a top view of a display apparatus 100 different from that in FIG. 1A. FIG. 16B is a cross-sectional view along a dashed-dotted line X3-X4 in FIG. 16A. FIG. 1B can be referred to for a cross-sectional view along the dashed-dotted line Y1-Y2.

The pixel 110 illustrated in FIG. 16A and FIG. 16B is composed of four subpixels: the subpixel 110a, the subpixel 110b, the subpixel 110c, and a subpixel 110d. The subpixel 110d can have a structure without the coloring layer 107.

For example, when the color conversion layer 109 contains a color conversion material that emits yellow light and the light-emitting device 130 emits blue light, white light is emitted from the color conversion layer 109. In the subpixel 110a provided with the coloring layer 107a transmitting red light, light emitted from the light-emitting device 130 passes through the color conversion layer 109 and the coloring layer 107a, whereby red light is emitted. Similarly, in the subpixel 110b provided with the coloring layer 107b transmitting green light, light emitted from the light-emitting device 130 passes through the color conversion layer 109 and the coloring layer 107b, whereby green light is emitted. In the subpixel 110c provided with the coloring layer 107c transmitting blue light, light emitted from the light-emitting device 130 passes through the color conversion layer 109 and the coloring layer 107c, whereby blue light is emitted. In the subpixel 110d not provided with the coloring layer, light emitted from the light-emitting device 130 passes through the color conversion layer 109, whereby white light is emitted.

With a structure including the subpixel 110d emitting white light, one color can be expressed by four subpixels of R (red), G (green), B (blue), and W (white). Such a structure allows a smaller amount of current to flow through the light-emitting device 130 than the structure in which one color is expressed by three subpixels of red (R), green (G), and blue (B), so that a display apparatus with low power consumption can be achieved.

This embodiment can be combined with the other embodiments as appropriate. In this specification, in the case where a plurality of structure examples are described in one embodiment, the structure examples can be combined as appropriate.

A method for manufacturing the display apparatus of one embodiment of the present invention will be described.

### Manufacturing Example 1

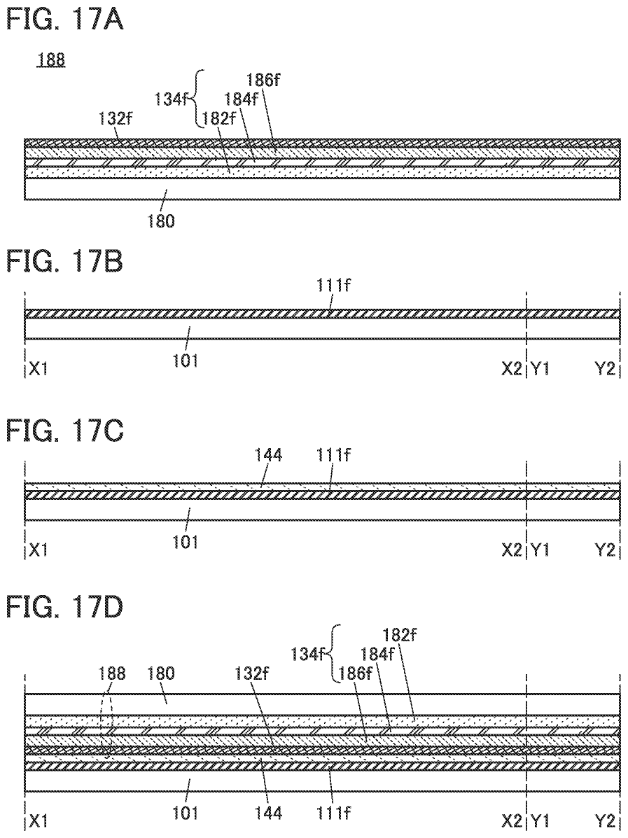

Here, a method for manufacturing the display apparatus illustrated in FIG. 12A is described with reference to FIG. 17A to FIG. 23C. FIG. 17B to FIG. 17D and FIG. 20A to FIG. 23C each illustrate a cross-sectional view along the dashed-dotted line X1-X2 and a cross-sectional view along the dashed-dotted line Y1-Y2 in FIG. 12A side by side. Note that in FIG. 17A to FIG. 23C, the transistor 105 illustrated in FIG. 12A is omitted.

Thin films included in the display apparatus (an insulating film, a semiconductor film, a conductive film, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method and a thermal CVD method. As an example of the thermal CVD method, a metal organic chemical vapor deposition (MOCVD) method can be given.

Alternatively, thin films included in the display apparatus (an insulating film, a semiconductor film, a conductive film, and the like) can be formed by a wet film formation method such as spin coating, dipping, spray coating, ink-jetting, dispensing, screen printing, offset printing, a doctor blade coating, slit coating, roll coating, curtain coating, or knife coating.

The thin films included in the display apparatus can be processed by a photolithography method or the like. Besides, a nanoimprinting method, a sandblasting method, or a lift-off method may be used for the processing of the thin films. Alternatively, island-shaped thin films may be directly formed by a film formation method using a shielding mask such as a metal mask.

There are the following two typical examples of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Alternatively, ultraviolet rays, KrF laser light, ArF laser light, or the like can be used. In addition, light exposure may be performed by liquid immersion exposure technique. As the light used for light exposure, extreme ultraviolet (EUV) light or X-rays may also be used. Instead of the light used for the light exposure, an electron beam can also be used. It is preferable to use EUV light, X-rays, or an electron beam because they can perform extremely minute processing. Note that a photomask is not needed when light exposure is performed by scanning with a beam such as an electron beam.

For etching of the thin films, for example, a dry etching method, a wet etching method, or sandblast method can be used.

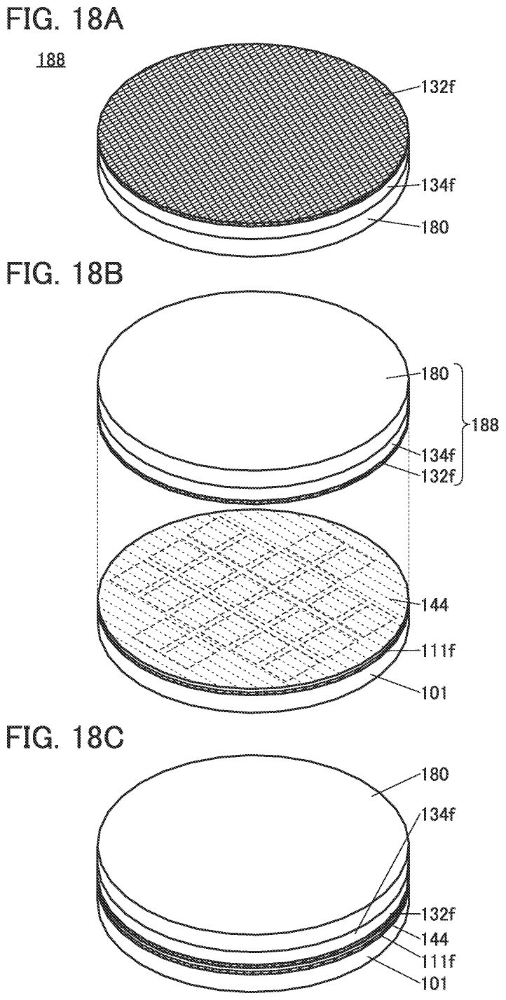

First, the formation of an LED substrate 188 illustrated in FIG. 17A and FIG. 18A is described. FIG. 17A is a cross-sectional view of the LED substrate 188, and FIG. 18A is a perspective view of the LED substrate 188. The LED substrate 188 includes an LED film 134f to be the LED layer 134 and a conductive film 132f to be the conductive layer 132.

Over the substrate 180, a semiconductor film 182f to be the semiconductor layer 182, a light-emitting film 184f to be the light-emitting layer 184, and a semiconductor film 186f to be the semiconductor layer 186 are formed. The semiconductor film 182f, the light-emitting film 184f, and the semiconductor film 186f can each be formed by epitaxial growth, for example. A solid phase epitaxy (SPE) method, a liquid phase epitaxy (LPE) method, and a vapor phase epitaxy (VPE) method are given as the method of epitaxial growth. In the case where a vapor phase epitaxial growth (VPE) method is employed, for example, the semiconductor film 182f, the light-emitting film 184f, and the semiconductor film 186f can be formed by a MOCVD method.

As the substrate 180, a single crystal substrate of a sapphire, silicon carbide, silicon, or a compound semiconductor can be used. The above-described compound containing the Group 13 element and the Group 15 element can be used as the compound semiconductor. The substrate 180 is preferably formed using a material having the same lattice constant as or slightly different lattice constant from a film included in the LED film 134f for the epitaxial growth of the LED film 134f. Note that a layer (also referred to as a buffer layer) in which a lattice distortion between the substrate 180 and the LED film 134f is reduced may be provided between the substrate 180 and the LED film 134f. Although the substrate 180 is shown in a circular shape in FIG. 18A, the shape of the substrate 180 is not particularly limited.

For example, when the light-emitting device 130 that emits blue light is formed, gallium nitride (GaN) can be used for the film included in the LED film 134f. In this case, a sapphire substrate can be used as the substrate 180, for example.

For example, when the light-emitting device 130 that emits red light is formed, gallium arsenide aluminum (AlGaAs) can be used for the film included in the LED film 134f. In this case, a gallium arsenide (GaAs) substrate or the like can be used as the substrate 180.

Next, the conductive film 132f is formed over the semiconductor film 186f. The conductive film 132f can be formed by a sputtering method or a vacuum evaporation method, for example. Alternatively, a film formed by an evaporation method and a film formed by a sputtering method may be stacked.

Next, a method for forming the light-emitting device 130 and the like over the layer 101 including transistors is described.

A conductive film 111f to be the conductive layer 111 is formed over the layer 101 including transistors (FIG. 17B). For formation of the conductive film 111f, a sputtering method or a vacuum evaporation method can be used, for example. Note that in FIG. 17B and the subsequent drawings, the transistors included in the layer 101 are omitted.

Next, the connection layer 144 is formed over the conductive film 111f (FIG. 17C).

Next, the above-described LED substrate 188 is bonded to the connection layer 144 (FIG. 17D). The connection layer 144 and the conductive film 132f are bonded to be in contact with each other. When the LED substrate 188 is bonded to the layer 101 in a state where the LED film 134f and the conductive film 132f are provided on an entire surface of the LED substrate 188, high accuracy is not necessary for the positional alignment of the LED substrate 188 and the layer 101, and accordingly the productivity can be increased. Alternatively, formation of an alignment marker can be omitted.

Although a structure in which the conductive film 132f and the conductive film 111f are electrically connected to each other through the connection layer 144 is described here, one embodiment of the present invention is not limited thereto. The conductive film 132f and the conductive film 111f may be directly bonded to each other. For example, copper is preferably used for the conductive film 132f and the conductive film 111f. In that case, it is possible to employ Cu—Cu direct bonding (a technique for establishing electrical continuity by connecting Cu (copper) pads to each other).

As illustrated in FIG. 18B and FIG. 18C, the shapes and sizes of the LED substrate 188 are equivalent to those of the layer 101, whereby bonding between the LED substrate 188 and the layer 101 can be facilitated. After the formation of the LED substrate 188, the LED substrate 188 may be divided and the divided LED substrates 188 may be attached to each other.

In FIG. 18B, a region to be the display apparatus is indicated by a dashed line over the connection layer 144. As illustrated in FIG. 18B, a plurality of display apparatuses can be provided on one layer 101. In addition, since a plurality of light-emitting devices can be formed in these display apparatuses when one LED substrate 188 is, bonded to the layer 101, the productivity of the display apparatus can be increased. Note that the number, the shape, and the position of the display apparatuses provided on the layer 101 are not limited to those in the region illustrated in FIG. 18B.

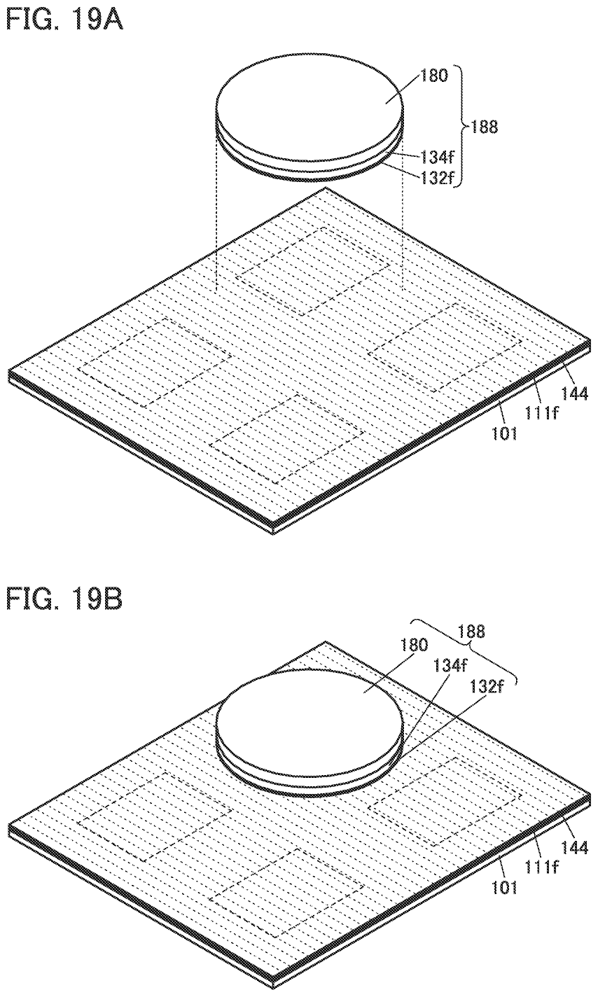

The shapes and sizes of the LED substrate 188 and the layer 101 may be different from each other. FIG. 19A and FIG. 19B each illustrate an example in which the LED substrate 188 has a circular shape, the layer 101 has a rectangular shape, and the size of the layer 101 is larger than the size of the LED substrate 188. Even in the case where the shapes and sizes of the LED substrate 188 and the layer 101 are different, with use of the LED substrate 188 whose size is larger than a region of one display apparatus, high accuracy alignment is not necessary between the LED substrate 188 and the layer 101, and accordingly the productivity can be increased. Although FIG. 19A and FIG. 19B illustrate an example in which the light-emitting device provided in one display apparatus is formed using one LED substrate 188, one embodiment of the present invention is not limited thereto. One LED substrate 188 may be used for forming light-emitting devices provided in a plurality of display apparatuses.

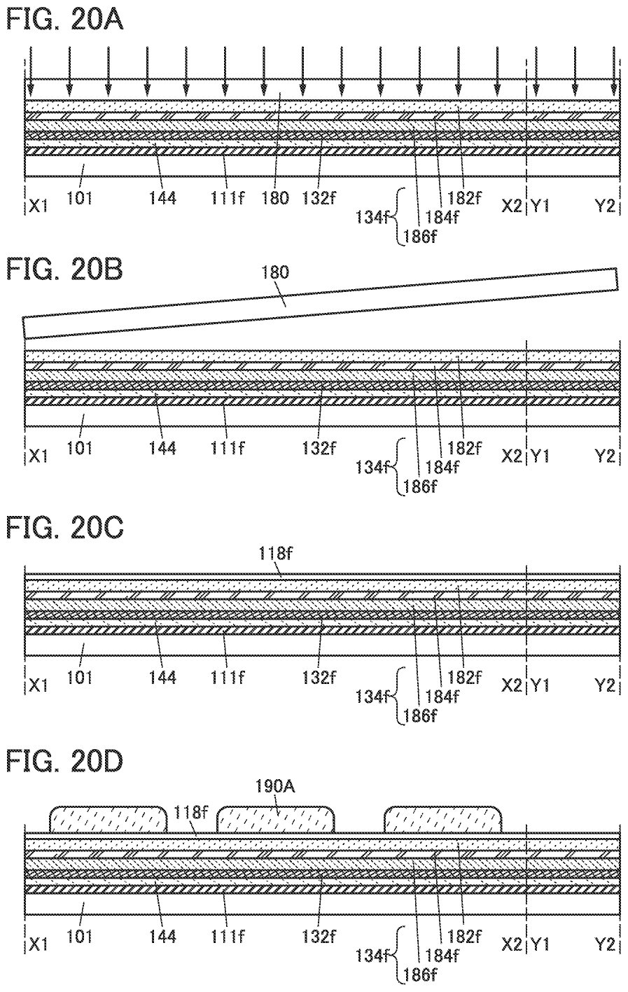

Next, the substrate 180 is separated and the LED film 134f is exposed (FIG. 20B). There is no particular limitation on the separation method of the substrate 180, and a laser lift off (LLO) method can be used, for example. In FIG. 20A, arrows schematically indicate lasers with which the substrate 180 is irradiated.

Note that a separation layer may be provided between the substrate 180 and the LED film 134f, and the substrate 180 may be separated from the LED film 134f using the separation layer. For example, a material that can be removed by a wet etching method can be used for the separation layer. For example, aluminum arsenide (AlAs) or the like can be used for the separation layer.

Next, a mask film 118f to be the mask layer 118 is formed over the LED film 134f (FIG. 20C). Although an example in which the mask film 118f is a single layer is described here, the mask film 118f may have a stacked-layer structure of two or more layers.

Provision of a mask film 118f over the LED film 134f can reduce damage to the LED film 134f in a manufacturing process of the display apparatus and increase the reliability of the light-emitting device 130.

As the mask film 118f, a film that is highly resistant to the processing conditions for the LED film 134f, specifically, a film having high etching selectivity with the LED film 134f is preferably used.

As the mask film 118f, a film that can be removed by a wet etching method is preferably used. Using a wet etching method can reduce damage to the LED film 134f in processing the mask film 118f, as compared to the case of using a dry etching method.

The mask film 118f can be formed by a sputtering method, an ALD method, a CVD method, or a vacuum evaporation method, for example. As an ALD method, a thermal ALD method or a PEALD method can be used, for example. An ALD method can be employed preferably for formation of the mask film 118f. The use of an ALD method can reduce damage to the LED film 134f at the time of forming the mask film 118f. Alternatively, the mask film 118f may be formed by a wet film formation process.

As the mask film 118f, one or more kinds of a metal film, an alloy film, a metal oxide film, a semiconductor film, an organic insulating film, and an inorganic insulating film can be used, for example.

For the mask film 118f, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver. The use of a metal material capable of blocking ultraviolet light for the mask film 118f is preferable, in which case ultraviolet light can be inhibited from entering the LED film 134f in the manufacturing process so that deterioration of the LED film 134f can be inhibited.

For the mask film 118f, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be used.

As the mask film 118f, a film containing a material having a light-blocking property, particularly with respect to ultraviolet light, can be used. For example, a film having a reflecting property with respect to ultraviolet light or a film absorbing ultraviolet light can be used. Although a variety of materials, such as a metal having a light-blocking property with respect to ultraviolet light, an insulator, a semiconductor, and a metalloid, can be used as the material having a light-blocking property, a film that can be processed by etching is preferable, and a film having good processability is particularly preferable because part or the whole of the mask film is removed in a later step.

For example, a semiconductor material such as silicon or germanium can be used as a material with a high affinity for the semiconductor manufacturing process. Alternatively, an oxide or a nitride of the semiconductor material can be used. Alternatively, a non-metallic (metalloid) material such as carbon or a compound thereof can be used. Alternatively, a metal, such as titanium, tantalum, tungsten, chromium, or aluminum, or an alloy containing one or more of them can be given. Alternatively, an oxide containing the above-described metal, such as titanium oxide or chromium oxide, or a nitride such as titanium nitride, chromium nitride, or tantalum nitride can be used.

When a film containing a material having a light-blocking property with respect to ultraviolet light is used as the mask film 118f, the LED film 134f can be inhibited from being irradiated with ultraviolet light in a light exposure step, for example. When the LED film 134f is inhibited from being damaged by ultraviolet light, the reliability of the light-emitting device can be improved.

Note that the same effect is obtained when a film containing a material having a light-blocking property with respect to ultraviolet light is used for an insulating film 125f to be described later.

For the mask film 118f, any of a variety of inorganic insulating films that can be used as the protective layer 131 can be used. In particular, an oxide insulating film is preferable because its adhesion to the LED film 134f is higher than that of a nitride insulating film. For example, aluminum oxide, hafnium oxide, or silicon oxide can be used preferably for the mask film 118f. As the mask film 118f, an aluminum oxide film can be formed by an ALD method, for example. The use of an ALD method is preferable because damage to a base (in particular, the LED film 134f) can be reduced.

Note that the same inorganic insulating film can be used for both the mask film 118f and the insulating layer 125 that is to be formed later. For example, an aluminum oxide film formed by an ALD method can be used for both the mask film 118f and the insulating layer 125. Here, for the mask film 118f and the insulating layer 125, the same film formation condition may be used or different film formation conditions may be used. For example, when the mask film 118f is formed under conditions similar to those for the insulating layer 125, the mask film 118f can be an insulating layer having a high barrier property against at least one of water and oxygen. Meanwhile, the mask film 118f is a layer most or all of which is to be removed in a later step, and thus is preferably easily processed. Therefore, the mask film 118f is preferably formed at a substrate temperature lower than that in formation of the insulating layer 125.

An organic material may be used for the mask film 118f. For example, as the organic material, a material that can be dissolved in a solvent chemically stable with respect to at least the uppermost film of the LED film 134f may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the LED film 134f can be accordingly reduced.

For each of the mask film 118f, a resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin such as perfluoropolymer may be used.

Note that as described in Embodiment 1, part of the mask film 118f sometimes remains as the mask layer 118 in the display apparatus of one embodiment of the present invention.

Next, a resist mask 190A is formed over the mask film 118f (FIG. 20D). The resist mask 190A is formed in a region where the LED layer 134 is provided. The resist mask 190A can be formed by application of a photosensitive resin (photoresist), exposure, and development. The resist mask 190A may be formed using either a positive resist material or a negative resist material.

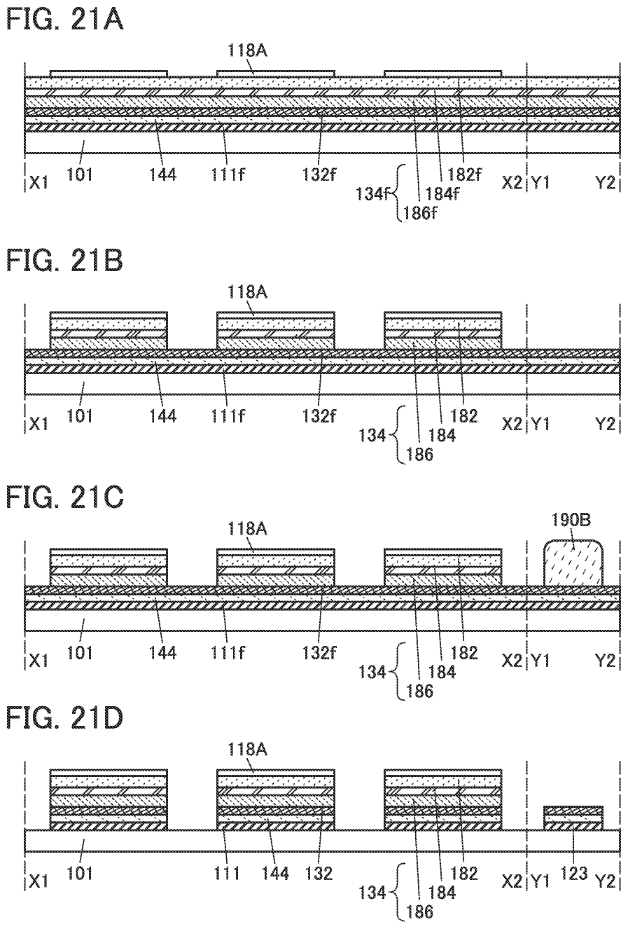

Next, part of the mask film 118f is removed with use of the resist mask 190A as a mask, so that a mask layer 118A is formed (FIG. 21A). The mask layer 118A is formed in a region where the LED layer 134 is provided and functions as a hard mask at the time of forming the LED layer 134. After that, the resist mask 190A is removed.

The mask film 118f can be processed by a wet etching method or a dry etching method. Anisotropic etching can be suitably used for the processing of the mask film 118f.

Using a wet etching method for processing the mask film 118f can reduce damage to the LED film 134f in processing the mask film 118f, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution containing a mixed solution of any of these acids, for example.

In the case of using a dry etching method for processing the mask film 118f, deterioration of the LED film 134f can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas (also referred to as a rare gas) such as He as the etching gas, for example.

For example, when an aluminum oxide film formed by an ALD method is used as the mask film 118f, the mask film 118f can be processed by a dry etching method using CHF₃ and He or CHF₃, He, and CH₄. In the case where an In—Ga—Zn oxide film formed by a sputtering method is used as the mask film 118f, the mask film 118f can be processed by a wet etching method using a diluted phosphoric acid. Alternatively, the mask film 118f may be processed by a dry etching method using CH₄ and Ar. Alternatively, the mask film 118f can be processed by a wet etching method using a diluted phosphoric acid. When a tungsten film formed by a sputtering method is used as the mask film 118f, the mask film 118f can be processed by a dry etching method using SF₆, CF₄, and O₂ or CF₄, Cl₂, and O₂.

The resist mask 190A can be removed by ashing using oxygen plasma, for example. Alternatively, an oxygen gas and any of CF₄, C₄F₈, SF₆, CHF₃, Cl₂, H₂O, BCl₃, and a noble gas such as He may be used. Alternatively, the resist mask 190A may be removed by wet etching. At this time, the LED film 134f is not exposed in a region where the mask layer 118A is formed; thus, the LED film 134f can be inhibited from being damaged in the step of removing the resist mask 190A. In addition, the range of choices of the method for removing the resist mask 190A can be widened. Note that the resist mask 190A may remain without removal.

Next, part of the LED film 134f is removed using the mask layer 118A as a mask, so that the LED layer 134 is formed and the conductive film 132f is exposed (FIG. 21B).

The LED film 134f can be processed by one or both of a wet etching method and a dry etching method. Anisotropic etching can be suitably used for processing the LED film 134f. With use of anisotropic etching, the distance between adjacent LED layers 134 can be small. The angle formed by the top surface of the layer 101 and the side surface of the LED layer 134 is preferably perpendicular or substantially perpendicular. The angle formed by the top surface of the layer 101 and the side surface of the LED layer 134 is preferably greater than or equal to 60° and less than or equal to 90°, further preferably greater than or equal to 70° and less than or equal to 90°, still further preferably greater than or equal to 80° and less than or equal to 90°. When the angle formed by the top surface of the layer 101 and the side surface of the LED layer 134 is perpendicular or substantially perpendicular, the aperture ratio of the pixel can be increased.

Then, a resist mask 190B is formed over the conductive film 132f (FIG. 21C). The resist mask 190B is formed in a region where the conductive layer 123 is provided. The description of formation of the resist mask 190A can be referred to for the formation of the resist mask 190B; thus, the detailed description is omitted.

Next, parts of the conductive film 132f, the connection layer 144, and the conductive film 111f are removed using the mask layer 118A and the resist mask 190B as a mask, so that the conductive layer 132, the connection layer 144, the conductive layer 111, and the conductive layer 123 are formed. After that, the resist mask 190B is removed (FIG. 21D). The removal of the resist mask 190B can be performed by one or both of a wet etching method and a dry etching method.

Thus, a stacked-layer structure of the connection layer 144, the conductive layer 132, the LED layer 134, and the mask layer 118A is formed over the conductive layer 111. A stacked-layer structure of the connection layer 144 and the conductive layer 132 is formed over the conductive layer 123. Note that the mask layer 118A may be removed.

It is preferable that the end portions of the LED layer 134, the conductive layer 132, the connection layer 144, and the conductive layer 111 be aligned or substantially aligned with each other. At least preferably, the end portions of the LED layer 134 and the conductive layer 132 are aligned or substantially aligned with each other. FIG. 21D illustrates an example in which the end portions of the LED layer 134, the conductive layer 132, the connection layer 144, and the conductive layer 111 are aligned with the end portion of the mask layer 118A. A pixel with such a structure can have a high aperture ratio. Note that one or more end portions of the LED layer 134, the conductive layer 132, the connection layer 144, and the conductive layer 111 may be positioned outside the end portion of the mask layer 118A or positioned inward from the end portion of the mask layer 118A. Although not illustrated, a depressed portion is sometimes formed in a region of the layer 101 that does not overlap with the conductive layer 111 or the conductive layer 123 by the etching treatment.

The side surface of the LED layer 134 is preferably perpendicular or substantially perpendicular to the top surface of the layer 101. For example, the angle formed by the top surface of the layer 101 and the side surface of the LED layer 134 is preferably greater than or equal to 60° and less than or equal to 90°.

As described above, the distance between adjacent two LED layers 134 formed by a photolithography method can be shortened to less than or equal to 8 μm, less than or equal to 5 μm, less than or equal to 3 μm, less than or equal to 2 μm, or less than or equal to 1 μm. Here, the distance can be specified by the distance between facing end portions of two adjacent LED layers 134, for example. The distance between the island-shaped LED layers 134 is shortened in this manner, whereby a display apparatus with high resolution and a high aperture ratio can be provided.

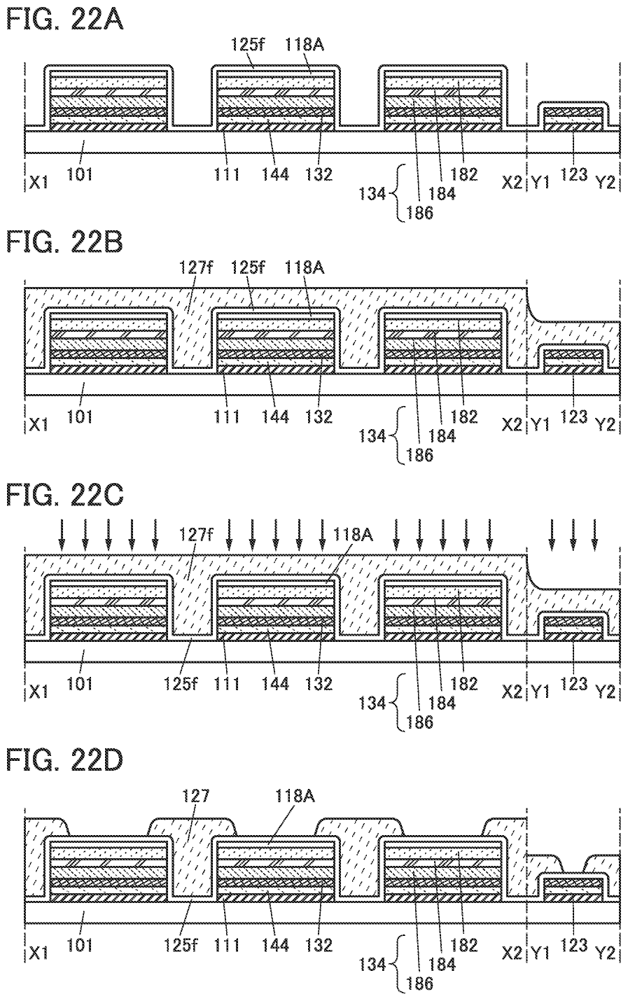

Next, the insulating film 125f to be the insulating layer 125 is formed to cover the conductive layer 111, the connection layer 144, the conductive layer 132, the LED layer 134, and the mask layer 118A (FIG. 22A).

Then, a filling film 127f to be the filling layer 127 later is formed over the insulating film 125f (FIG. 22B).

The insulating film 125f and the filling film 127f are preferably formed by a formation method that causes less damage to the LED layer 134. In particular, the insulating film 125f, which is formed in contact with the side surface of the LED layer 134, is preferably formed by a formation method that causes less damage to the LED layer 134 than the formation method of the filling film 127f.

The insulating film 125f and the filling film 127f are formed at a temperature lower than the upper temperature limit of the components of the layer 101, the conductive layer 111, the connection layer 144, the conductive layer 132, and the LED layer 134. Since the upper temperature limit of the LED layer 134 using an inorganic material is high, the insulating film 125f and the filling film 127f can be formed at a temperature lower than the upper temperature limit of the components of the layer 101, the conductive layer 111, the connection layer 144, and the conductive layer 132. When the substrate temperature at the time when the insulating film 125f is formed is increased, the formed insulating film 125f, even with a small thickness, can have a low impurity concentration and a high barrier property against at least one of water and oxygen.

The insulating film 125f A and the filling film 127f are preferably formed at a substrate temperature higher than or equal to 60° C., higher than or equal to 100° C., higher than or equal to 200° C., higher than or equal to 250° C., or higher than or equal to 300° C. and lower than or equal to 600° C., lower than or equal to 550° C., lower than or equal to 500° C., or lower than or equal to 450° C.

As the insulating film 125f, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. The use of an ALD method is preferable because damage due to film formation can be reduced and a film with good coverage can be formed. As the insulating film 125f, an aluminum oxide film is preferably formed by an ALD method, for example.

Alternatively, the insulating film 125f may be formed by a sputtering method, a CVD method, or a PECVD method that provides a higher film formation speed than an ALD method. In this case, a highly reliable display apparatus can be manufactured with high productivity.

The filling film 127f is preferably formed by the aforementioned wet film formation method. For example, the filling film 127f is preferably formed by spin coating using a photosensitive resin, specifically, a photosensitive acrylic resin.

Heat treatment (also referred to as prebaking) is preferably performed after the filling film 127f is formed. The heat treatment is performed at a temperature lower than the upper temperature limit of the filling film 127f. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the filling film 127f can be removed.

Next, part of the filling film 127f is exposed to visible light or ultraviolet rays. In the case where a positive acrylic resin is used for the filling film 127f, a region where the filling layer 127 is not formed is irradiated with visible light or ultraviolet rays. In FIG. 22C, light used for exposure is schematically illustrated as arrows.

Note that the width of the filling layer 127 to be formed later can be controlled by the region exposed to light here. In this embodiment, light exposure is performed so that the filling layer 127 includes a region overlapping with the top surface of the LED layer 134. The filling layer 127 does not necessarily include a portion overlapping with the top surface of the LED layer 134.

Light used for light exposure preferably includes the i-line (wavelength: 365 nm). The light used for light exposure may include at least one of the g-line (wavelength: 436 nm) and the h-line (wavelength: 405 nm).

Although an example described here is such that a positive photosensitive resin is used for the filling film 127f and a region where the filling layer 127 is not formed is irradiated with visible light or ultraviolet rays, one embodiment of the present invention is not limited thereto. For example, a structure may be employed in which a negative photosensitive resin is used for the filling film 127f. In this case, a region where the filling layer 127 is formed is irradiated with visible light or ultraviolet rays.

Next, development is performed to remove the region exposed to light in the filling film 127f, so that the filling layer 127 is formed (FIG. 22D). The filling layer 127 is formed in a region sandwiched between two LED layers 134 and around the conductive layer 123. Here, in the case where an acrylic resin is used for the filling film 127f, an alkaline solution is preferably used as a developer, and for example, an aqueous solution of tetramethyl ammonium hydroxide (TMAH) can be used.

Then, a residue (what is called scum) due to the development may be removed. For example, the residue can be removed by ashing using oxygen plasma.

In this step, etching may be performed to adjust the level of the top surface of the filling layer 127. The filling layer 127 may be processed by ashing using oxygen plasma, for example. In the case where a non-photosensitive material is used for the filling film 127f, the surface level of the filling layer 127 can be adjusted by the ashing, for example.

Next, light exposure may be performed on the entire substrate so that the filling layer 127 is irradiated with visible light or ultraviolet light. The energy density for the light exposure is preferably greater than 0 mJ/cm² and less than or equal to 800 mJ/cm², further preferably greater than 0 mJ/cm² and less than or equal to 500 mJ/cm². Performing such light exposure after development can improve the transparency of the filling layer 127 in some cases. In addition, it is sometimes possible to lower the substrate temperature required for heat treatment in a later step for changing the shape of the filling layer 127 into a tapered shape.

In contrast, as described later, when light exposure is not performed on the filling layer 127, the shape of the filling layer 127 can be easily changed or the filling layer 127 can be easily changed into a tapered shape in a later step in some cases. Thus, sometimes it is preferable not to perform light expose on the filling layer 127 after the development.

For example, in the case where a photocurable resin is used as a material of the filling layer 127, performing light exposure on the filling layer 127 can start polymerization and cure the filling layer 127. Note that without performing light exposure on the filling layer 127 at this stage, at least one of after-mentioned first etching treatment, post-baking, and second etching treatment may be performed while the filling layer 127 remains in a state where its shape is relatively easily changed. Thus, generation of unevenness in the formation surface of the conductive layer 115 can be inhibited and step disconnection of the conductive layer 115 can be inhibited. After any of the later-described first etching treatment, post-baking, and second etching treatment, light exposure may be performed on the filling layer 127.

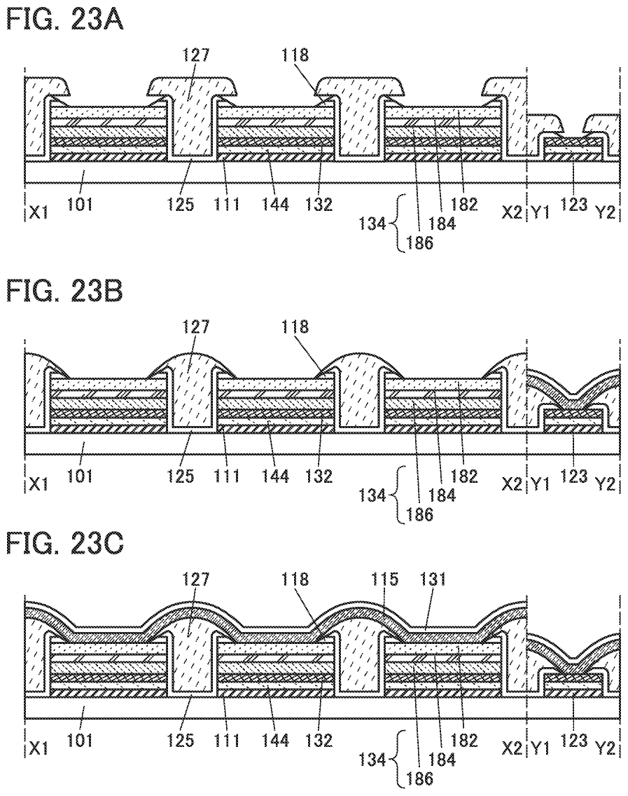

Next, etching treatment is performed using the filling layer 127 as a mask to remove part of the insulating film 125f and part of the mask layer 118A, so that the insulating layer 125 and the mask layer 118 are formed (FIG. 23A). Accordingly, the top surface of the LED layer 134 is exposed.

A dry etching method or a wet etching method can be used for the etching treatment. Note that in the case where a material similar to that for the mask layer 118A is used for the insulating film 125f, etching of the insulating film 125f and etching of the mask layer 118A can be performed concurrently, which is preferable.

As illustrated in FIG. 23A, etching is performed using the filling layer 127 with a tapered side surface as a mask, so that the side surface of the insulating layer 125 and the upper end portion of the side surface of the mask layer 118 can be tapered relatively easily.

In the case where dry etching is used for the formation of the insulating layer 125 and the mask layer 118, a chlorine-based gas is preferably used. As the chlorine-based gas, Cl₂, BCl₃, SiCl₄, CCl₄, or the like can be used alone or two or more of the gases can be mixed and used. Moreover, one or more of an oxygen gas, a hydrogen gas, a helium gas, an argon gas, and the like can be mixed with the chlorine-based gas as appropriate. By employing dry etching, the thin region of the mask layer 118 can be formed with a favorable in-plane uniformity.

A dry etching apparatus including a high-density plasma source can be used as the dry etching apparatus. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes.

In the case of performing dry etching, a by-product or the like generated by the dry etching is sometimes deposited on the top surface and the side surface of the filling layer 127, for example. Thus, a component contained in the etching gas, a component contained in the insulating film 125, components contained in the mask layer 118, or the like might be contained in the filling layer 127 of the display apparatus that has been fabricated.

The insulating layer 125 and the mask layer 118 are preferably formed by a wet etching method. Using a wet etching method can reduce damage to the LED layer 134, as compared to the case of using a dry etching method. For example, the wet etching can be performed using an alkaline solution or the like. For example, for wet etching of an aluminum oxide film, it is preferable to use an aqueous solution of tetramethyl ammonium hydroxide (TMAH) that is an alkaline solution. In this case, the wet etching can be performed by a puddle method. Note that in the case where a material similar to that for the mask layer 118A is used for the insulating film 125f, the insulating film 125f and the mask layer 118A can be subjected to etching treatment concurrently, which is preferable.

After that, heat treatment (also referred to as post-baking) is performed. By performing the heat treatment, the side surface of the filling layer 127 can be changed into a tapered shape (FIG. 23B). The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced pressure atmosphere. Employing a reduced pressure atmosphere is preferable, in which case drying at a lower temperature is possible. The heat treatment in this step is preferably performed at a higher substrate temperature than the heat treatment (pre-baking) after the formation of the filling film 127f. In this case, the adhesion between the filling layer 127 and the insulating layer 125 and the corrosion resistance of the filling layer 127 can be improved.

By performing heat treatment after part of the LED layer 134 is exposed, water contained in the LED layer 134 and water adsorbed on the surface of the LED layer 134 can be removed. By performing the heat treatment in a reduced pressure atmosphere, water can be removed at a lower temperature.

As described above, providing the filling layer 127, the insulating layer 125, and the mask layer 118 can inhibit the conductive layer 115 from having, between the light-emitting devices 130, connection defects due to a disconnected portion and an increase in electric resistance due to a locally thinned portion of the conductive layer 115. Accordingly, the display apparatus can have high display quality.

Next, the conductive layer 115 and the protective layer 131 are formed in this order over the filling layer 127 and the LED layer 134 (FIG. 23C).

The conductive layer 115 can be formed by a sputtering method or a vacuum evaporation method, for example. Alternatively, a film formed by an evaporation method and a film formed by a sputtering method may be stacked.

The protective layer 131 can be formed by a vacuum evaporation method, a sputtering method, a CVD method, or an ALD method, for example.

Next, the substrate 120 provided with the coloring layer 107 and the color conversion layer 109 is bonded to the protective layer 131 with the resin layer 122, whereby manufacturing the display apparatus can be completed (FIG. 12A).

The coloring layer 107 can be formed by a lithography method, for example. By processing the photosensitive resin by a lithography method, the coloring layer 107 can be formed.

The color conversion layer 109 can be formed by a droplet discharge method (e.g., an inkjet method), a coating method, an imprinting method, or a printing method (screen printing or offset printing). A color conversion film (e.g., a quantum dot film) may be used for the color conversion layer 109.

The color conversion layer 109 may be formed by a lithography method. For example, a method can be employed in which a resist mask is formed over a film that is to be the color conversion layer 109, the film is processed by etching or the like, and then the resist mask is removed. Alternatively, after a photosensitive film is formed, light exposure and development may be performed on the photosensitive film so that the color conversion layer 109 with a desired shape is formed. For example, a film is formed using a photosensitive material in which a color conversion material is mixed, and the film is processed by a lithography method, whereby an island-shaped color conversion layer 109 can be formed.

As described above, in the method for manufacturing a display apparatus of this embodiment, a film to be the LED layer 134 is formed on an entire surface of a display region and then processed into the island-shaped LED layers 134; accordingly, a high-resolution display apparatus or a display apparatus with a high aperture ratio can be achieved. Furthermore, even when the resolution or the aperture ratio is high and the distance between subpixels is extremely short, contact between the LED layers 134 in adjacent subpixels can be inhibited. Accordingly, generation of a leakage current between subpixels can be inhibited. This can prevent crosstalk due to unintended light emission, so that a display apparatus with extremely high contrast can be achieved.

Provision of the filling layer 127 having a tapered end portion between adjacent island-shaped LED layers 134 can inhibit formation of step disconnection and prevent formation of a locally thinned portion in the conductive layer 115 at the time of forming the conductive layer 115. This can inhibit the conductive layer 115 from having connection defects due to the disconnected portion and an increased electric resistance due to the locally thinned portion. Hence, the display apparatus of one embodiment of the present invention achieves both high resolution and high display quality.

This embodiment can be combined with the other embodiments as appropriate.

### Embodiment 2

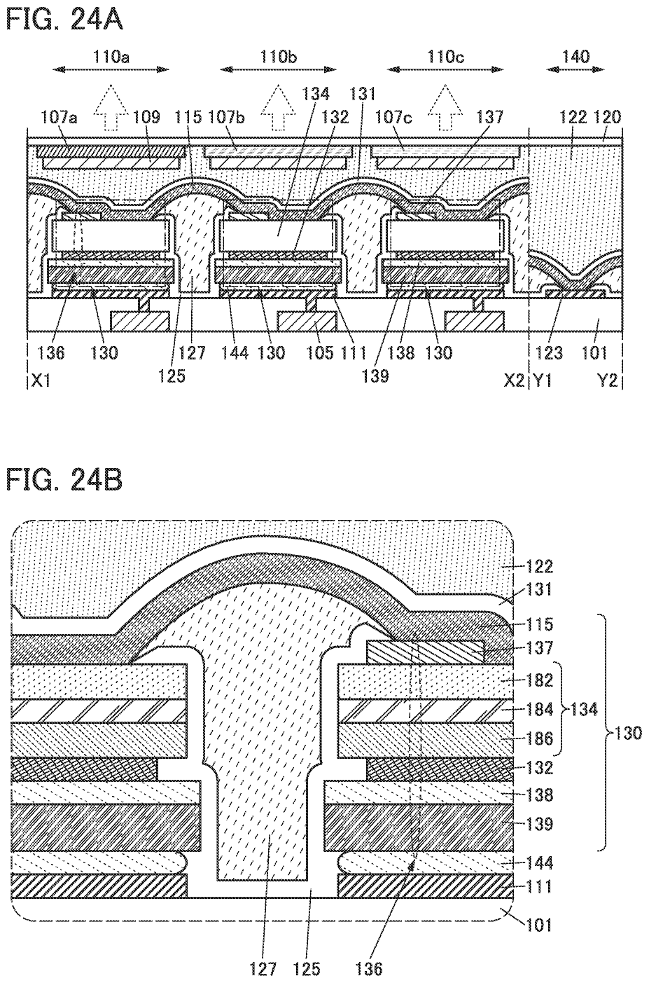

Examples of structures different from those of the display apparatus described in the above embodiment will be described with reference to FIG. 24 to FIG. 30. In the following description, the description of portions overlapping with those in the above embodiment are omitted in some cases. Furthermore, in drawings that are referred to later, the same hatching pattern is applied to portions having functions similar to those in the above embodiment, and the portions are not denoted by reference numerals in some cases.

### Structure Example 2-1

FIG. 24A is a cross-sectional view of a display apparatus of one embodiment of the present invention. FIG. 1A can be referred to for a top view. FIG. 24B is an enlarged view of part of the cross-sectional view illustrated in FIG. 24A.

The display apparatus illustrated in FIG. 24A and the like is different from the display apparatus described in Embodiment 1 mainly in that a light-emitting diode including a pair of electrodes (hereinafter also referred to as an LED chip) is provided between the conductive layer 111 and the conductive layer 115. An LED chip 136 provided between the conductive layer 111 and the conductive layer 115 includes the conductive layer 132, the LED layer 134 over the conductive layer 132, a conductive layer 137 over the LED layer 134, a connection layer 138, and a substrate 139. The conductive layer 132 and the conductive layer 137 each function as an electrode of the LED chip 136. The LED layer 134 is sandwiched between the pair of electrodes (the conductive layer 132 and the conductive layer 137). The LED chip 136 can be referred to as a light-emitting diode having what is called a vertical structure, in which the conductive layer 132 and the conductive layer 137 are provided on one surface and the surface opposite thereto of the LED layer 134.

Each of the connection layer 138 and the substrate 139 can be formed using a conductive material. The conductive layer 132 is electrically connected to the substrate 139 through the connection layer 138. For the connection layer 138, a material that can be used for the connection layer 144 can be used. As the substrate 139, for example, a conductive silicon substrate, a silicon carbide (SiC) substrate, a gallium arsenide (GaAs) substrate, a metal substrate, or an alloy substrate can be used. An example of the metal substrate is a substrate including one or more of tungsten, copper, gold, nickel, and titanium. An example of the alloy substrate is a Si—Al alloy substrate. The substrate 139 is electrically connected to the conductive layer 111 through a connection layer 144. It can be said that the conductive layer 132, the connection layer 138, the substrate 139, the connection layer 144, and the conductive layer 111 collectively function as a pixel electrode. Note that electrical connection between the conductive layer 111 and the substrate 139 may be formed by making the conductive layer 111 and the substrate 139 in direct contact with each other without providing the connection layer 144.

The conductive layer 115 is provided over the conductive layer 137. Note that FIG. 24A and FIG. 24B illustrate an example in which the end portion of the conductive layer 137 is positioned inward from the end portion of the LED layer 134. The conductive layer 111 includes a region in contact with the top surface and the side surface of the conductive layer 137 and the top surface of the LED layer 134. The insulating layer 125 includes a region in contact with part of the top surface and the side surface of the conductive layer 137 and part of the top surface and the side surface of the LED layer 134. The insulating layer 125 covers the end portion of the conductive layer 137 and the end portion of the LED layer 134, and the filling layer 127 is provided over the insulating layer 125. The conductive layer 115 is provided over the LED chip 136 and the filling layer 127.

Providing the insulating layer 125 and the filling layer 127 can reduce a level difference generated between a region where the LED chip 136 is provided and a region where the LED chip 136 is not provided. Thus, unevenness of the formation surface of the conductive layer 115 functioning as a common electrode can be reduced, so that coverage with the conductive layer 115 can be improved. Consequently, a connection defect due to disconnection of the conductive layer 115 can be inhibited. Moreover, an increase in electric resistance due to local thinning of the conductive layer 115 by the level difference can be inhibited.

Note that the insulating layer 125 may have a structure not covering the end portion of the conductive layer 137. The insulating layer 125 preferably covers at least the side surface of the LED layer 134.

In the case where a material with low light transmittance is used for one or more of the conductive layer 132 and the substrate 139, the LED chip 136 emits light toward the conductive layer 137 side. That is, the display apparatus illustrated in FIG. 24A and FIG. 24B can have a top emission structure. For the conductive layer 115, a material having a high transmitting property with respect to light is preferably used. In FIG. 24A illustrating an example of a top emission structure, white blank arrows schematically indicate light emitted from the substrate 120 side. In the case where a material with low light transmittance is used for the conductive layer 137, a region where the conductive layer 137 is provided has a small contribution to light emission. Therefore, the area of the region where the conductive layer 137 is provided is preferably small. Although one conductive layer 137 is illustrated in FIG. 24A and the like, the number, the shape, and the size of the conductive layer 137 are not particularly limited.

### Structure Example 2-2

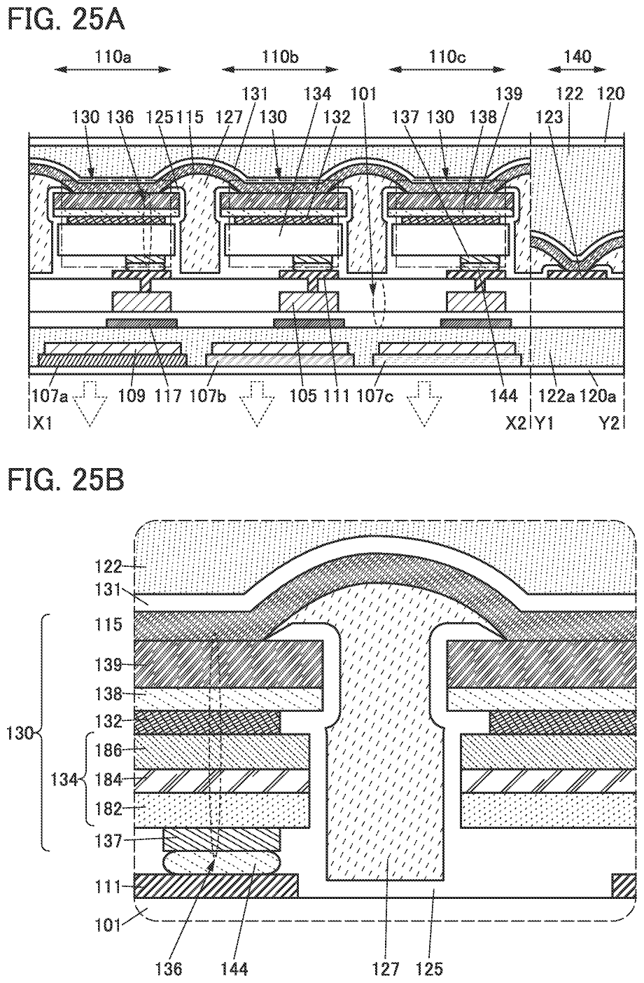

FIG. 25A is a cross-sectional view of a display apparatus of one embodiment of the present invention. FIG. 1A can be referred to for a top view. FIG. 25B is an enlarged view of part of the cross-sectional view illustrated in FIG. 25A.

The display apparatus illustrated in FIG. 25A and FIG. 25B is different from the display apparatus described in <Structure example 2-1> mainly in that the conductive layer 137 included in the LED chip 136 is provided over the connection layer 144 and the conductive layer 115 is provided over the substrate 139.

A substrate 120a is bonded to a surface of the layer 101, which is opposite to the surface where the LED chip 136 is provided, with an adhesive layer 122a. For each of the conductive layer 115, the substrate 120, and the adhesive layer 122a, a material having a high visible-light-transmitting property is preferably used. The coloring layer 107 and the color conversion layer 109 are provided for the substrate 120a. Light emitted from the LED chip 136 passes through the layer 101, the adhesive layer 122a, the color conversion layer 109, the coloring layer 107, and the substrate 120a. The display apparatus illustrated in FIG. 25A and FIG. 25B can have a bottom emission structure. In FIG. 25A illustrating an example of a bottom emission structure, white blank arrows schematically indicate light emitted from the substrate 120a side.

The layer 101 is preferably provided with a light-blocking layer 117. The light-blocking layer 117 is provided between the substrate 120a and the transistor 105 to block light from reaching the transistor 105 from the outside of the display apparatus, whereby deterioration of the transistor 105 due to the light can be inhibited and a highly reliable display apparatus can be obtained.

### Manufacturing Example 2

A method for manufacturing the display apparatus illustrated in FIG. 24A will be described.

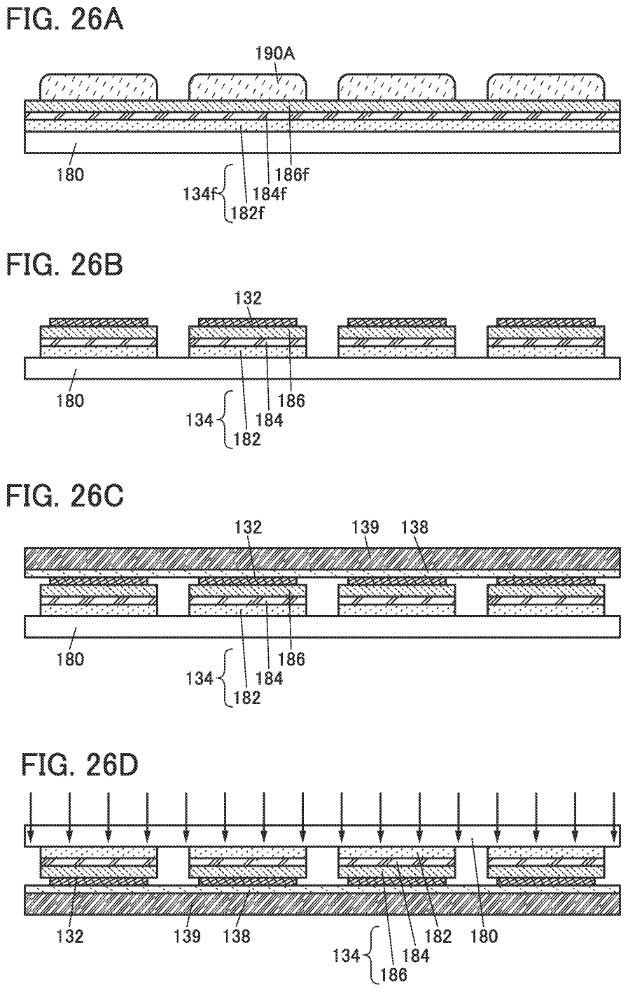

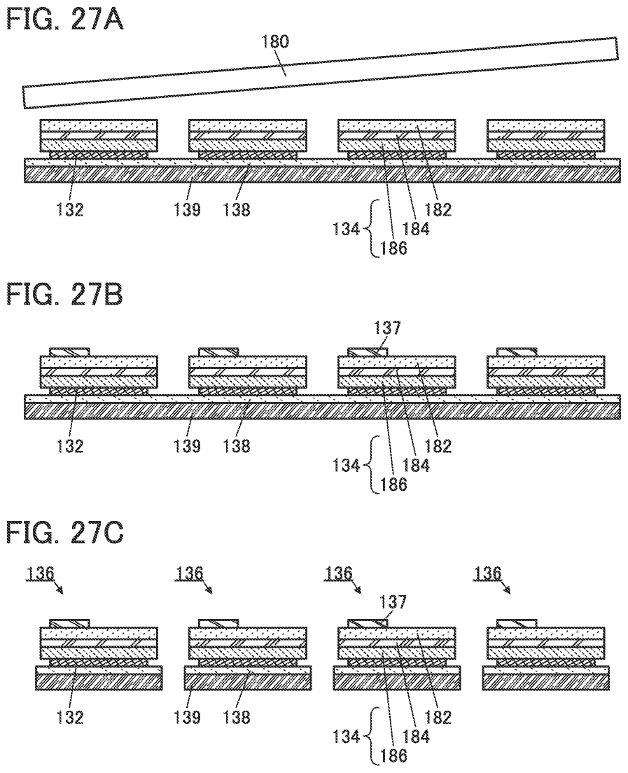

First, the formation of the LED chip 136 is described with reference to FIG. 26A to FIG. 27C. FIG. 26A to FIG. 27C are each a cross-sectional view of the formation of the LED chip 136.

An LED film 134f is formed over the substrate 180. The description of FIG. 17A can be referred to for the formation of the LED film 134f; thus, the detailed description thereof is omitted.

Next, the resist mask 190A is formed over the LED film 134f (FIG. 26A).

Next, part of the LED film 134f is removed using the resist mask 190A as a mask, so that the island-shaped LED layer 134 is formed. The resist mask 190A is removed, and the conductive layer 132 is formed over the LED layer 134 (FIG. 26B).

Next, the substrate 139 where the connection layer 138 is formed is bonded to the conductive layer 132 (FIG. 26C).

Next, the substrate 180 is separated and the LED layer 134 is exposed (FIG. 27A). There is no particular limitation on the separation method of the substrate 180, and a laser lift off (LLO) method can be used, for example. In FIG. 26D, arrows schematically indicate the laser with which the substrate 180 is irradiated.

Next, the conductive layer 137 is formed over the LED layer 134 (FIG. 27B).

Next, the connection layer 138 and the substrate 139 are divided into LED chips 136 separated from each other (FIG. 27C). There is no particular limitation on the dividing method of the connection layer 138 and the substrate 139, and a dicing method or a scribing method can be used, for example. Although four LED chips 136 formed using one substrate 180 are illustrated in FIG. 27C and the like, the number of LED chips 136 formed using one substrate 180 is not particularly limited.

The area of a light-emitting region of the LED chip 136 is preferably less than or equal to 1 mm², further preferably less than or equal to 10000 μm², still further preferably less than or equal to 3000 μm², even further preferably less than or equal to 700 μm². The area of the region is preferably greater than or equal to 1 μm², further preferably greater than or equal to 10 μm², still further preferably greater than or equal to 100 μm². Note that in this specification and the like, a light-emitting diode in which the area of a light-emitting region is less than or equal to 10000 μm² is referred to as a micro-LED in some cases.

Note that the LED chip that can be used for the display apparatus of one embodiment of the present invention is not limited to the above-described micro LED. For example, an LED chip having a light-emitting area of greater than 10000 μm² (also referred to as a mini LED) may be used.

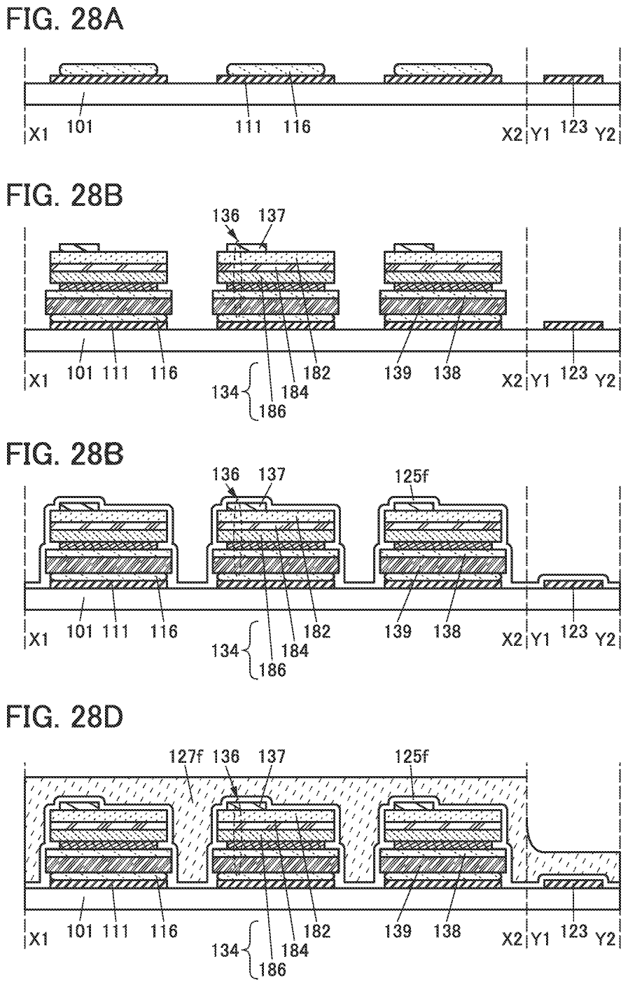

Next, a method for manufacturing a display apparatus including the LED chip 136 will be described with reference to FIG. 28A to FIG. 30B. FIG. 28A to FIG. 30B each illustrate a cross-sectional view along the dashed-dotted line X1-X2 and a cross-sectional view along the dashed-dotted line Y1-Y2 in FIG. 24A side by side. Note that in FIG. 28A to FIG. 30B, the transistor 105 illustrated in FIG. 24A is omitted.

The conductive layer 111 is formed over the layer 101. A connection layer 116 is formed over the conductive layer 111 (FIG. 28A).

Next, the LED chip 136 is provided over the connection layer 116 (FIG. 28B). The LED chip 136 can be provided over the connection layer 116 by a pick-and-place method, for example. Here, the LED chip 136 is arranged so that the substrate 139 is over and in contact with the connection layer 116.

Next, an insulating film 125f to be the insulating layer 125 is formed to cover the conductive layer 111, the connection layer 116, and the LED chip 136 (FIG. 28C).

Then, the filling film 127f to be the filling layer 127 later is formed over the insulating film 125f (FIG. 28D).

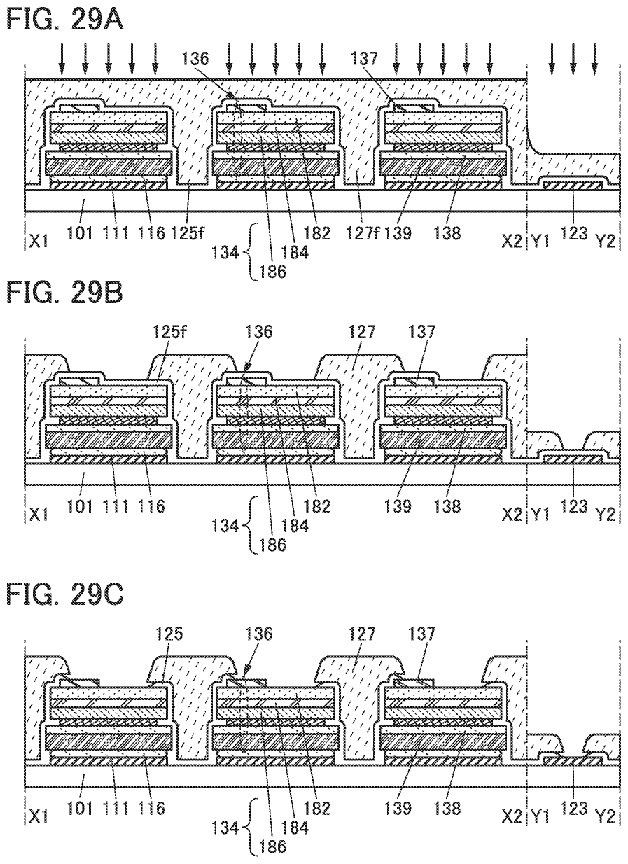

Next, part of the filling film 127f is exposed to visible light or ultraviolet rays. In FIG. 29A, light used for exposure is schematically illustrated as arrows.

Next, development is performed to remove a region of the filling film 127f exposed to light, so that the filling layer 127 is formed (FIG. 29B). The filling layer 127 is formed in a region sandwiched between two LED chips 136 and around the conductive layer 123.

Next, etching treatment is performed using the filling layer 127 as a mask to remove part of the insulating film 125f, so that the insulating layer 125 is formed (FIG. 29C). Thus, the top surfaces of the conductive layer 137 and the LED layer 134 are exposed.

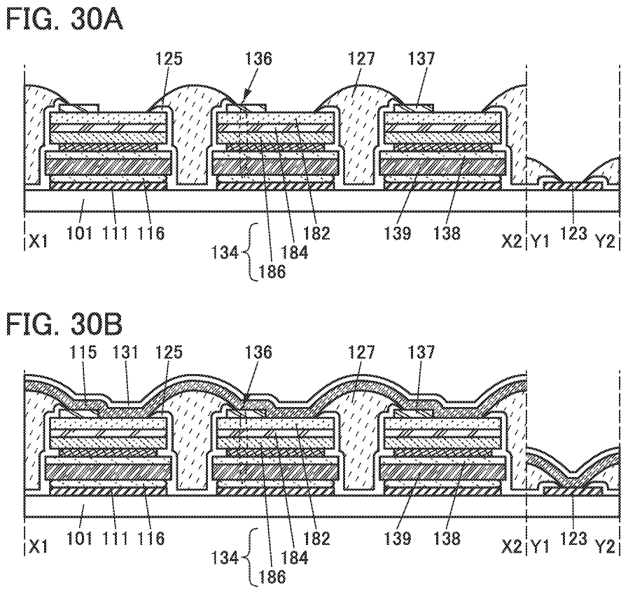

After that, heat treatment (also referred to as post-baking) is performed. By performing the heat treatment, the side surface of the filling layer 127 can change in shape and has a tapered shape (FIG. 30A).

Next, the conductive layer 115 and the protective layer 131 are formed in this order over the filling layer 127, the conductive layer 137, and the LED layer 134 (FIG. 30B).

Next, the substrate 120 provided with the coloring layer 107 and the color conversion layer 109 is bonded onto the protective layer 131 with the resin layer 122, whereby manufacturing the display apparatus can be completed (FIG. 24A).

This embodiment can be combined with the other embodiments as appropriate.

### Embodiment 3

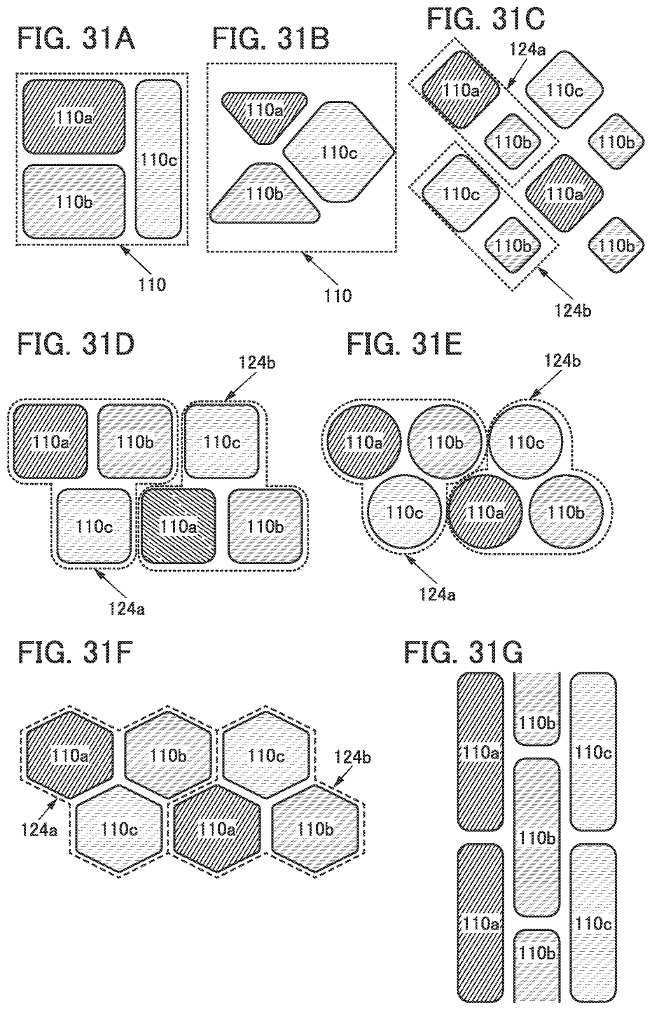

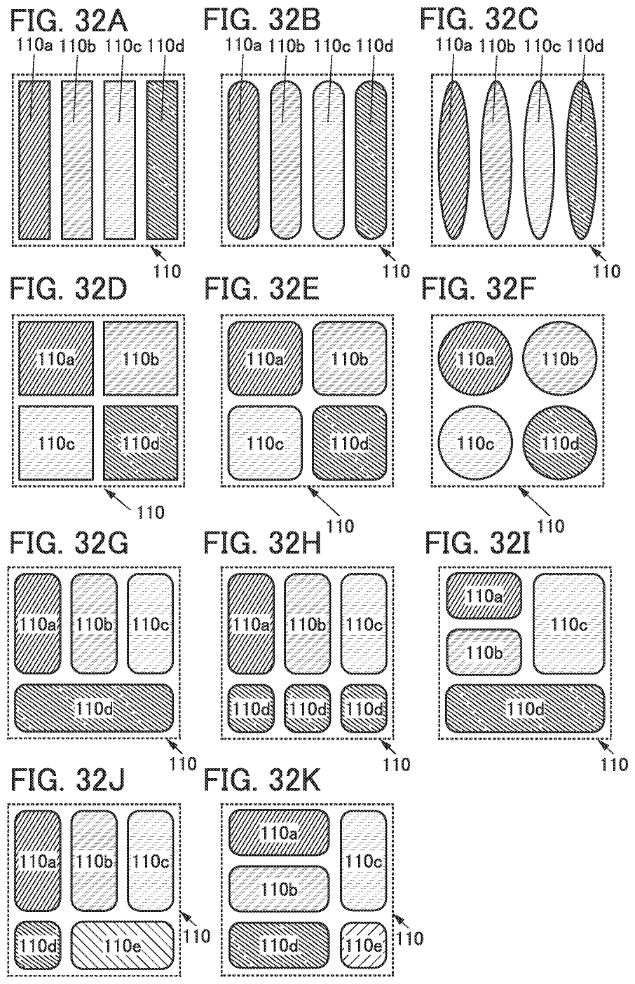

In this embodiment, a display apparatus of one embodiment of the present invention will be described with reference to FIG. 31 and FIG. 32.

In this embodiment, pixel layouts different from that in FIG. 1A are mainly described. There is no particular limitation on the arrangement of subpixels, and a variety of method can be employed. Examples of the arrangement of subpixels include stripe arrangement, S stripe arrangement, matrix arrangement, delta arrangement, Bayer arrangement, and PenTile arrangement.

The top surface shape of the subpixel illustrated in a diagram in this embodiment corresponds to the top surface shape of a light-emitting region.

Examples of the top surface shape of the subpixel include polygons such as a triangle, a tetragon (including a rectangle and a square), and a pentagon; polygons with rounded corners; an ellipse; and a circle.

Note that the circuit layout for forming the subpixel may be the same as or different from the pixel layout. The range of the circuit layout for forming the subpixels is not limited to the range of the subpixels illustrated in a diagram and may be placed outside the subpixels.

The pixel 110 illustrated in FIG. 31A employs S-stripe arrangement. The pixel 110 illustrated in FIG. 31A is composed of three subpixels 110a, 110b, and 110c.

The pixel 110 illustrated in FIG. 31B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller.

Pixels 124a and 124b illustrated in FIG. 31C are arranged in a pentile arrangement manner. FIG. 31C illustrates an example in which the pixels 124a each including the subpixel 110a and the subpixel 110b and the pixels 124b each including the subpixel 110b and the subpixel 110c are alternately arranged.

The pixels 124a and 124b illustrated in FIG. 31D to FIG. 31F are arranged in a delta arrangement manner. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row).

FIG. 31D illustrates an example where the top surface of each subpixel has a rough tetragonal shape with rounded corners, FIG. 31E illustrates an example where the top surface of each subpixel is circular, and FIG. 31F illustrates an example where the top surface of each subpixel has a rough hexagonal shape with rounded corners.

FIG. 31G illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view.

For example, in each pixel in FIG. 31A to FIG. 31G, it is preferable that the subpixel 110a be a subpixel R emitting red light, the subpixel 110b be a subpixel G emitting green light, and the subpixel 110c be a subpixel B emitting blue light. Note that the structure of the subpixels is not limited to this, and the colors and arrangement order of the subpixels can be determined as appropriate. For example, the subpixel 110b may be the subpixel R emitting red light and the subpixel 110a may be the subpixel G emitting green light.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface shape of a subpixel becomes a polygon with rounded corners, an ellipse, a circle, or the like in some cases.

Note that to obtain a desired top surface shape of the LED layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

As illustrated in FIG. 32A to FIG. 32I, the pixel can include four types of subpixels.

The pixels 110 illustrated in FIG. 32A to FIG. 32C employ stripe arrangement.

FIG. 32A illustrates an example where each subpixel has a rectangular top surface shape, FIG. 32B illustrates an example where each subpixel has a top surface shape formed by combining two half circles and a rectangle, and FIG. 32C illustrates an example where each subpixel has an elliptical top surface shape.

The pixels 110 illustrated in FIG. 32D to FIG. 32F are arranged in a matrix.

FIG. 32D illustrates an example where each subpixel has a square top surface shape, FIG. 32E illustrates an example where each subpixel has a substantially square top surface shape with rounded corners, and FIG. 32F illustrates an example where each subpixel has a circular top surface shape.

FIG. 32G and FIG. 32H each illustrate an example where one pixel 110 is composed of two rows and three columns.

The pixel 110 illustrated in FIG. 32G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 32H includes three subpixels (the subpixels 110a, 110b, and 110c) in the upper row (first row) and three the subpixels 110d in the lower row (second row). In other words, the pixel 110 includes the subpixel 110a and the subpixel 110d in the left column (first column), the subpixel 110b and another subpixel 110d in the center column (second column), and the subpixel 110c and another subpixel 110d in the right column (third column). Aligning the positions of the subpixels in the upper row and the lower row as illustrated in FIG. 32H enables dust and the like that would be produced in the manufacturing process to be removed efficiently. Thus, a display apparatus with high display quality can be provided.

FIG. 32I illustrates an example where one pixel 110 is composed of three rows and two columns.

The pixel 110 illustrated in FIG. 32I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 illustrated in FIG. 32A to FIG. 32I are each composed of four subpixels: the subpixel 110a, the subpixel 110b, the subpixel 110c, and the subpixel 110d.

The subpixels 110a, 110b, 110c, and 110d can include light-emitting devices emitting light of different colors. The subpixels 110a, 110b, 110c, and 110d can be subpixels of four colors of R, G, B, and white (W), subpixels of four colors of R, G, B, and Y, or subpixels of R, G, B, and infrared light (IR), for example.

In the pixels 110 illustrated in FIG. 32A to FIG. 32I, it is preferable that the subpixel 110a be the subpixel R emitting red light, the subpixel 110b be the subpixel G emitting green light, the subpixel 110c be the subpixel B emitting blue light, and the subpixel 110d be any of a subpixel W emitting white light, a subpixel Y emitting yellow light, and a subpixel IR emitting near-infrared light, for example. In the case of such a structure, stripe arrangement is employed as the layout of R, G, and B in the pixels 110 illustrated in FIG. 32G and FIG. 32H, leading to higher display quality. In addition, what is called S-stripe arrangement is employed as the layout of R, G, and B in the pixel 110 illustrated in FIG. 32I, leading to higher display quality.

As illustrated in FIG. 32J and FIG. 32K, the pixel can include five types of subpixels.

FIG. 32J illustrates an example where one pixel 110 is composed of two rows and three columns.

The pixel 110 illustrated in FIG. 32J includes three subpixels (the subpixels 110a, 110b, and 110c) in the upper row (first row) and two subpixels (the subpixel 110d and a subpixel 110e) in the lower row (second row). In other words, the pixel 110 includes the subpixels 110a and 110d in the left column (first column), the subpixel 110b in the center column (second column), the subpixel 110c in the right column (third column), and the subpixel 110e across the second and third columns.

FIG. 32K illustrates an example where one pixel 110 is composed of three rows and two columns.

The pixel 110 illustrated in FIG. 32K includes the subpixel 110a in the upper row (first row), the subpixel 110b in the center row (second row), the subpixel 110c across the first and second rows, and two subpixels (the subpixels 110d and 110e) in the lower row (third row). In other words, the pixel 110 includes the subpixels 110a, 110b, and 110d in the left column (first column), and the subpixels 110c and 110e in the right column (second column).

In the pixels 110 illustrated in FIG. 32J and FIG. 32K, for example, it is preferable that the subpixel 110a be the subpixel R emitting red light, the subpixel 110b be the subpixel G emitting green light, and the subpixel 110c be the subpixel B emitting blue light. In the case of such a structure, stripe arrangement is employed as the layout of R, G, and B in the pixel 110 illustrated in FIG. 32J, leading to higher display quality. In addition, what is called S-stripe arrangement is employed as the layout of R, G, and B in the pixel 110 illustrated in FIG. 32K, leading to higher display quality.

This embodiment can be combined with the other embodiments as appropriate.

### Embodiment 4

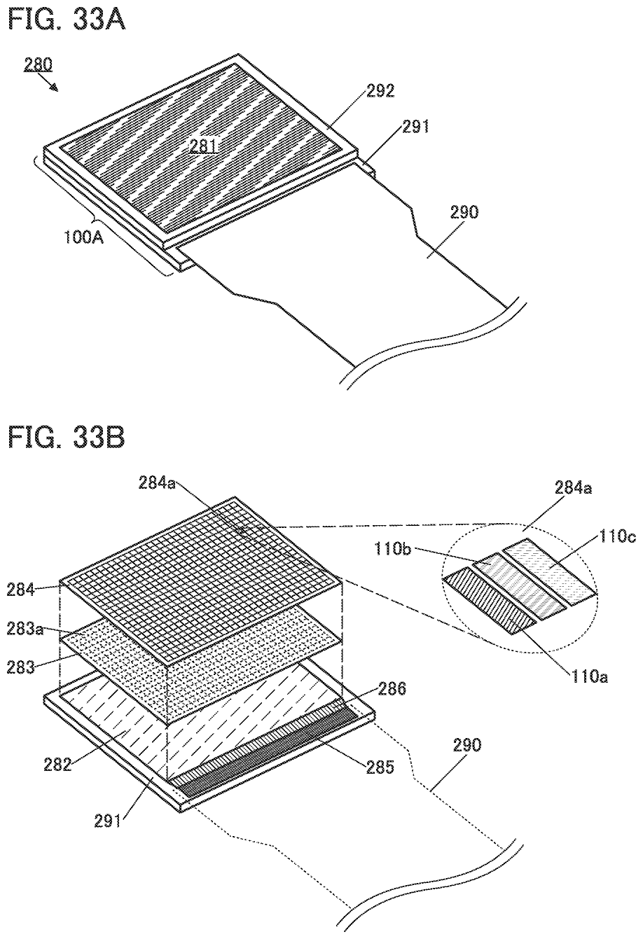

In this embodiment, a display apparatus of one embodiment of the present invention will be described with reference to FIG. 33 to FIG. 35.

The display apparatus of this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer and the like, digital signage, and a large game machine such as a pachinko machine.

### <Display Module>

FIG. 33A is a perspective view of a display module 280. The display module 280 includes a display apparatus 100A and an FPC 290. Note that the display apparatus included in the display module 280 is not limited to the display apparatus 100A and may be any of a display apparatus 100B to a display apparatus 100F described later.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 33B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged in a matrix. An enlarged view of one pixel 284a is illustrated on the right side of FIG. 33B. The pixel 284a can employ any of the structures described in the above embodiments. FIG. 33B illustrates an example where a structure similar to that of the pixel 110 illustrated in FIG. 1A is employed.

The pixel circuit portion 283 includes a plurality of pixel circuits 283a arranged in a matrix.

One pixel circuit 283a is a circuit that controls driving of a plurality of elements included in one pixel 284a. One pixel circuit 283a can be provided with three circuits each controlling light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. With such a structure, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged at very high density and thus the display portion 281 can have an extremely high definition. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as an HMD or a glasses-type AR device. For example, even with a structure where the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic devices including a relatively small display portion. For example, the display module 280 can be suitably used for a display portion of a wearable electronic device, such as a wrist watch.

### <Display Apparatus 100A>

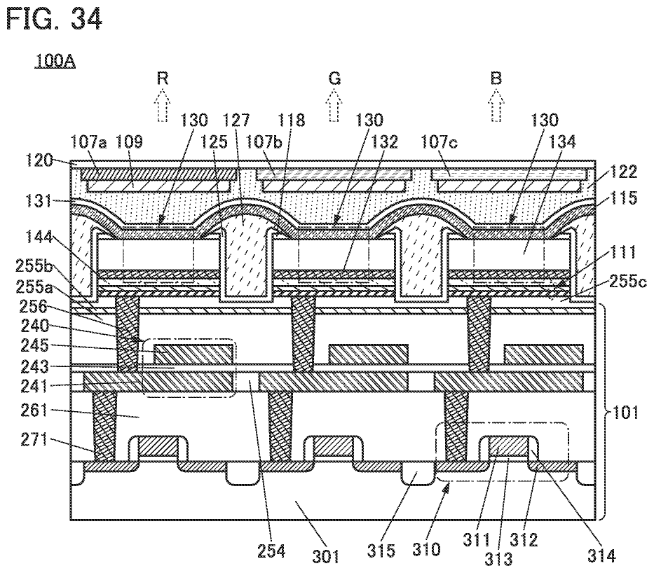

The display apparatus 100A illustrated in FIG. 34 includes a substrate 301, the light-emitting device 130, a capacitor 240, and a transistor 310.

The substrate 301 corresponds to the substrate 291 in FIG. 33A and FIG. 33B. A stacked-layer structure from the substrate 301 to an insulating layer 255c corresponds to the layer 101 including transistors in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

The insulating layer 255a is provided to cover the capacitor 240, the insulating layer 255b is provided over the insulating layer 255a, and the insulating layer 255c is provided over the insulating layer 255b. The light-emitting device 130 is provided over the insulating layer 255c. FIG. 34 illustrates an example where the light-emitting device 130 has a structure similar to the stacked-layer structure illustrated in FIG. 1B. An insulator is provided in a region between adjacent light-emitting devices 130. In FIG. 34, the insulating layer 125 and the filling layer 127 over the insulating layer 125 are provided in the region.

One or more of the insulating layer 255a, the insulating layer 255b, and the insulating layer 255c may have a depressed portion between the adjacent light-emitting devices. In the example illustrated in FIG. 34, the insulating layer 255c has a depressed portion.

As each of the insulating layer 255a, the insulating layer 255b, and the insulating layer 255c, a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. More specifically, it is preferred that a silicon oxide film be used as the insulating layer 255a and the insulating layer 255c, and a silicon nitride film be used as the insulating layer 255b. The insulating layer 255b preferably has a function of an etching protective film. The mask layer 118 is positioned over the LED layer 134 included in the light-emitting device 130.

The conductive layer 111 is electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 271 embedded in the insulating layer 261. The level of the top surface of the insulating layer 255c is equal to or substantially equal to the level of the top surface of the plug 256. A variety of conductive materials can be used for the plugs. FIG. 34 and the like illustrate an example where the pixel electrode has a two-layer structure of a reflective electrode and a transparent electrode over the reflective electrode.

The protective layer 131 is provided over the light-emitting device 130. The substrate 120 is bonded onto the protective layer 131 with the resin layer 122. Embodiment 1 can be referred to for details of the light-emitting devices and the components thereover up to the substrate 120. The substrate 120 corresponds to the substrate 292 in FIG. 33A.

### <Display Apparatus 100B>

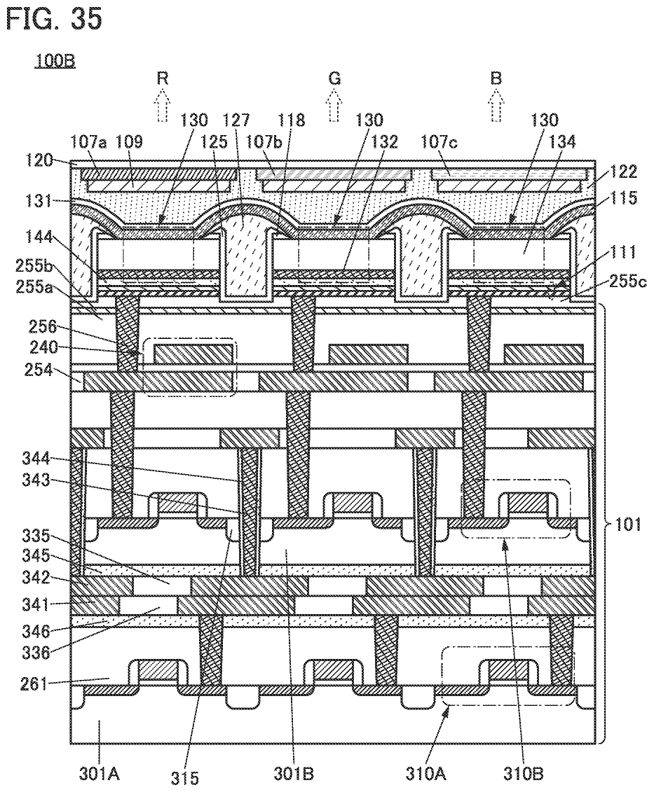

The display apparatus 100B illustrated in FIG. 35 has a structure where a transistor 310A and a transistor 310B in each of which a channel is formed in a semiconductor substrate are stacked. Note that in the description of the display apparatus below, portions similar to those of the above-mentioned display apparatus are not described in some cases.

In the display apparatus 100B, a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used as the protective layer 131 or an insulating layer 332 can be used.

The substrate 301B is provided with a plug 343 that penetrates the substrate 301B and the insulating layer 345. An insulating layer 344 is preferably provided to cover the side surface of the plug 343. The insulating layer 344 is an insulating layer functioning as a protective layer and can inhibit diffusion of impurities into the substrate 301B. For the insulating layer 344, an inorganic insulating film that can be used for the protective layer 131 can be used.

A conductive layer 342 is provided under the insulating layer 345 on the rear surface of the substrate 301B (a surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Meanwhile, a conductive layer 341 is provided over the insulating layer 346 over the substrate 301A. The conductive layer 341 is preferably provided to be embedded in the insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. In particular, copper is preferably used for the conductive layer 341 and the conductive layer 342. In that case, it is possible to employ Cu—Cu (copper-to-copper) direct bonding (a technique for achieving electrical continuity by connecting Cu (copper) pads).

### <Display Apparatus 100C>

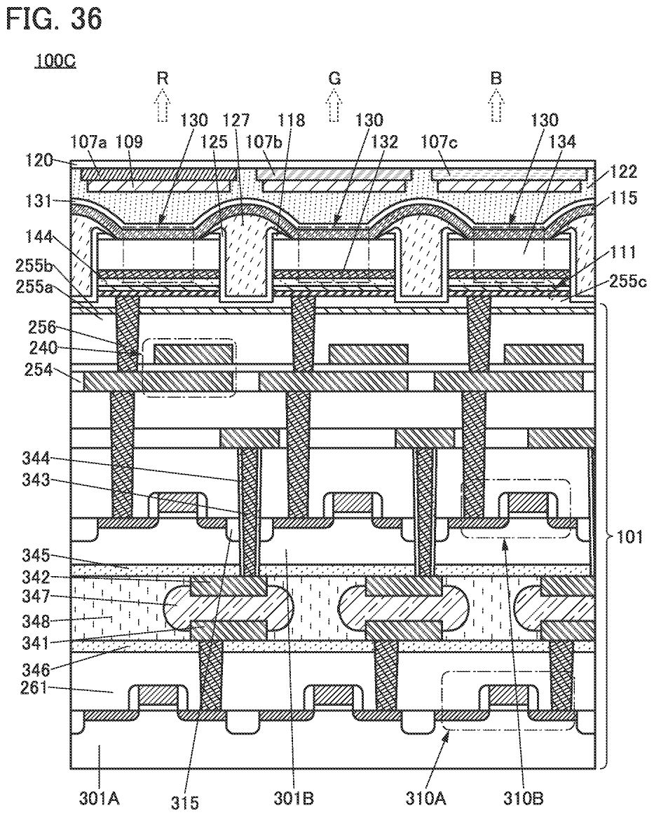

A display apparatus 100C illustrated in FIG. 36 has a structure where the conductive layer 341 and the conductive layer 342 are bonded to each other through a bump 347.

As illustrated in FIG. 36, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### <Display Apparatus 100D>

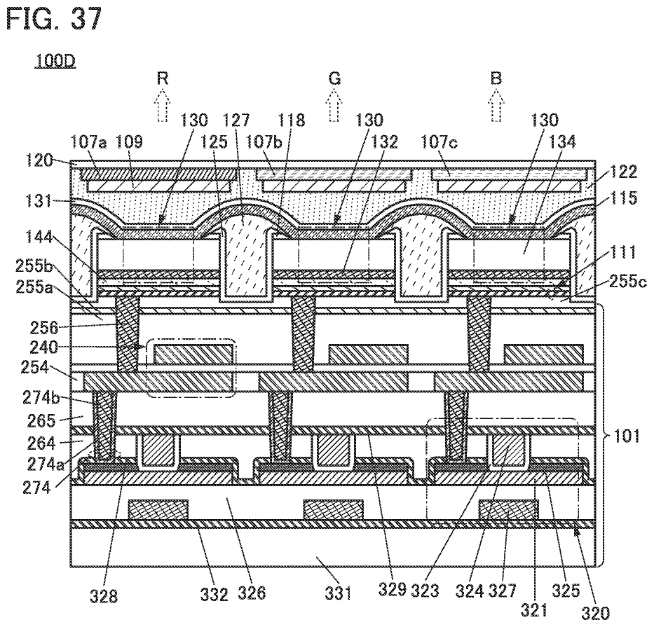

A display apparatus 100D illustrated in FIG. 37 is different from the display apparatus 100A mainly in a structure of a transistor.

A transistor 320 is a transistor that contains a metal oxide exhibiting semiconductor characteristics (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 33A and FIG. 33B. A stacked-layer structure from the substrate 331 to the insulating layer 255c corresponds to the layer 101 including transistors in Embodiment 1. As a substrate 331, an insulating substrate or a semiconductor substrate can be used.

The insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is unlikely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably contains an oxide semiconductor. The pair of conductive layers 325 are provided over and in contact with the semiconductor layer 321 and function as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that their levels are the same or substantially the same, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water and hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers a side surface of an opening of the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material in which hydrogen and oxygen are less likely to diffuse is preferably used for the conductive layer 274a.

### <Display Apparatus 100E>

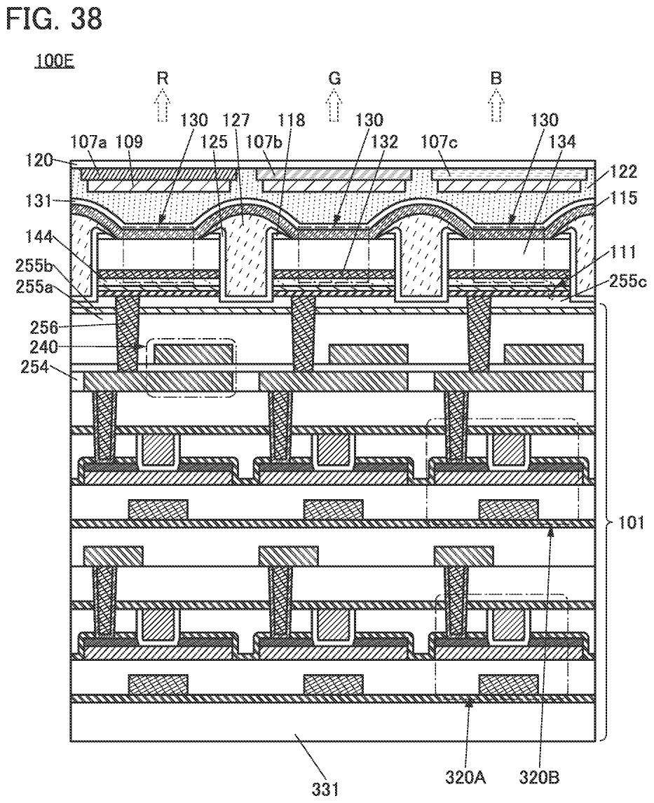

A display apparatus 100E illustrated in FIG. 38 has a structure in which a transistor 320A and a transistor 320B each including an oxide semiconductor in a semiconductor where a channel is formed are stacked.

The description of the display apparatus 100D can be referred to for the transistor 320A, the transistor 320B, and the components around them.

Although the structure where two transistors including an oxide semiconductor are stacked is described here, the present invention is not limited thereto. For example, three or more transistors may be stacked.

### <Display Apparatus 100F>

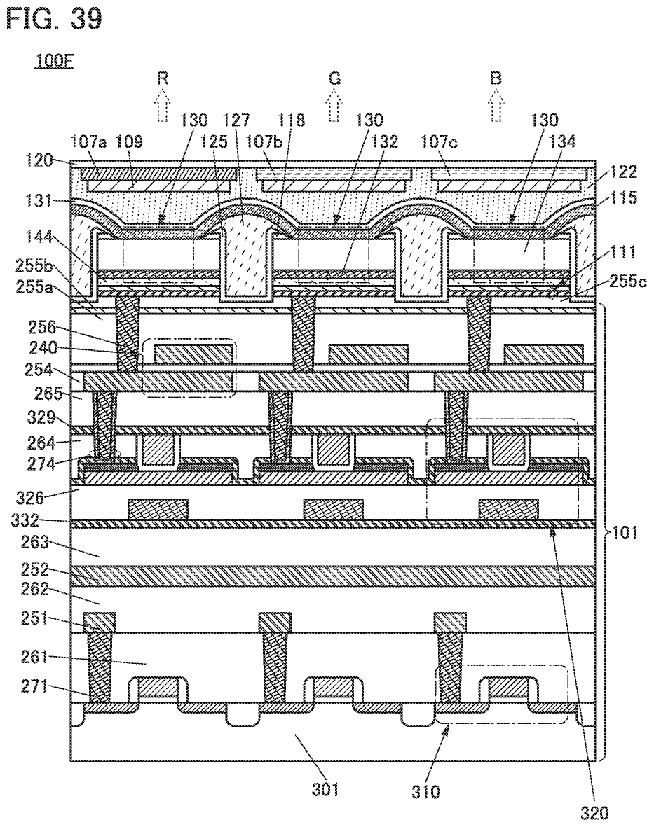

A display apparatus 100F illustrated in FIG. 39 has a structure in which the transistor 310 whose channel is formed in the substrate 301 and the transistor 320 including an oxide semiconductor in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display apparatus can be downsized as compared with the case where a driver circuit is provided around a display region.

### <Display Apparatus 100G>

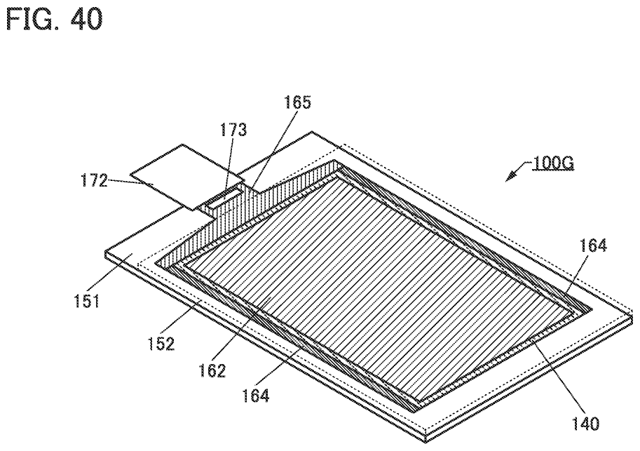

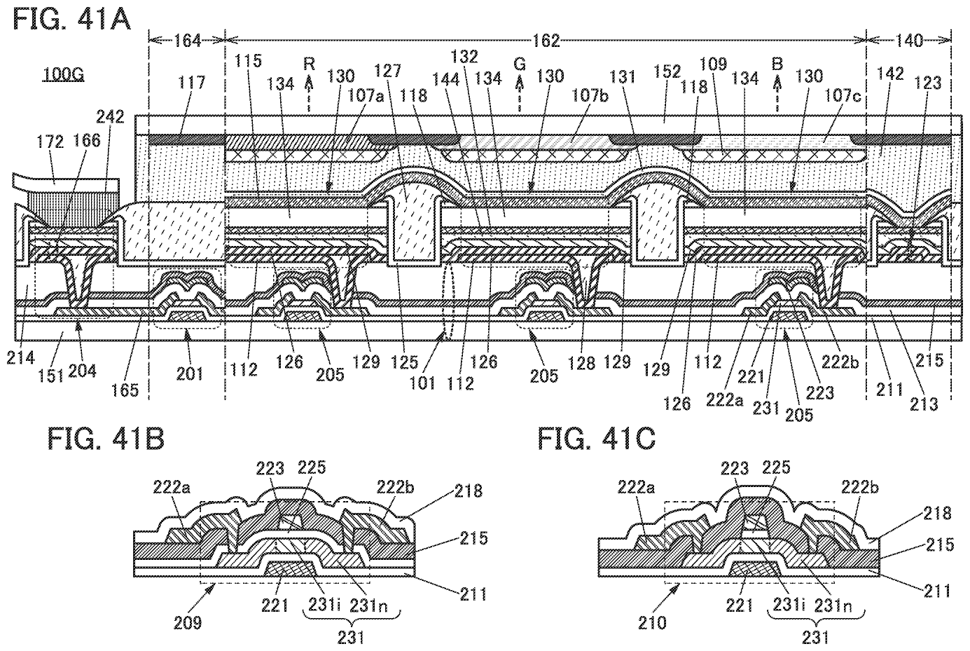

FIG. 40 is a perspective view of a display apparatus 100G, and FIG. 41A is a cross-sectional view of the display apparatus 100G.

In the display apparatus 100G, a substrate 152 and a substrate 151 are bonded to each other. In FIG. 40, the substrate 152 is denoted by a dashed line.

The display apparatus 100G includes a display portion 162, the connection portion 140, a circuit 164, a wiring 165, and the like. FIG. 40 illustrates an example where an IC 173 and an FPC 172 are mounted on the display apparatus 100G. Thus, the structure illustrated in FIG. 40 can be regarded as a display module including the display apparatus 100G, the IC (integrated circuit), and the FPC.

The connection portion 140 is provided outside the display portion 162. The connection portion 140 can be provided along one or more sides of the display portion 162. The number of connection portions 140 can be one or more. FIG. 40 illustrates an example where the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 40 illustrates an example where the IC 173 is provided over the substrate 151 by a COG (Chip On Glass) method, a COF (Chip on Film) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method or the like.

FIG. 41A illustrates an example of cross sections of part of a region including the FPC 172, part of the circuit 164, part of the display portion 162, part of the connection portion 140, and part of a region including an end portion of the display apparatus 100G.

The display apparatus 100G illustrated in FIG. 41A includes a transistor 201, a transistor 205, the light-emitting device 130, and the like between the substrate 151 and the substrate 152.

The light-emitting device 130 has the same structure as the stacked-layer structure illustrated in FIG. 1B except the structure of the pixel electrode. Embodiment 1 can be referred to for the details of the light-emitting devices.

The light-emitting device 130 includes a conductive layer 112, a conductive layer 126 over the conductive layer 112, and a conductive layer 129 over the conductive layer 126. All of the conductive layer 112, the conductive layer 126, and the conductive layer 129 can be referred to as pixel electrodes, or one or two of them can be referred to as pixel electrodes.

The conductive layer 112 is connected to a conductive layer 222b included in the transistor 205 through an opening provided in the insulating layer 214. The end portion of the conductive layer 126 is positioned outside the end portion of the conductive layer 112. The end portion of the conductive layer 126 and the end portion of the conductive layer 129 are aligned or substantially aligned with each other. For example, a conductive layer functioning as a reflective electrode can be used as the conductive layer 112 and the conductive layer 126, and a conductive layer functioning as a transparent electrode can be used as the conductive layer 129.

The conductive layer 112 is formed to cover the opening provided in the insulating layer 214. A layer 128 is embedded in a depressed portion of the conductive layer 112.

The layer 128 has a planarization function for the depressed portion of the conductive layer 112. The conductive layer 126 electrically connected to the conductive layer 112 is provided over the conductive layer 112 and the layer 128. Thus, a region overlapping with the depressed portion of the conductive layer 112 can also be used as a light-emitting region, increasing the aperture ratio of the pixel.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the filling layer 127 can be used, for example.

Note that although FIG. 41A illustrates an example where the top surface of the layer 128 includes a planar portion, the shape of the layer 128 is not particularly limited. The top surface of the layer 128 can have a shape that is recessed in the center and its vicinity, i.e., a shape with a concave surface, in the cross-sectional view. Alternatively, the top surface of the layer 128 can have a shape such that its center and the vicinity thereof bulge, i.e., a shape including a convex surface, in a cross-sectional view. Alternatively, the top surface of the layer 128 may include one or both of a convex surface and a concave surface. The number of convex surfaces and the number of concave surfaces included in the top surface of the layer 128 are not limited and can each be one or more.

The height of the top surface of the layer 128 and the level of the top surface of the conductive layer 112 may be equal to or substantially equal to each other, or may be different from each other. For example, the level of the top surface of the layer 128 may be either lower or higher than the level of the top surface of the conductive layer 112.

End portions of the conductive layer 126, the conductive layer 129, and the LED layer 134 are aligned or substantially aligned with each other. Accordingly, a region provided with the conductive layer 126 can be entirely used as a light-emitting region of the light-emitting device 130, increasing the aperture ratio of the pixels.

The side surface and part of the top surface of the LED layer 134 are covered with the insulating layer 125 and the filling layer 127. The mask layer 118 is positioned between the LED layer 134 and the insulating layer 125. The conductive layer 115 is provided over the LED layer 134, the insulating layer 125, and the filling layer 127. The conductive layer 115 is a continuous film provided to be shared by a plurality of light-emitting devices.

The protective layer 131 is provided over the light-emitting device 130. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting devices. In FIG. 41A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. The adhesive layer 142 may be provided not to overlap with the light-emitting device. The space may be filled with a resin different from that of the frame-like adhesive layer 142.

The conductive layer 123 is provided over the insulating layer 214 in the connection portion 140. In the example shown here, the conductive layer 123 has a stacked-layer structure of a conductive film obtained by processing the same conductive film as the conductive layer 112, a conductive film obtained by processing the same conductive film as the conductive layer 126, and a conductive film obtained by processing the same conductive film as the conductive layer 129. The end portion of the conductive layer 123 is covered with the mask layer 118, the insulating layer 125, and the filling layer 127. The conductive layer 115 is provided over the conductive layer 123. Note that in the connection portion 140, the conductive layer 123 is in direct contact with and electrically connected with the conductive layer 115.

The display apparatus 100G has a top-emission structure. Light emitted by the light-emitting device is emitted toward the substrate 152 side. For the substrate 152, a material having a high visible-light-transmitting property is preferably used. The pixel electrode contains a material that reflects visible light, and a counter electrode (the conductive layer 115) contains a material that transmits visible light.

A stacked-layer structure from the substrate 151 to the insulating layer 214 corresponds to the layer 101 including transistors described in the aforementioned embodiments.

The transistor 201 and the transistor 205 are formed over the substrate 151. These transistors can be manufactured using the same materials through the same process.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that there is no limitation on the number of gate insulating layers and the number of insulating layers covering the transistors, and each insulating layer may be a single layer or include two or more layers.

A material through which impurities such as water and hydrogen do not easily diffuse is preferably used for at least one of the insulating layers covering the transistors. In that case, the insulating layer can function as a barrier layer. Such a structure can effectively inhibit diffusion of impurities into the transistors from the outside and increase the reliability of the display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. In that case, a depressed portion can be inhibited from being formed in the insulating layer 214 at the time of processing the conductive layer 112, the conductive layer 126, the conductive layer 129, or the like. Alternatively, a depressed portion may be formed in the insulating layer 214 at the time of processing the conductive layer 112, the conductive layer 126, the conductive layer 129, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate transistor structure or a bottom-gate transistor structure may be employed. Alternatively, gates may be provided above and below the semiconductor layer where a channel is formed.

The structure in which the semiconductor layer where a channel is formed is sandwiched between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor, and a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes an oxide semiconductor. That is, an OS transistor is preferably used as the transistor included in the display apparatus of this embodiment.

As the oxide semiconductor having crystallinity, a CAAC (c-axis aligned crystalline)-OS, an nc (nanocrystalline)-OS, and the like are given.

Alternatively, a transistor containing silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and excellent frequency characteristics.

With use of Si transistors such as LTPS transistors, a circuit required to be driven at a high frequency (e.g., a source driver circuit) can be formed on the same substrate as the display portion. This allows simplification of an external circuit mounted on the display apparatus and a reduction in component cost and mounting cost.

An OS transistor has much higher field-effect mobility than a transistor containing amorphous silicon. In addition, an OS transistor has an extremely low leakage current between a source and a drain in an off state (also referred to as off-state current), and charge accumulated in a capacitor that is connected in series to the transistor can be retained for a long period. Furthermore, power consumption of the display apparatus can be reduced with use of an OS transistor.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When transistors operate in a saturation region, a change in source-drain current relative to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when the transistor operates in a saturation region, an OS transistor can feed more stable current (saturation current) than a Si transistor even when the source-drain voltage gradually increases. Thus, by using an OS transistor as the driving transistor, a stable current can be fed through light-emitting devices even when the current-voltage characteristics of the EL devices vary, for example. In other words, when the OS transistor operates in the saturation region, the source-drain current hardly changes with an increase in the source-drain voltage; hence, the emission luminance of the light-emitting device can be stable.

As described above, with use of an OS transistor as a driving transistor included in the pixel circuit, it is possible to achieve “inhibition of black-level degradation”, “increase in emission luminance”, “increase in gray level”, “inhibition of variation in light-emitting devices”, and the like.

A metal oxide used for the semiconductor layer preferably contains indium, an element M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, the element M is preferably one or more kinds selected from aluminum, gallium, yttrium, and tin.

It is particularly preferable that an oxide containing indium (In), gallium (Ga), and zinc (Zn) (also referred to as IGZO) be used as the semiconductor layer. Alternatively, it is preferable to use an oxide containing indium, tin, and zinc. Further alternatively, it is preferable to use an oxide containing indium, gallium, tin, and zinc. Alternatively, an oxide containing indium (In), aluminum (Al), and zinc (Zn) (also referred to as IAZO) is preferably used for the semiconductor layer. Alternatively, an oxide containing indium (In), aluminum (Al), gallium (Ga), and zinc (Zn) (also referred to as IAGZO) is preferably used for the semiconductor layer.

When the semiconductor layer is an In-M-Zn oxide, the atomic ratio of In is preferably higher than or equal to the atomic ratio of M in the In-M-Zn oxide. Examples of the atomic ratio (In:M:Zn) of the metal elements in such an In-M-Zn oxide include 1:1:1 or a composition in the neighborhood thereof, 1:1:1.2 or a composition in the neighborhood thereof, 1:3:2 or a composition in the neighborhood thereof, 1:3:4 or a composition in the neighborhood thereof, 2:1:3 or a composition in the neighborhood thereof, 3:1:2 or a composition in the neighborhood thereof, 4:2:3 or a composition in the neighborhood thereof, 4:2:4.1 or a composition in the neighborhood thereof, 5:1:3 or a composition in the neighborhood thereof, 5:1:6 or a composition in the neighborhood thereof, 5:1:7 or a composition in the neighborhood thereof, 5:1:8 or a composition in the neighborhood thereof, 6:1:6 or a composition in the neighborhood thereof, and 5:2:5 or a composition in the neighborhood thereof. Note that a composition in the neighborhood includes the range of ±30% of an intended atomic ratio.

For example, when the atomic ratio (In:Ga:Zn) is described as 4:2:3 or a composition in the neighborhood thereof, the case is included where Ga is greater than or equal to 1 and less than or equal to 3 and Zn is greater than or equal to 2 and less than or equal to 4 with In being 4. When the atomic ratio (In:Ga:Zn) is described as 5:1:6 or a composition in the neighborhood thereof, the case is included where Ga is greater than 0.1 and less than or equal to 2 and Zn is greater than or equal to 5 and less than or equal to 7 with In being 5. When the atomic ratio (In:Ga:Zn) is described as 1:1:1 or a composition in the neighborhood thereof, the case is included where Ga is greater than 0.1 and less than or equal to 2 and Zn is greater than 0.1 and less than or equal to 2 with In being 1.

The transistor included in the circuit 164 and the transistor included in the display portion 162 may have the same structure or different structures. One structure or two or more types of structures may be employed for a plurality of transistors included in the circuit 164. Similarly, one structure or two or more types of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high driving capability. Note that a structure where an LTPS transistor and an OS transistor are used in combination is referred to as LTPO in some cases. As a more suitable example, a structure in which the OS transistor is used as a transistor or the like functioning as a switch for controlling conduction or non-conduction between wirings, and the LTPS transistor is used as a transistor or the like for controlling current, can be given.

For example, one transistor included in the display portion 162 functions as a transistor for controlling current flowing through the light-emitting device and can also be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased in the pixel circuit.

Another transistor included in the display portion 162 functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the display apparatus of one embodiment of the present invention can have all of a high aperture ratio, high resolution, high display quality, and low power consumption.

The display apparatus of one embodiment of the present invention enables the leakage current that might flow through a transistor and the leakage current that might flow through adjacent light-emitting devices (also referred to as lateral leakage current, side leakage current, or the like) to be extremely reduced as described above. Furthermore, a viewer can notice any one or more of the image crispness, the image sharpness, a high chroma, and a high contrast ratio in an image displayed on the display apparatus. Note that when the leakage current that might flow through a transistor and the lateral leakage current between light-emitting devices are extremely low, light leakage (what is called black blurring) or the like that might occur in black display can be reduced as much as possible.

FIG. 41B and FIG. 41C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 41B illustrates an example of the transistor 209 in which the insulating layer 225 covers the top surface and the side surface of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 41C, the insulating layer 225 overlaps with the channel formation region 231i of the semiconductor layer 231 and does not overlap with the low-resistance regions 231n. The structure illustrated in FIG. 41C can be formed by processing the insulating layer 225 using the conductive layer 223 as a mask, for example. In FIG. 41C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. In the example shown here, the conductive layer 166 has a stacked-layer structure of a conductive film obtained by processing the same conductive film as the conductive layer 112, a conductive film obtained by processing the same conductive film as the conductive layer 126, and a conductive film obtained by processing the same conductive film as the conductive layer 129. The conductive layer 166 is exposed on the top surface of the connection portion 204. Thus, the connection portion 204 and the FPC 172 can be electrically connected to each other through the connection layer 242.

The light-blocking layer 117 is preferably provided on the surface of the substrate 152 on the substrate 151 side. The light-blocking layer 117 can be provided between adjacent light-emitting devices, in the connection portion 140, and in the circuit 164, for example. A variety of optical members can be provided on the outer surface of the substrate 152.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

### <Display Apparatus 100H>

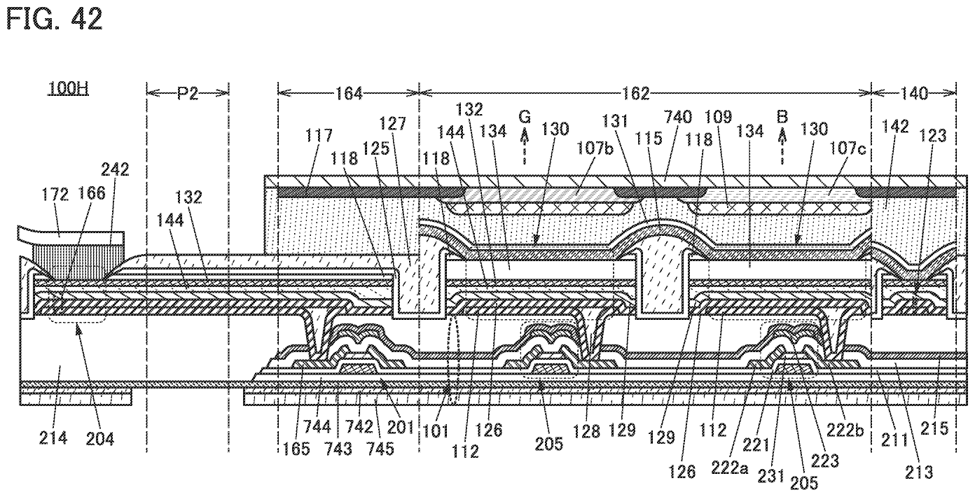

A display apparatus 100H illustrated in FIG. 42 includes a stack of a support substrate 745, an adhesive layer 742, a resin layer 743, and an insulating layer 744, instead of the substrate 151 illustrated in FIG. 41, and a protective layer 740 instead of the substrate 152. The transistor 205 and the like are provided over the insulating layer 744 over the resin layer 743.

The support substrate 745 includes an organic resin, glass, or the like and is thin enough to have flexibility. The resin layer 743 is a layer including an organic resin such as a polyimide resin or an acrylic resin. The insulating layer 744 includes an inorganic insulating film of silicon oxide, silicon oxynitride, silicon nitride, or the like. The resin layer 743 and the support substrate 745 are bonded to each other with the adhesive layer 742. The resin layer 743 is preferably thinner than the support substrate 745.

The protective layer 131 and the protective layer 740 are bonded to each other with the adhesive layer 142. A glass substrate, a resin film, or the like can be used as the protective layer 740. Alternatively, as the protective layer 740, an optical member such as a polarizing plate or a scattering plate, an input device such as a touch sensor panel, or a structure in which two or more of the above are stacked may be employed.

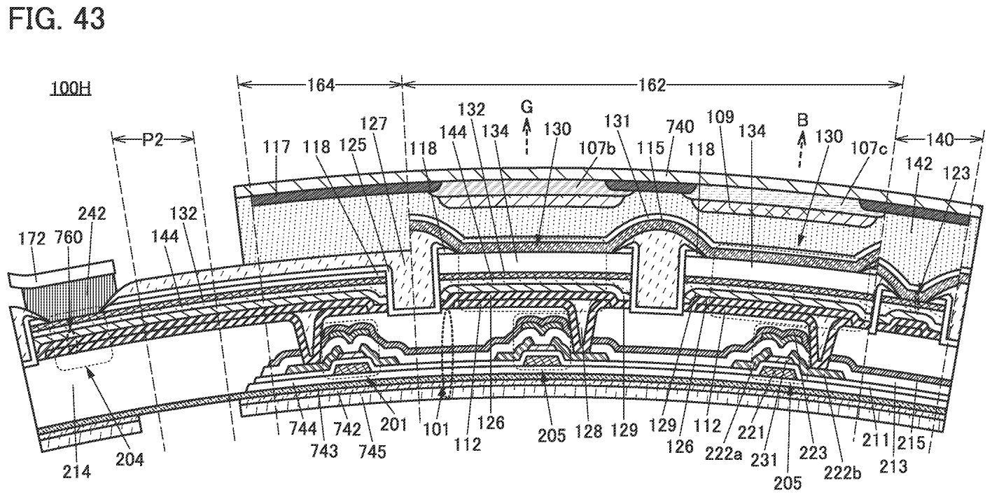

The display apparatus 100H can be used favorably as a flexible display. FIG. 43 illustrates the display apparatus 100H that is curved. Note that a state illustrated in FIG. 43 is such that the display apparatus 100H is curved convexly on the light-emitting surface (here, the protective layer 740) side; however, one embodiment of the present invention is not limited thereto. The display apparatus 100H may be curved concavely on the light-emitting surface side. Alternatively, a region curved convexly and a region curved concavely may be provided on the light-emitting surface side.

As illustrated in FIG. 42 and FIG. 43, a region P2 not provided with the support substrate 745 and the adhesive layer 742 may be included. When the support substrate 745 is not provided in the region P2, part of the display apparatus 100H can be bent with an extremely small radius of curvature. For example, when the region P2 is bent backward to the rear side, the FPC 172 can be placed to overlap with the rear side of the display portion 162. Thus, the size of an electronic device on which the display apparatus 100H is mounted can be reduced.

The region P2 may have a structure without an inorganic insulating film such as the insulating layer 744. When a structure is employed in which an inorganic insulating film is not provided if possible in the region P2 and only a conductive layer containing a metal or an alloy and a layer containing an organic material are stacked, generation of cracks caused at bending can be prevented.

In the connection portion 204, a wiring 760 is electrically connected to the FPC 172 through the connection layer 144, the conductive layer 132, and the connection layer 242. In the example shown here, the wiring 760 has a stacked-layer structure of a conductive film obtained by processing the same conductive film as the conductive layer 112, a conductive film obtained by processing the same conductive film as the conductive layer 126, and a conductive film obtained by processing the same conductive film as the conductive layer 129. The wiring 760 is electrically connected to the transistor 201.

This embodiment can be combined with the other embodiments as appropriate.

### Embodiment 5

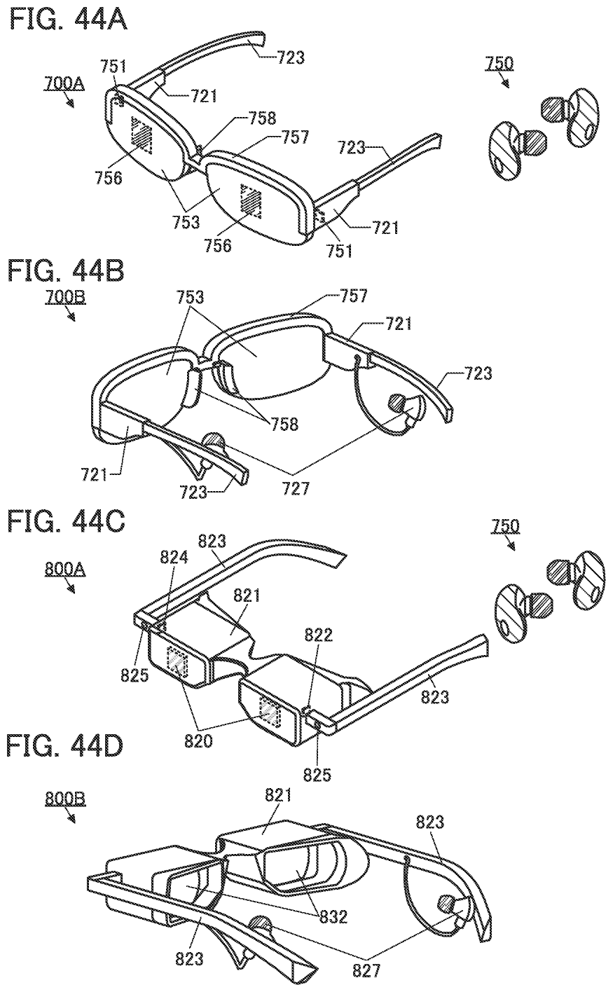

In this embodiment, electronic devices of one embodiment of the present invention will be described with reference to FIG. 44 to FIG. 46.

Electronic devices of this embodiment each include the display apparatus of one embodiment of the present invention in a display portion. The definition and resolution of the display apparatus of one embodiment of the present invention can be easily increased. Thus, the display apparatus of one embodiment of the present invention can be used for a display portion of a variety of electronic devices.

Examples of electronic devices include a digital camera, a digital video camera, a digital photo frame, a mobile phone, a portable game machine, a portable information terminal, and an audio reproducing device in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have a high resolution, and thus can be suitably used for an electronic device having a relatively small display portion. Examples of such an electronic device include a watch-type or a bracelet-type information terminal device (wearable device), and a wearable device worn on a head, such as a device for VR such as a head-mounted display, a glasses-type device for AR, and a device for MR.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840× 2160), or 8K (number of pixels: 7680× 4320). In particular, a definition of 4K, 8K, or higher is preferable. The pixel density (resolution) of the display apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With use of such a display apparatus having one or both of high resolution and high definition, the electronic device can have higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 44A to FIG. 44D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 44A and an electronic device 700B illustrated in FIG. 44B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device with extremely high resolution can be achieved.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables executing various types of processing. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

Any of various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 44C and an electronic device 800B illustrated in FIG. 44D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic device with extremely high resolution can be achieved. Such electronic devices provide an enhanced sense of immersion to the user.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be worn on the user's head with the wearing portions 823. FIG. 44C or the like illustrates an example where the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor capable of measuring a distance from an object (hereinafter also referred to as a sensing portion) just needs to be provided. In other words, the image capturing portion 825 is one embodiment of the sensing portion. As the sensing portion, an image sensor or a distance image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 44A has a function of transmitting information to the earphones 750 with the wireless communication function. As another example, the electronic device 800A illustrated in FIG. 44C has a function of transmitting information to the earphones 750 with the wireless communication function.

The electronic device may include an earphone portion. The electronic device 700B illustrated in FIG. 44B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 44D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

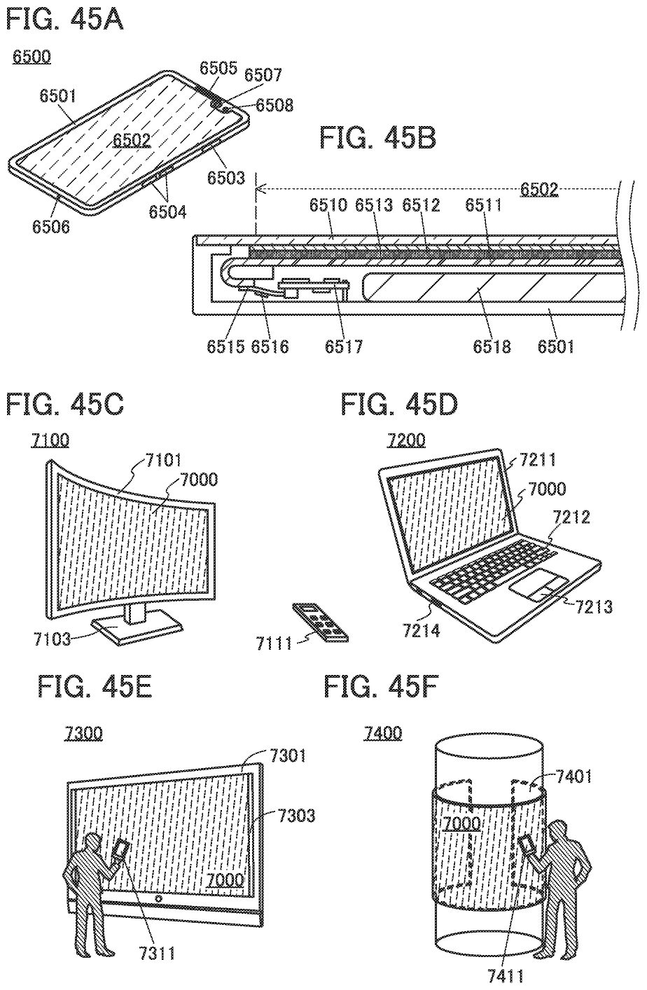

An electronic device 6500 illustrated in FIG. 45A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 45B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 45C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 45C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be operated and an image displayed on the display portion 7000 can be operated.

Note that the television device 7100 has a structure where a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 45D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 45E and FIG. 45F illustrate examples of digital signage.

Digital signage 7300 illustrated in FIG. 45E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 45F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 illustrated in each of FIG. 45E and FIG. 45F.

A larger area of the display portion 7000 can increase the amount of information that can be provided at a time. The larger display portion 7000 attracts more attentions, so that the effectiveness of the advertisement can be increased, for example.

A touch panel is preferably used in the display portion 7000, in which case intuitive operation by a user is possible in addition to display of an image or a moving image on the display portion 7000. Moreover, for an application that provides information such as route information or traffic information, usability can be enhanced by intuitive operation.

As illustrated in FIG. 45E and FIG. 45F, preferably, the digital signage 7300 or the digital signage 7400 can work with an information terminal 7311 or an information terminal 7411 such as a smartphone of a user through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

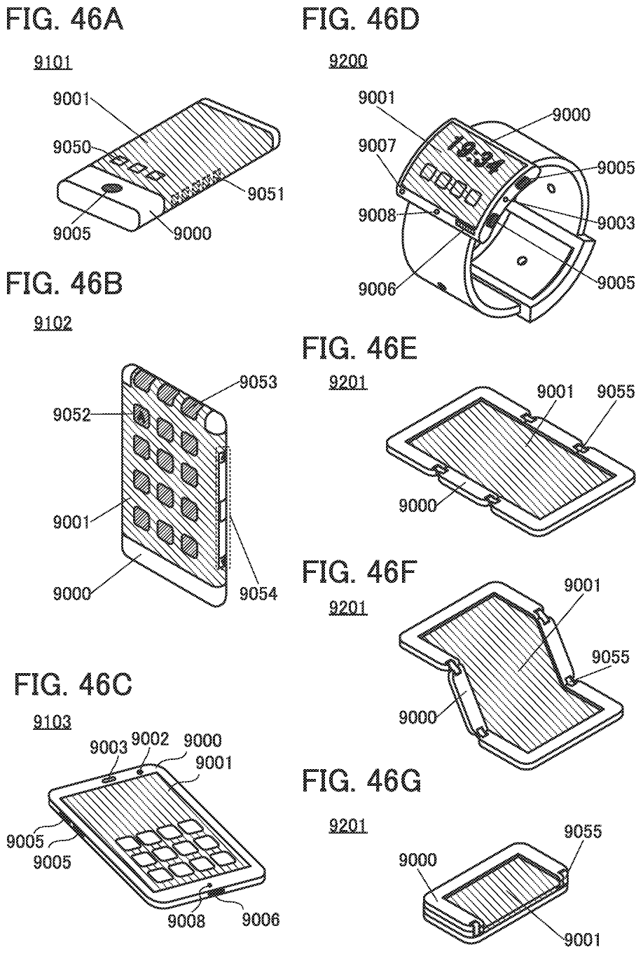

Electronic devices illustrated in FIG. 46A to FIG. 46G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 46A to FIG. 46G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. In addition, the electronic devices may each include a camera or the like and have a function of taking a still image or a moving image and storing the taken image in a recording medium (an external recording medium or a recording medium incorporated in the camera), a function of displaying the taken image on the display portion, or the like.

The electronic devices illustrated in FIG. 46A to FIG. 46G will be described in detail below.

FIG. 46A is a perspective view illustrating a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. FIG. 46A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 46B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 46C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 46D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 46E to FIG. 46G are perspective views illustrating a foldable portable information terminal 9201. FIG. 46E is a perspective view of an opened state of the portable information terminal 9201, FIG. 46G is a perspective view of a folded state thereof, and FIG. 46F is a perspective view of a state in the middle of change from one of FIG. 46E and FIG. 46G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

100A: display apparatus, 100B: display apparatus, 100C: display apparatus, 100D: display apparatus, 100E: display apparatus, 100F: display apparatus, 100G: display apparatus, 100H: display apparatus, 100: display apparatus, 101: layer, 105: transistor, 107a: coloring layer, 107b: coloring layer, 107c: coloring layer, 107: coloring layer, 109: color conversion layer, 110a: subpixel, 110b: subpixel, 110c: subpixel, 110d: subpixel, 110e: subpixel, 110: pixel, 111f: conductive film, 111: conductive layer, 112: conductive layer, 115: conductive layer, 116: connection layer, 117: light-blocking layer, 118A: mask layer, 118f: mask film, 118: mask layer, 120a: substrate, 120: substrate, 121: reflective layer, 122a: adhesive layer, 122: resin layer, 123: conductive layer, 124a: pixel, 124b: pixel, 125f: insulating film, 125: insulating layer, 126: conductive layer, 127f: filling film, 127: filling layer, 128: layer, 129: conductive layer, 130: light-emitting device, 131: protective layer, 132f: conductive film, 132: conductive layer, 133: lens, 134f: LED film, 134: LED layer, 135: light-blocking layer, 136: LED chip, 137: conductive layer, 138: connection layer, 139: substrate, 140: connection portion, 142: adhesive layer, 144: connection layer, 151: substrate, 152: substrate, 162: display portion, 164: circuit, 165: wiring, 166: conductive layer, 172: FPC, 173: IC, 180: substrate, 182f: semiconductor film, 182: semiconductor layer, 184f: light-emitting film, 184: light-emitting layer, 186f: semiconductor film, 186: semiconductor layer, 188: LED substrate, 190A: resist mask, 190B: resist mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 700A: electronic device, 700B: electronic device, 721: housing, 723: wearing portion, 727: earphone portion, 740: protective layer, 742: adhesive layer, 743: resin layer, 744: insulating layer, 745: support substrate, 750: earphone, 751: display panel, 753: optical member, 756: display region, 757: frame, 758: nose pad, 760: wiring, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first light-emitting device;
a second light-emitting device;
a first insulating layer; and
a filling layer,
wherein the first light-emitting device comprises:
a first electrode;
a first semiconductor layer over the first electrode; and
a common electrode over the first semiconductor layer,
wherein the second light-emitting device comprises:
a second electrode;
a second semiconductor layer over the second electrode; and
the common electrode over the second semiconductor layer,
wherein the first insulating layer comprises a region in contact with a side surface of the first semiconductor layer and a region in contact with a side surface of the second semiconductor layer,
wherein the filling layer comprises a region overlapping with the side surface of the first semiconductor layer with the first insulating layer therebetween and a region overlapping with the side surface of the second semiconductor layer with the first insulating layer therebetween, and
wherein the common electrode comprises a region in contact with a top surface of the filling layer.

2. A display apparatus comprising:
a first light-emitting device;
a second light-emitting device;
a first insulating layer;
a filling layer;
a coloring layer; and
a color conversion layer,
wherein the first light-emitting device comprises:
a first electrode;
a first semiconductor layer over the first electrode; and
a common electrode over the first semiconductor layer,
wherein the second light-emitting device comprises:
a second electrode;
a second semiconductor layer over the second electrode; and
the common electrode over the second semiconductor layer,
wherein the first insulating layer comprises a region in contact with a side surface of the first semiconductor layer and a region in contact with a side surface of the second semiconductor layer,
wherein the filling layer comprises a region overlapping with the side surface of the first semiconductor layer with the first insulating layer therebetween and a region overlapping with the side surface of the second semiconductor layer with the first insulating layer therebetween,
wherein the common electrode comprises a region in contact with a top surface of the filling layer,
wherein the coloring layer comprises a region overlapping with the first light-emitting device with the color conversion layer therebetween, and
wherein the color conversion layer comprises a fluorescent substance or a quantum dot.

3. The display apparatus according to claim 1,
wherein, in a cross-sectional view, a first end portion of the filling layer is over the first semiconductor layer and a second end portion of the filling layer is over the second semiconductor layer, and
wherein the first end portion and the second end portion of the filling layer each have a tapered shape in the cross-sectional view.

4. The display apparatus according to claim 1,
wherein, in a cross-sectional view, a first end portion of the first insulating layer is over the first semiconductor layer and a second end portion of the first insulating layer is over the second semiconductor layer, and
wherein the first end portion and the second end portion of the first insulating layer each have a tapered shape in the cross-sectional view.

5. The display apparatus according to claim 1, wherein a first end portion of the filling layer is outside a first end portion of the first insulating layer.

6. The display apparatus according to claim 1, wherein top surface of the filling layer has a convex shape in a cross-sectional view.

7. The display apparatus according to claim 1, further comprising:
a reflective layer,
wherein the reflective layer is between the first insulating layer and the filling layer, and
wherein the reflective layer comprises a region overlapping with the side surface of the first semiconductor layer with the first insulating layer therebetween and a region overlapping with the side surface of the second semiconductor layer with the first insulating layer therebetween.

8. The display apparatus according to claim 1, further comprising:
a second insulating layer,
wherein the second insulating layer comprises a region in contact with a top surface of the first semiconductor layer, and
wherein the filling layer comprises a region overlapping with the top surface of the first semiconductor layer with the second insulating layer therebetween.

9. The display apparatus according to claim 1, further comprising:
a second insulating layer,
wherein the second insulating layer comprises a region in contact with a top surface of the first semiconductor layer,
wherein the filling layer comprises a region overlapping with the top surface of the first semiconductor layer with the second insulating layer therebetween, and
wherein an end portion of the second insulating layer has a tapered shape in a cross-sectional view.

10. The display apparatus according to claim 1,
wherein the first insulating layer comprises an inorganic material, and
wherein the filling layer comprises an organic material.

11. The display apparatus according to claim 1,
wherein the first insulating layer comprises an inorganic material,
wherein the filling layer comprises an organic material, and
wherein the filling layer has an insulating property.

12. The display apparatus according to claim 1,
wherein the first insulating layer comprises an inorganic material,
wherein the filling layer comprises an organic material, and
wherein the filling layer has a conductive property.

13. The display apparatus according to claim 1, wherein each of the first semiconductor layer and the second semiconductor layer comprises a Group 13 element and a Group 15 element.

14. The display apparatus according to claim 1, further comprising:
a layer,
wherein the layer comprises a first transistor and a second transistor,
wherein the first light-emitting device and the second light-emitting device are over the layer,
wherein the first light-emitting device is electrically connected to the first transistor, and
wherein the second light-emitting device is electrically connected to the second transistor.

15. (canceled)

16. (canceled)

17. A display apparatus comprising:
a first light-emitting device;
a second light-emitting device;
a first insulating layer; and
a filling layer,
wherein the first light-emitting device comprises:
a first electrode;
a first semiconductor layer over the first electrode; and
a common electrode over the first semiconductor layer,
wherein the second light-emitting device comprises:
a second electrode;
a second semiconductor layer over the second electrode; and
the common electrode over the second semiconductor layer,
wherein the first insulating layer comprises a region in contact with a side surface of the first semiconductor layer and a region in contact with a side surface of the second semiconductor layer,
wherein the filling layer comprises a region overlapping with the side surface of the first semiconductor layer with the first insulating layer therebetween and a region overlapping with the side surface of the second semiconductor layer with the first insulating layer therebetween,
wherein the common electrode comprises a region in contact with a top surface of the filling layer,
wherein, in a cross-sectional view, a first end portion of the filling layer is over the first semiconductor layer,
wherein the first end portion of the filling layer has a tapered shape in the cross-sectional view,
wherein, in the cross-sectional view, a first end portion of the first insulating layer is over the first semiconductor layer, and
wherein the first end portion of the first insulating layer has a tapered shape in the cross-sectional view.

18. The display apparatus according to claim 2, wherein a first end portion of the filling layer is outside a first end portion of the first insulating layer.

19. The display apparatus according to claim 2, wherein the top surface of the filling layer has a convex shape in a cross-sectional view.

20. The display apparatus according to claim 2, further comprising:
a reflective layer,
wherein the reflective layer is between the first insulating layer and the filling layer, and
wherein the reflective layer comprises a region overlapping with the side surface of the first semiconductor layer with the first insulating layer therebetween and a region overlapping with the side surface of the second semiconductor layer with the first insulating layer therebetween.
